(19) United States
(12) Patent Application Publication
(10) Pub. No.: US 2023/0043201 A1
(43) Pub. Date: Feb. 9, 2023

(54) COLORING COMPOSITION, FILM, OPTICAL FILTER, SOLID-STATE IMAGING ELEMENT, AND IMAGE DISPLAY DEVICE

(71) Applicant: FUJIFILM Corporation, Tokyo (JP)

(72) Inventor: Haruki INABE, Haibara-gun (JP)

(73) Assignee: FUJIFILM Corporation, Tokyo (JP)

(21) Appl. No.: 17/944,393

(22) Filed: Sep. 14, 2022

Related U.S. Application Data
(63) Continuation of application No. PCT/JP2021/009400, filed on Mar. 10, 2021.

(30) Foreign Application Priority Data
Mar. 16, 2020 (JP) 2020-045475

(51) Int. Cl. G03F 7/028; G03F 7/00; G03F 7/004

(52) U.S. Cl. CPC G03F 7/028; G03F 7/0007; G03F 7/0048; G02B 5/223

(57) ABSTRACT

Provided are a coloring composition including a colorant, a first resin including a repeating unit represented by Formula (b-10), and a second resin different from the first resin, in which the second resin is at least one selected from a polyimide precursor, a polyimide resin, a polybenzoxazole precursor, a polybenzoxazole resin, or a polysiloxane resin; a film formed of the coloring composition; an optical filter; a solid-state imaging element; and an image display device. In Formula (b-10), Ar¹⁰ represents a group including an aromatic carboxyl group, L¹¹ represents —COO— or —CONH—, L¹² represents a trivalent linking group, and P¹⁰ represents a polymer chain.

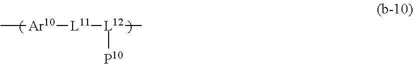

### CROSS-REFERENCE TO RELATED APPLICATIONS

This application is a Continuation of PCT International Application No. PCT/JP2021/009400 filed on Mar. 10, 2021, which claims priority under 35 U.S.C § 119(a) to Japanese Patent Application No. 2020-045475 filed on Mar. 16, 2020. Each of the above application(s) is hereby expressly incorporated by reference, in its entirety, into the present application.

### BACKGROUND OF THE INVENTION

### 1. Field of the Invention

The present invention relates to a coloring composition. The present invention further relates to a film formed of the coloring composition, an optical filter, a solid-state imaging element, and an image display device.

### 2. Description of the Related Art

In recent years, as a digital camera, a mobile phone with a camera, and the like have been further spreading, there has been a greatly increasing demand for a solid-state imaging element such as a charge coupled device (CCD) image sensor. A color filter has been used as a key device in a display or an optical element.

The color filter is manufactured by using a coloring composition including a colorant. JP2019-078878A discloses manufacturing a color filter using a coloring composition including a pigment, a resin having an aromatic carboxyl group, and a polymerizable monomer.

In addition, JP2017-186530A discloses manufacturing a color filter using a coloring composition containing a polyimide precursor, a colorant, and an organic solvent.

### SUMMARY OF THE INVENTION

Various devices such as a solid-state imaging element equipped with an optical filter such as a color filter may be used in a high humidity environment. Therefore, in recent years, it has been desired to develop a coloring composition with which a film having excellent moisture resistance can be formed.

In addition, from intensive studies with regard to the coloring compositions disclosed in JP2019-078878A and JP2017-186530A, the present inventor has found that the films obtained from the coloring compositions disclosed above have insufficient moisture resistance, and spectral characteristics of the films are likely to fluctuate in a case where the films are exposed to a high humidity environment.

Therefore, an object of the present invention is to provide a coloring composition with which a film having excellent moisture resistance can be formed. Another object of the present invention is to provide a film formed of the coloring composition, an optical filter, a solid-state imaging element, and an image display device.

According to the studies conducted by the present inventor, it has been found that the above-described object can be achieved by adopting the following configuration, thereby leading to the completion of the present invention. Therefore, the present invention provides the following.

<1> A coloring composition comprising:
a colorant;
a first resin including a repeating unit represented by Formula (b-10); and
a second resin different from the first resin,
in which the second resin is at least one selected from the group consisting of a polyimide precursor, a polyimide resin, a polybenzoxazole precursor, a polybenzoxazole resin, and a polysiloxane resin,

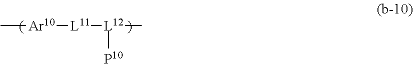

in Formula (b-10), Ar¹⁰ represents a group including an aromatic carboxyl group, L¹¹ represents —COO— or —CONH—, L¹² represents a trivalent linking group, and P¹⁰ represents a polymer chain.

<2> The coloring composition according to <1>,

in which the second resin is at least one selected from the group consisting of a polyimide precursor, a polybenzoxazole precursor, and a polysiloxane resin.

<3> The coloring composition according to <1> or <2>,

in which the second resin includes at least one selected from the group consisting of a polyimide precursor having a crosslinkable group, a polybenzoxazole precursor having a crosslinkable group, and a polysiloxane resin having a crosslinkable group.

<4> The coloring composition according to any one of <1> to <3>,

in which the second resin includes at least one selected from the group consisting of a polyimide precursor including a silicon atom and a polybenzoxazole precursor including a silicon atom.

<5> The coloring composition according to <4>,

in which the polyimide precursor including a silicon atom is a polyimide precursor including a siloxane bond, and the polybenzoxazole precursor including a silicon atom is a polybenzoxazole precursor including a siloxane bond.

<6> The coloring composition according to any one of <1> to <3>,

in which the second resin includes a polysiloxane resin having at least one group selected from the group consisting of an alkylsilyl group and an alkoxysilyl group.

<7> The coloring composition according to any one of <1> to <6>,

in which the first resin includes a crosslinkable group.

<8> The coloring composition according to any one of <1> to <7>,

in which the coloring composition includes 100 to 1600 parts by mass of the second resin with respect to 100 parts by mass of the first resin.

<9> The coloring composition according to any one of <1> to <8>,

in which a content of the first resin in a total solid content of the coloring composition is 0.5% to 10% by mass, and a content of the second resin in the total solid content of the coloring composition is 10% to 50% by mass.

<10> The coloring composition according to any one of <1> to <9>,

in which a content of the colorant in a total solid content of the coloring composition is 30% to 70% by mass.

<11> The coloring composition according to any one of <1> to <10>, further comprising:

a polymerizable monomer; and

a photopolymerization initiator.

<12> The coloring composition according to any one of <1> to <11>,

in which the coloring composition is used for forming a pixel of a color filter.

<13> The coloring composition according to any one of <1> to <12>,

in which the coloring composition is used for a solid-state imaging element.

<14> A film obtained from the coloring composition according to any one of <1> to

<13>.

<15> An optical filter comprising:

the film according to <14>.

<16> A solid-state imaging element comprising:

the film according to <14>.

<17> An image display device comprising:

the film according to <14>.

According to the present invention, it is possible to provide a coloring composition with which a film having excellent moisture resistance can be formed. It is also possible to provide a film formed of the coloring composition, an optical filter, a solid-state imaging element, and an image display device.

### DESCRIPTION OF THE PREFERRED EMBODIMENTS

Hereinafter, the details of the present invention will be described.

In the present specification, “to” is used to refer to a meaning including numerical values denoted before and after “to” as a lower limit value and an upper limit value.

In the present specification, unless specified as a substituted group or as an unsubstituted group, a group (atomic group) denotes not only a group (atomic group) having no substituent but also a group (atomic group) having a substituent. For example, an “alkyl group” includes not only an alkyl group having no substituent (unsubstituted alkyl group), but also an alkyl group having a substituent (substituted alkyl group).

In the present specification, unless specified otherwise, “exposure” denotes not only exposure using light but also drawing using a corpuscular beam such as an electron beam or an ion beam. In addition, examples of light used for the exposure include actinic rays or radiation such as a bright line spectrum of a mercury lamp, far ultraviolet rays typified by an excimer laser, extreme ultraviolet rays (EUV light), X-rays, or electron beams.

In the present specification, “(meth)acrylate” denotes either or both of acrylate and methacrylate, “(meth)acryl” denotes either or both of acryl and methacryl, and “(meth)acryloyl” denotes either or both of acryloyl and methacryloyl.

In the present specification, in a structural formula, Me represents a methyl group, Et represents an ethyl group, Bu represents a butyl group, Pr represents a propyl group, and Ph represents a phenyl group.

In the present specification, a weight-average molecular weight and a number-average molecular weight are values in terms of polystyrene through measurement by a gel permeation chromatography (GPC) method.

In the present specification, a total solid content denotes the total mass of all the components of the composition excluding a solvent.

In the present specification, a pigment means a compound which is hardly dissolved in a solvent. For example, as the pigment, both of the solubility in 100 g of water at 23° C. and 100 g of propylene glycol monomethyl ether acetate at 23° C. is preferably 0.1 g or less and more preferably 0.01 g or less.

In the present specification, the term “step” is not only an independent step, but also includes a step which is not clearly distinguished from other steps in a case where an intended action of the step is obtained.

<Coloring Composition>

A coloring composition according to an embodiment of the present invention includes a colorant, a first resin including a repeating unit represented by Formula (b-10), and a second resin different from the first resin, in which the second resin is at least one selected from a polyimide precursor, a polyimide resin, a polybenzoxazole precursor, a polybenzoxazole resin, or a polysiloxane resin.

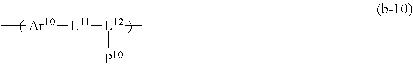

In Formula (b-10), Ar¹⁰ represents a group including an aromatic carboxyl group, L¹¹ represents —COO— or —CONH—, L¹² represents a trivalent linking group, and P¹⁰ represents a polymer chain.

With the coloring composition according to the embodiment of the present invention, a film having excellent moisture resistance can be formed. The reason for obtaining such an effect is presumed as follows. The first resin including a repeating unit represented by Formula (b-10) tends to have a low glass transition temperature. Therefore, in a case where a film formed of the coloring composition including the first resin is exposed to a high humidity environment, it is presumed that the first resin thermally moves in the film to generate a channel through which water permeates into the film. In a case where such a channel is formed, it is presumed that the water permeates into the film through this channel, causing deterioration of the film such as fluctuation in spectral characteristics. However, since the coloring composition according to the embodiment of the present invention further includes the above-described second resin in addition to the first resin, even in a case where the first resin thermally moves in the film in a case where the film is exposed to a high humidity environment, it is presumed that the water permeation channel generated thereby can be filled with the second resin to suppress the permeation of water. Therefore, according to the coloring composition according to the embodiment of the present invention, it is presumed that a film having excellent moisture resistance can be formed.

The coloring composition according to the embodiment of the present invention is preferably used as a coloring composition for an optical filter. The coloring composition according to the embodiment of the present invention is more preferably a coloring composition for an optical filter used in a solid-state imaging element. Examples of the optical filter include a color filter and a near-infrared transmitting filter, and a color filter is preferable. In addition, the coloring composition according to the embodiment of the present invention can also be used as a coloring composition for a black matrix and a light-shielding film.

Examples of the color filter include a filter having a colored pixel which transmits light having a specific wavelength, and a filter having at least one colored pixel selected from a red pixel, a blue pixel, a green pixel, a yellow pixel, a cyan pixel, or a magenta pixel is preferable. The colored pixel of the color filter can be formed using a coloring composition including a chromatic colorant.

The near-infrared transmitting filter is a filter which transmits at least a part of near-infrared rays. As the near-infrared transmitting filter, a filter which shields at least a part of visible light and transmits at least a part of near-infrared rays is preferably. Preferred examples of the near-infrared transmitting filter include filters satisfying spectral characteristics in which the maximum value of a transmittance in a wavelength range of 400 to 640 nm is 20% or less (preferably 15% or less and more preferably 10% or less) and the minimum value of a transmittance in a wavelength range of 1100 to 1300 nm is 70% or more (preferably 75% or more and more preferably 80% or more). The near-infrared transmitting filter is preferably a filter which satisfies any one of the following spectral characteristics (1) to (4).

(1): filter in which the maximum value of a transmittance in a wavelength range of 400 to 640 nm is 20% or less (preferably 15% or less and more preferably 10% or less) and the minimum value of a transmittance in a wavelength range of 800 to 1300 nm is 70% or more (preferably 75% or more and more preferably 80% or more).

(2): filter in which the maximum value of a transmittance in a wavelength range of 400 to 750 nm is 20% or less (preferably 15% or less and more preferably 10% or less) and the minimum value of a transmittance in a wavelength range of 900 to 1300 nm is 70% or more (preferably 75% or more and more preferably 80% or more).

(3): filter in which the maximum value of a transmittance in a wavelength range of 400 to 830 nm is 20% or less (preferably 15% or less and more preferably 10% or less) and the minimum value of a transmittance in a wavelength range of 1000 to 1300 nm is 70% or more (preferably 75% or more and more preferably 80% or more).

(4): filter in which the maximum value of a transmittance in a wavelength range of 400 to 950 nm is 20% or less (preferably 15% or less and more preferably 10% or less) and the minimum value of a transmittance in a wavelength range of 1100 to 1300 nm is 70% or more (preferably 75% or more and more preferably 80% or more).

The coloring composition according to the embodiment of the present invention is also preferably a coloring composition used for forming a pixel by a photolithography method.

According to this aspect, finely sized pixels can be easily formed. Therefore, the coloring composition according to the embodiment of the present invention can be particularly preferably used as a coloring composition for forming a pixel of a color filter used in a solid-state imaging element. For example, a coloring composition containing a polymerizable monomer and a photopolymerization initiator can be preferably used as a coloring composition for forming a pattern by a photolithography method.

The concentration of solid contents of the coloring composition according to the embodiment of the present invention is preferably 5% to 30% by mass. The lower limit is preferably 7.5% by mass or more and more preferably 10% by mass or more. The upper limit is preferably 25% by mass or less, more preferably 20% by mass or less, and still more preferably 15% by mass or less.

Hereinafter, the respective components used in the coloring composition according to the embodiment of the present invention will be described.

<<Colorant>>

The coloring composition according to the embodiment of the present invention contains a colorant. Examples of the colorant include a chromatic colorant and a black colorant. In a case of using a chromatic colorant as the colorant, the coloring composition according to the embodiment of the present invention can be preferably used as a coloring composition for forming a colored pixel in a color filter.

The colorant may be a pigment or a dye. The pigment and the dye may be used in combination. In addition, the pigment may be an inorganic pigment or an organic pigment, but from the viewpoint of many color variations, ease of dispersion, safety, and the like, an organic pigment is preferable. In addition, as the pigment, a material in which a part of an inorganic pigment or an organic-inorganic pigment is substituted with an organic chromophore can also be used. By substituting an inorganic pigment or an organic-inorganic pigment with an organic chromophore, hue design can be easily performed.

The colorant used in the present invention preferably includes the pigment. A content of the pigment in the colorant is preferably 50% by mass or more, more preferably 70% by mass or more, still more preferably 80% by mass or more, and particularly preferably 90% by mass or more.

It is preferable that the colorant included in the coloring composition includes at least one selected from a phthalocyanine pigment, a dioxazine pigment, a quinacridone pigment, an anthraquinone pigment, a perylene pigment, an azo pigment, a diketopyrrolopyrrole pigment, a pyrrolopyrrole pigment, an isoindoline pigment, or a quinophthalone pigment, it is more preferable to include at least one selected from a phthalocyanine pigment, a diketopyrrolopyrrole pigment, or a pyrrolopyrrole pigment, and it is still more preferable to include a phthalocyanine pigment or a diketopyrrolopyrrole pigment. In addition, from the reason that it is easy to form a film in which spectral characteristics do not easily fluctuate even after heating to a high temperature (for example, 300° C. or higher), the phthalocyanine pigment is preferably a phthalocyanine pigment having no central metal or a phthalocyanine pigment having copper or zinc as a central metal.

From the reason that it is easy to form a film in which spectral characteristics do not easily fluctuate even after heating to a high temperature (for example, 300° C. or higher), it is preferable that the colorant included in the coloring composition includes at least one selected from a red pigment, a yellow pigment, or a blue pigment, it is more preferable to include at least one selected from a red pigment or a blue pigment, and it is still more preferable to include a blue pigment.

The colorant included in the coloring composition preferably includes a pigment A satisfying the following requirement 1. By using a colorant having such characteristics, it is possible to form a film in which spectral characteristics do not easily fluctuate even after heating to a high temperature (for example, 300° C. or higher). The proportion of the pigment A in the total amount of the pigment included in the coloring composition is preferably 20% to 100% by mass, more preferably 30% to 100% by mass, and still more preferably 40% to 100% by mass.

Requirement 1)

In a case where a film having a thickness of 0.60 μm is formed by heating, at 200° C. for 30 minutes, a composition which includes 6% by mass of the pigment A, 10% by mass of a resin 1, and 84% by mass of propylene glycol monomethyl ether acetate, in a case where the film is subjected to a heating treatment at 300° C. for 5 hours in a nitrogen atmosphere, the rate of change AA10 in absorbance of the film after the heating treatment, which is represented by Expression (A10), is 50% or less;

ΔA10=|100−(A12/A11)×100| (10)

ΔA10 is the rate of change in the absorbance of the film after the heating treatment;

A11 is the maximum value of the absorbance of the film before the heating treatment in a wavelength range of 400 to 1100 nm;

A12 is the absorbance of the film after the heating treatment, and is the absorbance at the wavelength showing the maximum value of the film before the heating treatment in a wavelength range of 400 to 1100 nm; and

The resin 1 is a resin having the following structure, in which a numerical value added to a main chain represents a molar ratio, the weight-average molecular weight is 11000, and the acid value is 32 mgKOH/g.

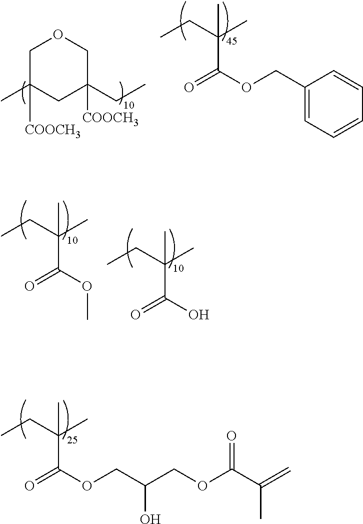

Examples of the pigment A satisfying the above-described requirement 1 include Color Index (C. I.) Pigment Red 254, C. I. Pigment Red 264, C. I. Pigment Red 272, C. I. Pigment Red 122, C. I. Pigment Red 177, C. I. Pigment Blue 15:3, C. I. Pigment Blue 15:4, C. I. Pigment Blue 15:6, and C. I. Pigment Blue 16.

An average primary particle diameter of the pigment is preferably 1 to 200 nm. The lower limit is preferably 5 nm or more and more preferably 10 nm or more. The upper limit is preferably 180 nm or less, more preferably 150 nm or less, and still more preferably 100 nm or less. In a case where the average primary particle diameter of the pigment is within the above-described range, dispersion stability of the pigment in the coloring composition is good. In the present specification, the primary particle diameter of the pigment can be determined from a captured image obtained by observing primary particles of the pigment using a transmission electron microscope. Specifically, a projected area of the primary particles of the pigment is determined, and the corresponding equivalent circle diameter is calculated as the primary particle diameter of the pigment. In addition, the average primary particle diameter in the present specification is an arithmetic average of the primary particle diameters with respect to 400 primary particles of the pigment. In addition, the primary particle of the pigment means a particle which is independent without aggregation.

(Chromatic Colorant)

Examples of the chromatic colorant include a colorant having a maximal absorption wavelength in a wavelength range of 400 to 700 nm. Examples thereof include yellow colorants, orange colorants, red colorants, green colorants, violet colorants, and blue colorants. Specific examples of the chromatic colorant include the following.

C. I. Pigment Yellow 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 150, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, 214, 215, 228, 231, 232 (methine-based), 233 (quinoline-based), 234 (aminoketone-based), 235 (aminoketone-based), 236 (aminoketone-based), and the like (all of which are yellow pigments);

C. I. Pigment Orange 2, 5, 13, 16, 17:1, 31, 34, 36, 38, 43, 46, 48, 49, 51, 52, 55, 59, 60, 61, 62, 64, 71, 73, and the like (all of which are orange pigments); C. I. Pigment Red 1, 2, 3, 4, 5, 6, 7, 9, 10, 14, 17, 22, 23, 31, 38, 41, 48:1, 48:2, 48:3, 48:4, 49, 49:1, 49:2, 52:1, 52:2, 53:1, 57:1, 60:1, 63:1, 66, 67, 81:1, 81:2, 81:3, 83, 88, 90, 105, 112, 119, 122, 123, 144, 146, 149, 150, 155, 166, 168, 169, 170, 171, 172, 175, 176, 177, 178, 179, 184, 185, 187, 188, 190, 200, 202, 206, 207, 208, 209, 210, 216, 220, 224, 226, 242, 246, 254, 255, 264, 269, 270, 272, 279, 291, 294 (xanthene-based, Organo Ultramarine, Bluish Red), 295 (monoazo-based), 296 (diazo-based), 297 (aminoketone-based), and the like (all of which are red pigments);

C. I. Pigment Green 7, 10, 36, 37, 58, 59, 62, 63, 64 (phthalocyanine-based), 65 (phthalocyanine-based), 66 (phthalocyanine-based), and the like (all of which are green pigments);

C. I. Pigment Violet 1, 19, 23, 27, 32, 37, 42, 60 (triarylmethane-based), 61 (xanthene-based), and the like (all of which are violet pigments); and

C. I. Pigment Blue 1, 2, 15, 15:1, 15:2, 15:3, 15:4, 15:6, 16, 22, 29, 60, 64, 66, 79, 80, 87 (monoazo-based), 88 (methine-based), and the like (all of which are blue pigments).

In addition, a halogenated zinc phthalocyanine pigment having an average number of halogen atoms in one molecule of 10 to 14, an average number of bromine atoms in one molecule of 8 to 12, and an average number of chlorine atoms in one molecule of 2 to 5 can also be used as the green colorant. Specific examples thereof include the compounds described in WO2015/118720A. In addition, as the green colorant, a compound described in CN2010-6909027A, a phthalocyanine compound described in WO2012/102395A, which has phosphoric acid ester as a ligand, a phthalocyanine compound described in JP2019-008014A, a phthalocyanine compound described in JP2018-180023A, a compound described in JP2019-038958A, and the like can also be used.

In addition, as the blue colorant, an aluminum phthalocyanine compound having a phosphorus atom can also be used. Specific examples thereof include the compounds described in paragraph Nos. 0022 to 0030 of JP2012-247591A and the compounds described in paragraph No. 0047 of JP2011-157478A.

In addition, as the yellow colorant, compounds described in JP2017-201003A, compounds described in JP2017-197719A, compounds described in paragraph Nos. 0011 to 0062 and 0137 to 0276 of JP2017-171912A, compounds described in paragraph Nos. 0010 to 0062 and 0138 to 0295 of JP2017-171913A, compounds described in paragraph Nos. 0011 to 0062 and 0139 to 0190 of JP2017-171914A, compounds described in paragraph Nos. 0010 to 0065 and 0142 to 0222 of JP2017-171915A, quinophthalone compounds described in paragraph Nos. 0011 to 0034 of JP2013-054339A, quinophthalone compounds described in paragraph Nos. 0013 to 0058 of JP2014-026228A, isoindoline compounds described JP2018-062644A, quinophthalone compounds described in JP218-203798A, quinophthalone compounds described in JP2018-062578A, quinophthalone compounds described in JP6432077B, quinophthalone compounds described in JP6432076B, quinophthalone compounds described in JP2018-155881A, quinophthalone compounds described in JP2018-111757A, quinophthalone compounds described in JP2018-040835A, quinophthalone compounds described in JP2017-197640A, quinophthalone compounds described in JP2016-145282A, quinophthalone compounds described in JP2014-085565A, quinophthalone compounds described in JP2014-021139A, quinophthalone compounds described in JP2013-209614A, quinophthalone compounds described in JP2013-209435A, quinophthalone compounds described in JP2013-181015A, quinophthalone compounds described in JP2013-061622A, quinophthalone compounds described in JP2013-054339A, quinophthalone compounds described in JP2013-032486A, quinophthalone compounds described in JP2012-226110A, quinophthalone compounds described in JP2008-074987A, quinophthalone compounds described in JP2008-081565A. quinophthalone compounds described in JP2008-074986A, quinophthalone compounds described in JP2008-074985A, quinophthalone compounds described in JP2008-050420A, quinophthalone compounds described in JP2008-031281A, quinophthalone compounds described in JP1973-032765A (JP-S48-032765A), quinophthalone compounds described in JP2019-008014A, a compound represented by Formula (QP1), a compound represented by Formula (QP2), compounds described in KR10-2014-0034963A, compounds described in JP2017-095706A, compounds described in TW2019-20495A, and compounds described in JP6607427B can also be used. In addition, from the viewpoint of improving a color value, a multimerized compound of these compounds is also preferably used.

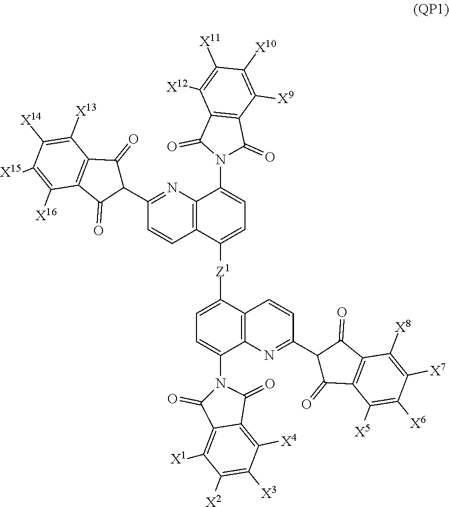

In Formula (QP1), X¹ to X¹⁶ each independently represent a hydrogen atom or a halogen atom, and Z¹ represents an alkylene group having 1 to 3 carbon atoms. Specific examples of the compound represented by Formula (QP1) include compounds described in paragraph No. 0016 of JP6443711B.

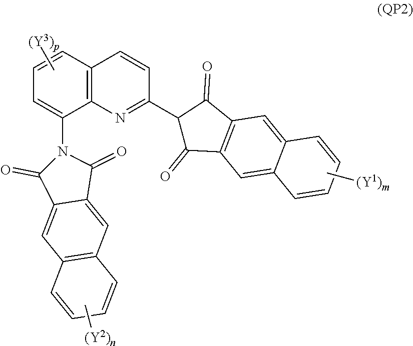

In Formula (QP2), Y¹ to Y³ each independently represent halogen atom. n and m represent an integer of 0 to 6, and p represents an integer of 0 to 5. (n+m) is 1 or more. Specific examples of the compound represented by Formula (QP2) include compounds described in paragraph Nos. 0047 and 0048 of JP6432077B.

A diketopyrrolopyrrole pigment described in JP2017-201384A, in which the structure has at least one substituted bromine atom, a diketopyrrolopyrrole pigment described in paragraph Nos. 0016 to 0022 of JP6248838B, a red colorant described in JP6516119B, a red colorant described in JP6525101B, and the like can also be used as the red colorant. In addition, as the red colorant, a compound having a structure that an aromatic ring group in which a group bonded with an oxygen atom, a sulfur atom, or a nitrogen atom is introduced to an aromatic ring is bonded to a diketopyrrolopyrrole skeleton can be used.

In addition, regarding diffraction angles preferably possessed by various pigments, descriptions of JP6561862B, JP6413872B, and JP6281345B can be referred to, the contents of which are incorporated herein by reference.

In addition, a dye can also be used as the chromatic colorant. The dye is not particularly limited and a known dye can be used. Examples thereof include a pyrazoleazo compound, an anilinoazo compound, a triarylmethane compound, an anthraquinone compound, an anthrapyridone compound, a benzylidene compound, an oxonol compound, a pyrazolotriazoleazo compound, a pyridoneazo compound, a cyanine compound, a phenothiazine compound, a pyrrolopyrazoleazomethine compound, a xanthene compound, a phthalocyanine compound, a benzopyran compound, an indigo compound, and a pyrromethene compound. In addition, the thiazole compound described in JP2012-158649A, the azo compound described in JP2011-184493A. or the azo compound described in JP2011-145540A can also be used. In addition, as the dye, a coloring agent multimer can also be used. The coloring agent multimer has two or more coloring agent structures in one molecule, and preferably has three or more coloring agent structures in one molecule. The upper limit is particularly not limited, but may be 100 or less. A plurality of coloring agent structures included in one molecule may be the same coloring agent structure or different coloring agent structures. A weight-average molecular weight (Mw) of the coloring agent multimer is preferably 2000 to 50000. The lower limit is more preferably 3000 or more and still more preferably 6000 or more. The upper limit is more preferably 30000 or less and still more preferably 20000 or less. As the coloring agent multimer, the compounds described in JP2011-213925A, JP2013-041097A, JP2015-028144A, JP2015-030742A, JP2016-102191A, WO2016/031442A, or the like can also be used.

The chromatic colorant may be used in a combination of two or more kinds thereof. For example, in a case where the coloring composition according to the embodiment of the present invention is used for a green pixel of a color filter, it is preferable to use a green colorant and a yellow colorant as the colorant. A proportion of the green colorant and the yellow colorant is preferably 20 to 200 parts by mass, more preferably 50 to 150 parts by mass, of the yellow colorant with respect to 100 parts by mass of the green colorant. In addition, as the green colorant, at least one selected from C. I. Pigment Green 7, C. I. Pigment Green 36, C. I. Pigment Green 58, C. I. Pigment Green 59, C. I. Pigment Green 62, or C. I. Pigment Green 63 is preferable, and at least one selected from C. I. Pigment Green 7, C. I. Pigment Green 36, or C. I. Pigment Green 58 is more preferable. In addition, as the yellow colorant, at least one selected from C. I. Pigment Yellow 129, C. I. Pigment Yellow 138, C. I. Pigment Yellow 139, C. I. Pigment Yellow 150, C. I. Pigment Yellow 185, or C. I. Pigment Yellow 215 is preferable, and at least one selected from C. I. Pigment Yellow 139, C. I. Pigment Yellow 150, or C. I. Pigment Yellow 185 is more preferable.

In addition, in a case where the chromatic colorant is used in a combination of two or more kinds thereof, the combination of two or more kinds of chromatic colorants may form black. Examples of such a combination include the following aspects (1) to (7). In a case where two or more chromatic colorants are included in the coloring composition and the combination of two or more chromatic colorants forms black, the coloring composition according to the embodiment of the present invention can be preferably used as a coloring composition for forming a near-infrared transmitting filter.

(1): aspect in which the colorant contains a red colorant and a blue colorant (2): aspect in which the colorant contains a red colorant, a blue colorant, and a yellow colorant

(3): aspect in which the colorant contains a red colorant, a blue colorant, a yellow colorant, and a violet colorant

(4): aspect in which the colorant contains a red colorant, a blue colorant, a yellow colorant, a violet colorant, and a green colorant

(5): aspect in which the colorant contains a red colorant, a blue colorant, a yellow colorant, and a green colorant

(6): aspect in which the colorant contains a red colorant, a blue colorant, and a green colorant

(7): aspect in which the colorant contains a yellow colorant and a violet colorant

(Black Colorant) The black colorant is not particularly limited, and a known black colorant can be used.

Examples of an inorganic black colorant include carbon black, titanium black, and graphite, and carbon black or titanium black is preferable and titanium black is more preferable. The titanium black is black particles containing a titanium atom, and is preferably lower titanium oxide or titanium oxynitride. The surface of the titanium black can be modified, as necessary, according to the purpose of improving dispersibility, suppressing aggregating properties, and the like. For example, the surface of the titanium black can be coated with silicon oxide, titanium oxide, germanium oxide, aluminum oxide, magnesium oxide, or zirconium oxide. In addition, a treatment with a water-repellent substance as described in JP2007-302836A can be performed. Examples of the black colorant include Color Index (C. I.) Pigment Black 1 and 7. It is preferable that the titanium black has a small primary particle diameter of the individual particles and has a small average primary particle diameter. Specifically, an average primary particle diameter thereof is preferably 10 to 45 nm. The titanium black can be used as a dispersion. Examples thereof include a dispersion which includes titanium black particles and silica particles and in which the content ratio of Si atoms to Ti atoms is adjusted to a range of 0.20 to 0.50. With regard to the dispersion, reference can be made to the description in paragraphs 0020 to 0105 of JP2012-169556A, the contents of which are incorporated herein by reference. Examples of a commercially available product of the titanium black include Titanium black 10S, 12S, 13R, 13M, 13M-C, 13R-N, 13M-T (trade name; manufactured by Mitsubishi Materials Corporation) and Tilack D (trade name; manufactured by Akokasei Co., Ltd.). Examples of the organic black colorant include a bisbenzofuranone compound, an azomethine compound, a perylene compound, and an azo compound. Among these, a bisbenzofuranone compound or a perylene compound is preferable. Examples of the bisbenzofuranone compound include compounds described in JP2010-534726A, JP2012-515233A, JP2012-515234A, WO2014/208348A, JP2015-525260A, and the like, and the bisbenzofuranone compound is available, for example, as “Irgaphor Black” manufactured by BASF SE. Examples of the perylene compound include C. I.

Pigment Black 31 and 32. Examples of the azomethine compound include the compounds described in JP1989-170601A (JP-HO1-170601A) and JP1990-034664A (JP-H02-034664A), and the azomethine compound is available, for example, “CHROMOFINE BLACK A1103” manufactured by Dainichiseika Color & Chemicals Mfg. Co., Ltd. In addition, as the organic black colorant, perylene black (Lumogen Black FK4280 and the like) described in paragraphs 0016 to 0020 of JP2017-226821A may be used.

A content of the colorant in the total solid content of the coloring composition is preferably 30% to 70% by mass. The lower limit is preferably 35% by mass or more and more preferably 40% by mass or more. The upper limit is preferably 65% by mass or less and more preferably 60% by mass or less.

In addition, a content of the pigment in the total solid content of the coloring composition is preferably 30% to 70% by mass. The lower limit is preferably 35% by mass or more and more preferably 40% by mass or more. The upper limit is preferably 65% by mass or less and more preferably 60% by mass or less.

<<Pigment Derivative>>

The coloring composition according to the embodiment of the present invention can contain a pigment derivative. Examples of the pigment derivative include a compound having a structure in which a part of a chromophore is substituted with an acid group or a basic group. Examples of the chromophore constituting the pigment derivative include a quinoline skeleton, a benzimidazolone skeleton, a diketopyrrolopyrrole skeleton, an azo skeleton, a phthalocyanine skeleton, an anthraquinone skeleton, a quinacridone skeleton, a dioxazine skeleton, a perinone skeleton, a perylene skeleton, a thioindigo skeleton, an isoindoline skeleton, an isoindolinone skeleton, a quinophthalone skeleton, a threne skeleton, and a metal complex-based skeleton. Among these, a quinoline skeleton, a benzimidazolone skeleton, a diketopyrrolopyrrole skeleton, an azo skeleton, a quinophthalone skeleton, an isoindoline skeleton, or a phthalocyanine skeleton is preferable, and an azo skeleton or a benzimidazolone skeleton is more preferable. Examples of the acid group include a sulfo group, a carboxyl group, a phosphoric acid group, and a salt thereof. Examples of an atom or atomic group constituting the salts include alkali metal ions (Li⁺, Na⁺, K⁺, and the like), alkaline earth metal ions (Ca²⁺, Mg²⁺, and the like), an ammonium ion, an imidazolium ion, a pyridinium ion, and a phosphonium ion. Examples of the basic group included in the pigment derivative include an amino group, a pyridinyl group, or a salt thereof, a salt of an ammonium group, and a phthalimidomethyl group. Examples of an atom or atomic group constituting the salts include a hydroxide ion, a halogen ion, a carboxylate ion, a sulfonate ion, and a phenoxide ion.

In the present invention, as the pigment derivative, a pigment derivative having excellent visible transparency (hereinafter, also referred to as a transparent pigment derivative) can be contained. The maximum value (εmax) of a molar absorption coefficient of the transparent pigment derivative in a wavelength range of 400 to 700 nm is preferably 3000 L·mol⁻¹·cm⁻¹ or less, more preferably 1000 L·mol⁻¹·cm⁻¹ or less, and still more preferably 100 L·mol⁻¹·cm⁻¹ or less. The lower limit of εmax is, for example, 1 L mol⁻¹·cm⁻¹ or more and may be 10 L mol⁻¹ cm⁻¹ or more.

Specific examples of the pigment derivative include compounds described in JP1981-118462A (JP-S56-118462A), JP1988-264674A (JP-S63-264674A), JP1989-217077A (JP-HO1-217077A), JP1991-009961A (JP-H03-009961A), JP1991-026767A (JP-H03-026767A), JP1991-153780A (JP-H03-153780A), JP1991-045662A (JP-H03-045662A), JP1992-285669A (JP-H04-285669A), JP1994-145546A (JP-H06-145546A), JP1994-212088A (JP-H06-212088A), JP1994-240158A (JP-H06-240158A), JP1998-030063A (JP-H10-030063A), JP1998-195326A (JP-H10-195326A), paragraph Nos. 0086 to 0098 of WO2011/024896A, paragraph Nos. 0063 to 0094 of WO2012/102399A, paragraph No. 0082 of WO2017/038252A, paragraph No. 0171 of JP2015-151530A, paragraph Nos. 0162 to 0183 of JP2011-252065A, JP2003-081972A, JP5299151B, JP2015-172732A, JP2014-199308A, JP2014-085562A, JP2014-035351A, JP2008-081565A, and JP2019-109512A.

The content of the pigment derivative is preferably 1 to 30 parts by mass and still more preferably 3 to 20 parts by mass with respect to 100 parts by mass of the colorant. The pigment derivative may be used singly or in a combination of two or more kinds thereof. In a case where two or more kinds thereof are used in combination, the total amount thereof is preferably within the above-described range.

Resin

The coloring composition according to the embodiment of the present invention includes a resin. The resin included in the coloring composition according to the embodiment of the present invention includes the first resin including a repeating unit represented by Formula (b-10) and the second resin different from the first resin. The second resin is at least one selected from a polyimide precursor, a polyimide resin, a polybenzoxazole precursor, a polybenzoxazole resin, or a polysiloxane resin. Since the first resin is also excellent in dispersibility of the pigment, the resin is preferably used as a dispersant.

(First Resin)

The first resin is a resin including a repeating unit represented by Formula (b-10). The repeating unit represented by Formula (b-10) will be described.

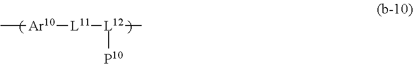

In Formula (b-10), Ar¹⁰ represents a group including an aromatic carboxyl group, L¹¹ represents —COO— or —CONH—, L¹² represents a trivalent linking group, and P¹⁰ represents a polymer chain.

In Formula (b-10), examples of the group including an aromatic carboxyl group, represented by Ar¹⁰, include a structure derived from an aromatic tricarboxylic acid anhydride and a structure derived from an aromatic tetracarboxylic acid anhydride. Examples of the aromatic tricarboxylic acid anhydride and the aromatic tetracarboxylic acid anhydride include compounds having the following structures.

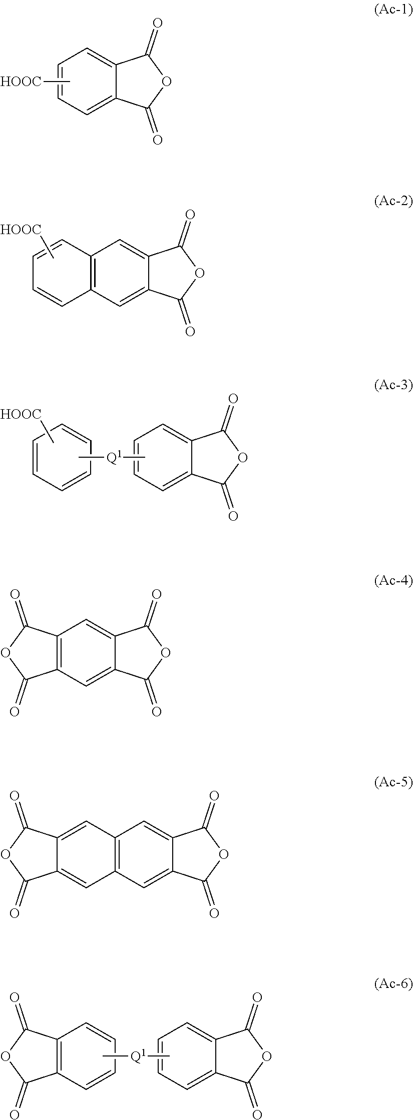

In the formulae, Q¹ represents a single bond, —O—, —CO—, —COOCH₂CH₂OCO—, —SO₂—, —C(CF₃)₂—, a group represented by Formula (Q-1), or a group represented by Formula (Q-2).

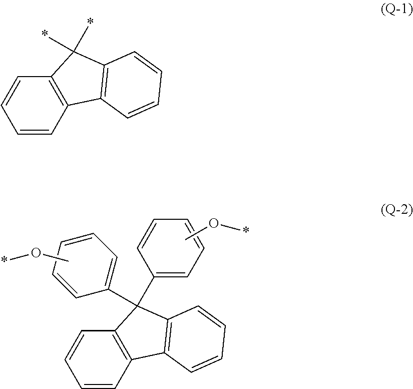

Specific examples of the aromatic tricarboxylic acid anhydride include a benzenetricarboxylic acid anhydride (1,2,3-benzenetricarboxylic acid anhydride, trimellitic acid anhydride [1,2,4-benzenetricarboxylic acid anhydride], and the like), a naphthalenetricarboxylic acid anhydride (1,2,4-naphthalenetricarboxylic acid anhydride, 1,4,5-naphthalenetricarboxylic acid anhydride, 2,3,6-naphthalenetricarboxylic acid anhydride, 1,2,8-naphthalenetricarboxylic acid anhydride, and the like), 3,4,4′-benzophenonetricarboxylic acid anhydride, 3,4,4′-biphenylethertricarboxylic acid anhydride, 3,4,4′-biphenyltricarboxylic acid anhydride, 2,3,2′-biphenyltricarboxylic acid anhydride, 3,4,4′-biphenylmethanetricarboxylic acid anhydride, and 3,4,4′-biphenylsulfonetricarboxylic acid anhydride. Specific examples of the aromatic tetracarboxylic acid anhydride include pyromellitic acid dianhydride, ethylene glycol dianhydrous trimellitic acid ester, propylene glycol dianhydrous trimellitic acid ester, butylene glycol dianhydrous trimellitic acid ester, 3,3′,4,4′-benzophenonetetracarboxylic acid dianhydride, 3,3′,4,4′-biphenylsulfonetetracarboxylic acid dianhydride, 1,4,5,8-naphthalenetetracarboxylic acid dianhydride, 2,3,6,7-naphthalenetetracarboxylic acid dianhydride, 3,3′,4,4′-biphenylethertetracarboxylic acid dianhydride, 3,3′,4,4′-dimethyldiphenylsilanetetracarboxylic acid dianhydride, 3,3′,4,4′-tetraphenylsilanetetracarboxylic acid dianhydride, 1,2,3,4-frantetracarboxylic acid dianhydride, 4,4′-bis(3,4-dicarboxyphenoxy)diphenylsulfide dianhydride, 4,4′-bis(3,4-dicarboxyphenoxy)diphenylsulfone dianhydride, 4,4′-bis (3,4-dicarboxyphenoxy) diphenylpropane dianhydride, 3,3′,4,4′-perfluoroisopropyridendiphthalic acid dianhydride, 3,3′,4,4′-biphenyltetracarboxylic acid dianhydride, bis(phthalic acid) phenylphosphineoxide dianhydride, p-phenylene-bis(triphenylphthalic acid) dianhydride, m-phenylene-bis(triphenylphthalic acid) dianhydride, bis(triphenylphthalic acid)-4,4′-diphenylether dianhydride, bis(triphenylphthalic acid)-4,4′-diphenylmethane dianhydride, 9,9-bis(3,4-dicarboxyphenyl)fluorene dianhydride, 9,9-bis[4-(3,4-dicarboxyphenoxy)phenyl]fluorene dianhydride, 3,4-dicarboxy-1,2,3,4-tetrahydro-1-naphthalenesuccinic acid dianhydride, and 3,4-dicarboxy-1,2,3,4-tetrahydro-6-methyl-1-naphthalenesuccinic acid dianhydride.

Specific examples of the group including an aromatic carboxyl group represented by Ar¹⁰ include a group represented by Formula (Ar-1), a group represented by Formula (Ar-2), and a group represented by Formula (Ar-3).

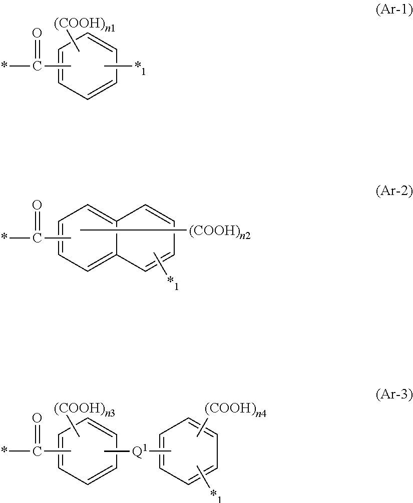

In Formula (Ar-1), n1 represents an integer of 1 to 4, and is preferably 1 or 2 and more preferably 2.

In Formula (Ar-2), n2 represents an integer of 1 to 8, and is preferably an integer of 1 or 4, more preferably 1 or 2, and still more preferably 2.

In Formula (Ar-3), n3 and n4 each independently represent an integer of 0 to 4, and are preferably an integer of 0 or 2, more preferably 1 or 2, and still more preferably 1. However, at least one of n3 or n4 is an integer of 1 or more.

In Formula (Ar-3), Q¹ represents a single bond, —O—, —CO—, —COOCH₂CH₂OCO—, —SO₂—, —C(CF₃)₂—, the above-described group represented by Formula (Q-1), or the above-described group represented by Formula (Q-2).

In Formulae (Ar-1) to (Ar-3), *1 represents a bonding position with L¹¹.

In Formula (b-10), L¹¹ represents —COO— or —CONH—, preferably —COO—.

In Formula (b-10), examples of the trivalent linking group represented by L¹² include a hydrocarbon group, —O—, —CO—, —COO—, —OCO—, —NH—, —S—, and a group formed by a combination of two or more of these groups. Examples of the hydrocarbon group include an aliphatic hydrocarbon group and an aromatic hydrocarbon group. The number of carbon atoms in the aliphatic hydrocarbon group is preferably 1 to 30, more preferably 1 to 20, and still more preferably 1 to 15. The aliphatic hydrocarbon group may be linear, branched, or cyclic. The number of carbon atoms in the aromatic hydrocarbon group is preferably 6 to 30, more preferably 6 to 20, and still more preferably 6 to 10. The hydrocarbon group may have a substituent. Examples of the substituent include an ethylenically unsaturated bond-containing group and a hydroxy group. Examples of the ethylenically unsaturated bond-containing group include a vinyl group, a vinylphenyl group, a (meth)allyl group, a (meth)acryloyl group, a (meth)acryloyloxy group, and a (meth)acryloylamide group. Among these, a (meth)allyl group, a (meth)acryloyl group, or a (meth)acryloyloxy group is preferable, and a (meth)acryloyloxy group is more preferable. The trivalent linking group represented by L¹¹ is preferably a group represented by Formula (L12-1), and more preferably a group represented by Formula (L12-2).

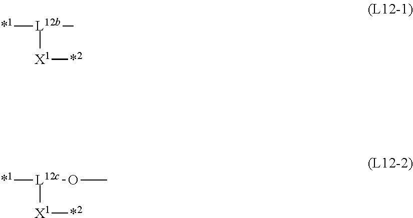

In Formula (L12-1), L^{12b} represents a trivalent linking group, X¹ represents S, *1 represents a bonding position with L¹¹ in Formula (b-10), and *2 represents a bonding position with P¹⁰ in Formula (b-10). Examples of the trivalent linking group represented by L^{12b} include a hydrocarbon group; and a group formed by a combination of a hydrocarbon group and at least one selected from —O—, —CO—, —COO—, —OCO—, —NH—, or —S—, and a hydrocarbon group or a group in which a hydrocarbon group and —O— are combined is preferable.

In Formula (L12-2), L^{12c} represents a trivalent linking group, X¹ represents S, *1 represents a bonding position with L¹¹ in Formula (b-10), and *2 represents a bonding position with P¹⁰ in Formula (b-10). Examples of the trivalent linking group represented by L^{12c} include a hydrocarbon group; and a group formed by a combination of a hydrocarbon group and at least one selected from —O—, —CO—, —COO—, —OCO—, —NH—, or —S—, and a hydrocarbon group is preferable.

In Formula (b-10), P¹⁰ represents a polymer chain. It is preferable that the polymer chain represented by P¹⁰ has at least one repeating unit selected from a poly(meth)acrylic repeating unit, a polyether repeating unit, a polyester repeating unit, or a polyol repeating unit. A weight-average molecular weight of the polymer chain P¹⁰ is preferably 500 to 20000. The lower limit is preferably 600 or more and more preferably 1000 or more. The upper limit is preferably 10000 or less, more preferably 5000 or less, and still more preferably 3000 or less.

Tt is also preferable that the polymer chain represented by P¹⁰ has a repeating unit having a crosslinkable group. According to this aspect, it is possible to form a film having more excellent moisture resistance. Examples of the crosslinkable group include an ethylenically unsaturated bond-containing group, a cyclic ether group, and a blocked isocyanate group, and an ethylenically unsaturated bond-containing group or a cyclic ether group is preferable and an ethylenically unsaturated bond-containing group is more preferable. Examples of the ethylenically unsaturated bond-containing group include a vinyl group, a vinylphenyl group, a (meth)allyl group, a (meth)acryloyl group, a (meth)acryloyloxy group, and a (meth)acryloylamide group. Among these, a (meth)allyl group, a (meth)acryloyl group, or a (meth)acryloyloxy group is preferable, and a (meth)acryloyloxy group is more preferable. Examples of the cyclic ether group include an epoxy group and an oxetanyl group. The blocked isocyanate group in the present invention is a group capable of generating an isocyanate group by heat, and preferred examples thereof include a group in which an isocyanate group is protected by reacting a blocking agent and an isocyanate group. Examples of the blocking agent include oxime compounds, lactam compounds, phenol compounds, alcohol compounds, amine compounds, active methylene compounds, pyrazole compounds, mercaptan compounds, imidazole compounds, and imide compounds. Examples of the blocking agent include compounds described in paragraph Nos. 0115 to 0117 of JP2017-067930A, the contents of which are incorporated herein by reference. In addition, the blocked isocyanate group is preferably a group capable of generating an isocyanate group by heat of 90° C. to 260° C.

Among these, the polymer chain represented by P¹⁰ preferably includes each of the ethylenically unsaturated bond-containing group and the cyclic ether group. According to this aspect, it is easy to form a film having more excellent moisture resistance. The reason why such an effect is obtained is that the glass transition temperature of the film increases due to thermal crosslinking of the ethylenically unsaturated bond-containing group or the cyclic ether group, and the generation of the water permeation channel in the film generated by the thermal motion of the first resin is more effectively suppressed. In addition, in a case where the polymer chain represented by P¹⁰ includes each of the ethylenically unsaturated bond-containing group and the cyclic ether group, the polymer chain represented by P¹⁰ is preferably a polymer chain which has a repeating unit having an ethylenically unsaturated bond-containing group and a repeating unit having a cyclic ether group. In addition, from the reason that the moisture resistance of the obtained film and the temporal stability of the coloring composition can be achieved at a high level, the above-described cyclic ether group is preferably an oxetanyl group. In addition, it is preferable that the above-described polymer chain further includes a repeating unit having a tertiary alkyl group. According to this aspect, the effect of improving the heat resistance of the film can be expected. From the reason that the heat resistance of the film can be further improved, the above-described tertiary alkyl group is preferably a tert-butyl group.

In a case where the polymer chain represented by P¹⁰ has a repeating unit having a crosslinkable group, a proportion of the repeating unit having a crosslinkable group in all repeating units constituting P¹⁰ is preferably 5% to 50% by mass, more preferably 15% to 45% by mass, and still more preferably 20% to 40% by mass.

In addition, it is also preferable that the polymer chain represented by P¹⁰ has a repeating unit having an acid group. Examples of the acid group include a carboxyl group, a phosphoric acid group, a sulfo group, and a phenolic hydroxy group. According to this aspect, the dispersibility of the colorant such as the pigment in the coloring composition can be further improved. Further, the developability can be further improved, and the generation of development residue can be further suppressed. In a case where the polymer chain represented by P¹⁰ has a repeating unit having an acid group, a proportion of the repeating unit having an acid group in all repeating units constituting P¹⁰ is preferably 1% to 30% by mass, more preferably 2% to 20% by mass, and still more preferably 3% to 10% by mass.

For example, the first resin can be manufactured through a first step of first producing a reaction product of a hydroxy group of a compound (a) having two hydroxy groups and one thiol group and an acid anhydride group of one or more aromatic acid anhydrides selected from aromatic tetracarboxylic acid anhydride and aromatic tricarboxylic acid anhydride; a second step of radically polymerizing a polymerizable monomer (c) which includes a polymerizable monomer (b) containing a hydroxy group and an ethylenically unsaturated bond-containing group using the thiol group remaining in the reaction product as a chain transfer agent to produce a hydroxy group-containing polymer into which a vinyl polymer moiety having a hydroxy group is introduced; and a third step which is a reaction with a compound (d) having one isocyanate group and one or more ethylenically unsaturated bond-containing groups. In addition, the first resin can also be synthesized according to the method described in paragraph Nos. 0018 to 0036 of JP2019-078878A.

A weight-average molecular weight of the first resin is preferably a value exceeding 3000, and more preferably 5000 to 15000. The upper limit of the weight-average molecular weight is preferably 13000 or less and more preferably 11000 or less. The lower limit of the weight-average molecular weight is preferably 6000 or more and more preferably 7000 or more. In a case where the weight-average molecular weight of the first resin is within the above-described range, the effects of the present invention are more remarkably obtained. In addition, storage stability of the coloring composition can also be improved.

An acid value of the first resin is preferably 5 to 200 mgKOH/g. The upper limit of the acid value is preferably 150 mgKOH/g or less and more preferably 100 mgKOH/g or less. The lower limit of the acid value is preferably 10 mgKOH/g or more and more preferably 20 mgKOH/g or more. In a case where the acid value of the first resin is within the above-described range, the effects of the present invention are more remarkably obtained. In addition, pigment adsorption ability can be appropriately obtained, and pigment dispersibility in the composition can be enhanced. Furthermore, the storage stability of the coloring composition can also be improved.

(Second Resin)

The coloring composition according to the embodiment of the present invention includes, as the second resin, at least one selected from a polyimide precursor, a polyimide resin, a polybenzoxazole precursor, a polybenzoxazole resin, or a polysiloxane resin. The second resin preferably includes at least one selected from a polyimide precursor, a polybenzoxazole precursor, or a polysiloxane resin, from the reason that it is easy to form a film having more excellent moisture resistance, it is more preferable to include at least one selected from a polyimide precursor or a polybenzoxazole precursor, and from the reason that it is possible to form a film having excellent solvent solubility, it is still more preferable to include a polyimide precursor.

[Polyimide Precursor]

The polyimide precursor preferably has a crosslinkable group. According to this aspect, it is possible to form a film having excellent moisture resistance and heat resistance.

Examples of the crosslinkable group include an ethylenically unsaturated bond-containing group and a cyclic ether group, and an ethylenically unsaturated bond-containing group is preferable. In a case where a polyimide precursor having an ethylenically unsaturated bond-containing group is used as the polyimide precursor, it is also possible to obtain a coloring composition having excellent pattern forming properties by a photolithography method. Examples of the ethylenically unsaturated bond-containing group include a vinyl group, a vinylphenyl group, a (meth)allyl group, a (meth)acryloyl group, a (meth)acryloyloxy group, and a (meth)acryloylamide group. Among these, a (meth)allyl group, a (meth)acryloyl group, or a (meth)acryloyloxy group is preferable, and a (meth)acryloyloxy group is more preferable. Examples of the cyclic ether group include an epoxy group and an oxetanyl group.

In addition, the polyimide precursor preferably includes a silicon atom. According to this aspect, it is possible to form a film having more excellent moisture resistance and heat resistance. The polyimide precursor including a silicon atom is preferably a polyimide precursor including a siloxane bond. It is also preferable that the polyimide precursor including a silicon atom further has a crosslinkable group.

Examples of the polyimide precursor include precursors including a constitutional unit represented by Formula (PI-1).

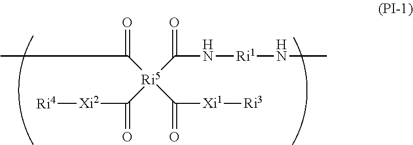

In the formula, Ri¹ represents a divalent organic group, Ri represents a tetravalent organic group, Ri³ and Ri⁴ each independently represent a hydrogen atom or a monovalent organic group, Xi¹ and Xi² each independently represent 0 or NRxi, and Rxi represents a hydrogen atom or a substituent.

Examples of the divalent organic group represented by Ri¹ include a group including an aliphatic hydrocarbon group, a group including an aromatic hydrocarbon group, and a group including a heterocyclic group. The divalent organic group represented by Ri¹ is preferably a group including a linear aliphatic hydrocarbon group having 2 to 20 carbon atoms, a branched aliphatic hydrocarbon group having 3 to 20 carbon atoms, a cyclic aliphatic hydrocarbon group having 3 to 20 carbon atoms, or an aromatic hydrocarbon group having 6 to 20 carbon atoms.

Ri¹ is preferably a group derived from diamine. The diamine is preferably a compound including a linear aliphatic hydrocarbon group having 2 to 20 carbon atoms, a branched aliphatic hydrocarbon group having 3 to 20 carbon atoms, a cyclic aliphatic hydrocarbon group having 3 to 20 carbon atoms, or an aromatic hydrocarbon group having 6 to 20 carbon atoms, and more preferably a compound including an aromatic hydrocarbon group having 6 to 20 carbon atoms. In addition, it is also preferable that the diamine is a compound including a silicon atom. The diamine including a silicon atom is more preferably a diamine including a siloxane bond. Specific examples of the diamine include compounds described in paragraph Nos. 0024 to 0029 of WO2017/209177A, the contents of which are incorporated herein by reference.

Ri¹ is preferably a group represented by —Ar¹-L¹-Ar²—. Ar¹ and Ar² are each independently preferably an aromatic hydrocarbon group (preferably an aromatic hydrocarbon group having 6 to 22 carbon atoms, more preferably an aromatic hydrocarbon group having 6 to 18 carbon atoms, and particularly preferably an aromatic hydrocarbon group having 6 to 10 carbon atoms). The aromatic hydrocarbon group may have a substituent. Examples of the substituent include an alkyl group, a halogen atom, and a hydroxy group, and a hydroxy group is preferable. L¹ represents a single bond or a divalent linking group. As the divalent linking group, an aliphatic hydrocarbon group having 1 to 10 carbon atoms, which may be substituted with a fluorine atom, or a group selected from —O—, —C(═O)—, —C(═O)O—, —S—, —S(═O)₂—, —NHCO—, and a combination thereof is preferable, an alkylene group having 1 to 3 carbon atoms, which may be substituted with a fluorine atom, or a group selected from —O—, —C(═O)—, —S—, —SO₂—, and —NHCO— is more preferable, and —CH₂—, —O—, —S—, —SO₂—, —C(CF₃)₂—, —C(CH₃)₂—, or —NHCO— is still more preferable.

In addition, from the reason that it is possible to form a film having excellent adhesiveness to a base, Ri¹ is also preferably a group represented by Formula (SR).

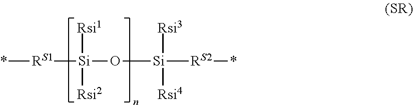

In the formula, R^{S1} and R^{S2} each independently represent a group including an aliphatic hydrocarbon group, a group including an aromatic hydrocarbon group, or a group including a heterocyclic group, Rsi¹ to Rsi⁴ each independently represent a hydrogen atom, an alkyl group, or an aryl group, and n represents an integer of 1 to 10.

R^{S1} and R^{S2} are each independently preferably a group including an aliphatic hydrocarbon group or a group including an aromatic hydrocarbon group, more preferably a group including an aliphatic hydrocarbon group, and still more preferably an aliphatic hydrocarbon group.

Rsi¹ to Rsi⁴ are each independently preferably an alkyl group or an aryl group, and more preferably an alkyl group.

The alkyl group represented by Rsi¹ to Rsi⁴ preferably has 1 to 10 carbon atoms, more preferably has 1 to 5 carbon atoms, and still more preferably 1 to 3 carbon atoms.

The aryl group represented by Rsi¹ to Rsi⁴ preferably has 6 to 22 carbon atoms, more preferably has 6 to 18 carbon atoms, and still more preferably 6 to 10 carbon atoms. n represents an integer of 1 to 10, and is preferably an integer of 1 to 5, more preferably 1 or 2, and still more preferably 1.

As the tetravalent organic group represented by Ri⁵, a group including an aromatic ring is preferable, and a group represented by Formula (Ri⁵-1) or Formula (Ri⁵-2) is more preferable.

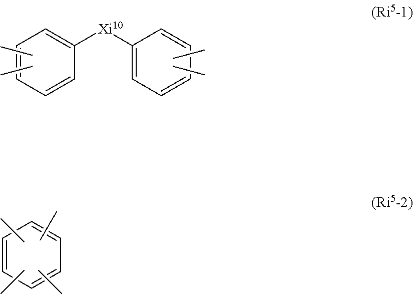

Xi¹⁰ represents a single bond or a divalent linking group. As the divalent linking group, an aliphatic hydrocarbon group having 1 to 10 carbon atoms, which may be substituted with a fluorine atom, or a group selected from —O—, —C(═O)—, —C(═O)O—, —S—, —S(═O)₂-, —NHCO—, and a combination thereof is preferable, an alkylene group having 1 to 3 carbon atoms, which may be substituted with a fluorine atom, or a group selected from —O—, —C(═O)—, —S—, and —SO₂— is more preferable, and —CH₂—, —O—, —S—, —SO₂—, —C(CF₃)₂—, or —C(CH₃)₂— is still more preferable.

Specific examples of the tetravalent organic group represented by Ri^{P} include a tetracarboxylic acid residue remaining after removing an acid dianhydride group from a tetracarboxylic dianhydride. The tetracarboxylic acid dianhydride may be used singly or two or more kinds thereof may be used. Specific examples of the tetracarboxylic acid dianhydride include compounds described in paragraphs 0035 to 0037 of WO2017/209177A, the contents of which are incorporated herein by reference.

Ri³ and Ri⁴ each independently represent a hydrogen atom or a monovalent organic group. Examples of the monovalent organic group include a group including a crosslinkable group, an acid-decomposable group, a hydrocarbon group, and a heterocyclic group. It is preferable that at least one of Ri³ or Ri¹ is a group including a crosslinkable group, and it is more preferable that both are groups including a crosslinkable group. Examples of the crosslinkable group include an ethylenically unsaturated bond-containing group and a cyclic ether group, and an ethylenically unsaturated bond-containing group is preferable. In a case of using a polyimide precursor including an ethylenically unsaturated bond-containing group, a film having more excellent characteristics can be easily obtained. In addition, in a case where the coloring composition according to the embodiment of the present invention includes a photopolymerization initiator, the coloring composition according to the embodiment of the present invention can be a coloring composition having excellent pattern forming properties by a photolithography method. Examples of the ethylenically unsaturated bond-containing group include a vinyl group, a vinylphenyl group, a (meth)allyl group, a (meth)acryloyl group, a (meth)acryloyloxy group, and a (meth)acryloylamide group. Among these, a (meth)allyl group, a (meth)acryloyl group, or a (meth)acryloyloxy group is preferable, and a (meth)acryloyloxy group is more preferable. Examples of the cyclic ether group include an epoxy group and an oxetanyl group.

Examples of the group including a crosslinkable group, represented by Ri³ and Ri⁴, include a group represented by -Rc¹-Rc². Rc¹ represents a single bond or a divalent linking group and Rc² represents a crosslinkable group. Examples of the divalent linking group represented by Rc¹ include an aliphatic hydrocarbon group, an aromatic hydrocarbon group, a heterocyclic group, and a group selected from a combination of these groups and at least one selected from —O—, —C(═O)—, —C(═O)O—, —S—, —S(═O)₂—, or —NHCO—. Examples of the crosslinkable group represented by Rc² include the above-described groups.

Examples of the acid-decomposable group represented by Ri³ and Ri⁴ include a tertiary alkyl group and an acetal-type acid-decomposable group. Examples of the above-described tertiary alkyl group include a t-butyl group. Examples of the above-described acetal-type acid-decomposable group include a 1-alkoxyalkyl group, a 2-tetrahydrofuranyl group, and a 2-tetrahydropyranyl group.

Examples of the hydrocarbon group represented by Ri³ and Ri⁴ include an alkyl group, an aryl group, and an arylalkyl group. The alkyl group preferably has 1 to 30 carbon atoms, more preferably has 1 to 15 carbon atoms, and still more preferably 1 to 8 carbon atoms. The alkyl group may be linear, branched, or cyclic, and is preferably linear or branched. The aryl group preferably has 6 to 30 carbon atoms, more preferably has 6 to 25 carbon atoms, and still more preferably has 6 to 12 carbon atoms. The arylalkyl group preferably has 7 to 30 carbon atoms, more preferably has 7 to 25 carbon atoms, and still more preferably 7 to 12 carbon atoms.

The heterocyclic group represented by Ri³ and Ri⁴ may be a single ring or a fused ring. The heterocyclic group is preferably a single ring or a fused ring having 2 to 4 fused numbers. The number of heteroatoms constituting a ring of the heterocyclic group is preferably 1 to 3. The heteroatom constituting the ring of the heterocyclic group is preferably a nitrogen atom, an oxygen atom, or a sulfur atom. The number of carbon atoms constituting the ring of the heterocyclic group is preferably 3 to 30, more preferably 3 to 18, and more preferably 3 to 12.

The hydrocarbon group and heterocyclic group represented by Ri³ and Ri⁴ may have a substituent or may be unsubstituted. Examples of the substituent include acid groups such as a hydroxy group, a carboxyl group, a sulfo group, a phosphoric acid group, and a phosphonic acid group; groups in which these acid groups are protected by an acid-decomposable group; and crosslinkable groups.

Xi¹ and Xi² each independently represent O or NRxi, in which Rxi represents a hydrogen atom or a substituent. Examples of the substituent represented by Rxi include an alkyl group, an aryl group, an alkoxy group, an aryloxy group, and an acyl group. Rxi is preferably a hydrogen atom. Xi¹ and Xi² are preferably O.

In the polyimide precursor, the constitutional unit represented by Formula (PI-1) may be one kind or two or more kinds. In addition, the polyimide precursor may include a structural isomer of the constitutional unit represented by Formula (PI-1). In addition, the polyimide precursor may include other types of constitutional units in addition to the constitutional unit represented by Formula (PI-1).

As one embodiment of the polyimide precursor, a polyimide precursor in which 50 mol % or more, still 70 mol % or more, particularly 90 mol % or more of all constitutional units are the constitutional unit represented by Formula (PI-1) is mentioned.

As the polyimide precursor, polyimide precursors described in paragraph Nos. 0015 to 0029 of JP2017-186530A, paragraph Nos. 0030 to 0036 of JP2019-023728A, and paragraph Nos. 0029 to 0035 of JP2019-045865A can also be used, the contents of which are incorporated herein by reference.

A weight-average molecular weight (Mw) of the polyimide precursor is preferably 2000 to 500000, more preferably 5000 to 100000, and still more preferably 10000 to 50000. In addition, a number-average molecular weight (Mn) thereof is preferably 800 to 250000, more preferably 2000 to 50000, and still more preferably 4000 to 25000.

A degree of dispersion of the molecular weight of the polyimide precursor is preferably 1.5 to 3.5 and more preferably 2 to 3.

[Polyimide Resin]

Examples of the polyimide resin include a resin having a polyimide ring. Examples thereof include a resin obtained by cyclizing a polyimide precursor. Examples of the polyimide precursor include those described above.

The polyimide resin preferably has a crosslinkable group. According to this aspect, a film having excellent moisture resistance and heat resistance is easily obtained. Examples of the crosslinkable group are as described above.

In addition, the polyimide resin preferably includes a silicon atom, and more preferably includes a siloxane bond. According to this aspect, a film having excellent moisture resistance and heat resistance is easily obtained.

In addition, it is also preferable that the polyimide resin has at least one group selected from a carboxyl group, a sulfo group, a phosphoric acid group, or a phosphonic acid group in at least one of the main chain or the side chain. According to this aspect, a polyimide resin having excellent solubility in an alkali developer can be obtained.

[Polybenzoxazole Precursor]

The polybenzoxazole precursor preferably has a crosslinkable group. According to this aspect, it is possible to form a film having excellent moisture resistance and heat resistance. Examples of the crosslinkable group include an ethylenically unsaturated bond-containing group and a cyclic ether group, and an ethylenically unsaturated bond-containing group is preferable. In a case where a polybenzoxazole precursor having an ethylenically unsaturated bond-containing group is used as the polybenzoxazole precursor, it is also possible to obtain a coloring composition having excellent pattern forming properties by a photolithography method. Examples of the crosslinkable group are as described above.

In addition, the polybenzoxazole precursor preferably includes a silicon atom. According to this aspect, it is possible to form a film having excellent moisture resistance and heat resistance. The polybenzoxazole precursor including a silicon atom is preferably a polybenzoxazole precursor including a siloxane bond. It is also preferable that the polybenzoxazole precursor including a silicon atom further has a crosslinkable group.

Examples of the polybenzoxazole precursor include precursors including a constitutional unit represented by Formula (PBO-1).

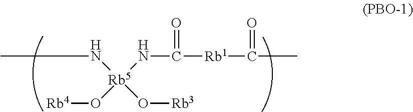

Rb¹ represents a divalent organic group, Rb³ represents a tetravalent organic group, and Rb³ and Rb⁴ each independently represent a hydrogen atom or a monovalent organic group.

Examples of divalent organic group represented by Rb¹ of Formula (PBO-1) include a group including an aliphatic hydrocarbon group, a group including an aromatic hydrocarbon group, and a group including a heterocyclic group. The divalent organic group represented by Rb¹ is preferably a group including a linear aliphatic hydrocarbon group having 2 to 20 carbon atoms, a branched aliphatic hydrocarbon group having 3 to 20 carbon atoms, a cyclic aliphatic hydrocarbon group having 3 to 20 carbon atoms, or an aromatic hydrocarbon group having 6 to 20 carbon atoms.

As the tetravalent organic group represented by Rb³ in Formula (PBO-1), a group including an aromatic ring is preferable, and the group represented by Formula (Ri⁵-1) or Formula (Ri⁵-2) described above is more preferable.

Examples of the monovalent organic group represented by Rb³ and Rb¹ in Formula (PBO-1) include a group including a crosslinkable group, an acid-decomposable group, a hydrocarbon group, and a heterocyclic group. It is preferable that at least one of Rb³ or Rb¹ is a group including a crosslinkable group, and it is more preferable that both are groups including a crosslinkable group. Examples of details of the group including a crosslinkable group, acid-decomposable group, hydrocarbon group, and heterocyclic group include those described in the section of monovalent organic group represented Ri³ and Ri⁴ in Formula (PI-1), and the same applies to the preferred range.

In the polybenzoxazole precursor, the constitutional unit represented by Formula (PBO-1) may be one kind or two or more kinds. In addition, the polybenzoxazole precursor may include a structural isomer of the constitutional unit represented by Formula (PBO-1). In addition, the polybenzoxazole precursor may include other types of constitutional units in addition to the constitutional unit represented by Formula (PBO-1).

Examples of other constitutional units include a constitutional unit represented by Formula (SL-1).

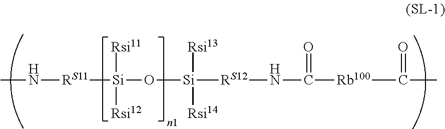

In Formula (SL-1), R^{S11} and R^{S12} each independently represent a group including an aliphatic hydrocarbon group, a group including an aromatic hydrocarbon group, or a group including a heterocyclic group, Rsi¹¹ to Rsi¹⁴ each independently represent a hydrogen atom, an alkyl group, or an aryl group, n represents an integer of 1 to 10, and Rb¹⁰⁰ represents a divalent organic group.

R^{S11} and R^{S12} of Formula (SL-1) are each independently preferably a group including an aliphatic hydrocarbon group or a group including an aromatic hydrocarbon group, more preferably a group including an aliphatic hydrocarbon group, and still more preferably an aliphatic hydrocarbon group.

Rsi¹¹ to Rsi¹⁴ of Formula (SL-1) are each independently preferably an alkyl group or an aryl group, and more preferably an alkyl group.

The alkyl group represented by Rsi¹¹ to Rsi¹⁴ preferably has 1 to 10 carbon atoms, more preferably has 1 to 5 carbon atoms, and still more preferably 1 to 3 carbon atoms.

The aryl group represented by Rsi¹¹ to Rsi¹⁴ preferably has 6 to 22 carbon atoms, more preferably has 6 to 18 carbon atoms, and still more preferably 6 to 10 carbon atoms.

n1 in Formula (SL-1) represents an integer of 1 to 10, and is preferably an integer of 1 or 5, more preferably 1 or 2, and still more preferably 1.

Examples of the divalent organic group represented by Rb¹⁰⁰ include a group including an aliphatic hydrocarbon group, a group including an aromatic hydrocarbon group, and a group including a heterocyclic group. The divalent organic group represented by Rb¹⁰⁰ is preferably a group including a linear aliphatic hydrocarbon group having 2 to 20 carbon atoms, a branched aliphatic hydrocarbon group having 3 to 20 carbon atoms, a cyclic aliphatic hydrocarbon group having 3 to 20 carbon atoms, or an aromatic hydrocarbon group having 6 to 20 carbon atoms.

A weight-average molecular weight (Mw) of the polybenzoxazole precursor is preferably 2000 to 500000, more preferably 5000 to 100000, and still more preferably 10000 to 50000. In addition, a number-average molecular weight (Mn) thereof is preferably 800 to 250000, more preferably 2000 to 50000, and still more preferably 4000 to 25000.

A degree of dispersion of the molecular weight of the polybenzoxazole precursor is preferably 1.5 to 3.5 and more preferably 2 to 3.

[Polybenzoxazole Resin]

Examples of the polybenzoxazole resin include a resin having a polybenzoxazole ring. Examples thereof include a resin obtained by cyclizing a polybenzoxazole precursor. Examples of the polybenzoxazole precursor include those described above.

The polybenzoxazole resin preferably has a crosslinkable group. According to this aspect, a film having excellent moisture resistance and heat resistance is easily obtained. Examples of the crosslinkable group are as described above.

In addition, the polybenzoxazole resin preferably includes a silicon atom, and more preferably includes a siloxane bond. According to this aspect, a film having excellent moisture resistance and heat resistance is easily obtained.

In addition, it is also preferable that the polybenzoxazole resin has at least one group selected from a carboxyl group, a sulfo group, a phosphoric acid group, or a phosphonic group in at least one of the main chain or the side chain. According to this aspect, a polybenzoxazole resin having excellent solubility in an alkali developer can be obtained.

[Polysiloxane Resin]

Examples of the polysiloxane resin include a resin having a repeating unit including a siloxane bond. In the polysiloxane resin, the repeating unit including a siloxane bond may be included in the main chain or the side chain. Examples of the polysiloxane resin include an epoxy-modified polysiloxane resin, a polyester-modified polysiloxane resin, an alkyd-modified polysiloxane resin, a urethane-modified polysiloxane resin, and an acrylic-modified polysiloxane resin, and from the reason that it is easy to form a film having more excellent moisture resistance and heat resistance, an epoxy-modified polysiloxane resin or a polyester-modified polysiloxane resin is preferable, and an epoxy-modified polysiloxane resin is more preferable.

In addition, from the reason that the effects of the present invention are more remarkably exhibited, the polysiloxane resin preferably has at least one group selected from an alkylsilyl group or an alkoxysilyl group, and more preferably has an alkoxysilyl group.

In addition, it is also preferable that the polysiloxane resin has a crosslinkable group. According to this aspect, it is possible to form a film having excellent moisture resistance and heat resistance. Examples of the crosslinkable group include an ethylenically unsaturated bond-containing group and a cyclic ether group. Examples of the crosslinkable group are as described above.

A weight-average molecular weight (Mw) of the polysiloxane resin is preferably 500 to 1000000, more preferably 1000 to 100000, and still more preferably 2000 to 20000.

Examples of one aspect of the polysiloxane resin include a reactant of a compound having a hydroxy group and an epoxy group with a silsesquioxane compound containing an epoxy group and an alkoxy group. The polysiloxane resin of this embodiment preferably has an epoxy group. In addition, an epoxy equivalent of the polysiloxane resin of this embodiment is preferably 150 to 500 g/eq. In addition, with regard to the polysiloxane resin of this embodiment, the ratio of the number of moles of epoxy groups derived from the compound having a hydroxy group and an epoxy group and the number of moles of epoxy groups derived from the silsesquioxane compound containing an epoxy group and an alkoxy group ((number of moles of epoxy groups derived from the compound having a hydroxy group and an epoxy group)/(number of moles of epoxy groups derived from the silsesquioxane compound containing an epoxy group and an alkoxy group)) is preferably 0.1 to 3. In addition, it is also preferable that the polysiloxane resin of this embodiment has an alkoxy group. An amount of the alkoxy group included in the polysiloxane resin is preferably 150 to 3000 g/eq.

Examples of the above-described compound having a hydroxy group and an epoxy group include bisphenol-type epoxy resins such as a bisphenol A-type epoxy resin, a bisphenol F-type epoxy resin, and a bisphenol S-type epoxy resin, a hydrogenated bisphenol type epoxy resin with nuclear hydrogenated benzene ring of epoxy resin, a phenolic novolac-type epoxy resin, a cresol novolac-type epoxy resin, a biphenol-type epoxy resin, and a naphthalene-type epoxy resin.

The average number of hydroxy groups included in the compound having a hydroxy group and an epoxy group is preferably 0.3 to 5.

Examples of the above-described silsesquioxane compound having an epoxy group and an alkoxy group include a compound obtained by hydrolyzing and condensing a compound represented by Formula (Si-1).

Rs¹Si(ORs²)₃ (Si-1)

(in the formula, Rs¹ represents a hydrocarbon group having 3 to 8 carbon atoms, which has an epoxy group, and R^{S2} represents a hydrogen atom or a hydrocarbon group having 1 to 4 carbon atoms)

Specific examples of the compound represented by Formula (Si-1) include glycydoxypropyltrialkoxysilanes such as 3-glycidoxypropyltrimethoxysilane, 3-glycidoxypropyltriethoxysilane, and 3-glycidoxypropyltripropoxysilane; and (epoxycyclohexyl)ethyltrialkoxysilanes such as 2-(3,4-epoxycyclohexyl)ethyltrimethoxysilane, 2-(3,4-epoxycyclohexyl)ethyltriethoxysilane, and 2-(3,4-epoxycyclohexyl)ethyltripropoxysilane.

In addition to the above-described compound represented by Formula (Si-1), metal alkoxides which do not contain an epoxy group, such as trialkylalkoxysilanes such as trimethylmethoxysilane, trimethylethoxysilane, triethylmethoxysilane, triethylethoxysilane, triphenylmethoxysilane, and triphenylethoxysilane; dialkyldialkoxysilanes such as dimethyldimethoxysilane, dimethyldiethoxysilane, diethyldimethoxysilane, diethyldiethoxysilane, diphenyldimethoxysilane, diphenyldiethoxysilane, methylphenyldimethoxysilane, methylphenyldiethoxysilane, and 3-mercaptopropylmethyldimethoxysilane; alkyltrialkoxysilanes such as methyltrimethoxysilane, methyltriethoxysilane, ethyltrimethoxysilane, ethyltriethoxysilane, phenyltrimethoxysilane, and phenyltriethoxysilane; tetraalkoxysilanes such as tetramethoxysilane, tetraethoxysilane, tetrapropoxysilane, and tetrabutoxysilane; tetraalkoxytitaniums such as tetramethoxytitanium, tetraethoxytitanium, tetrapropoxytitanium, and tetrabutoxytitanium; and tetraalkoxyzirconiums such as tetraethoxyzirconium, tetrapropoxyzirconium, and tetrabutoxyzirconium, may be further used in combination.

(Total of the number of moles of alkoxy groups included in the compound represented by Formula (Si-1) and the number of moles of alkoxy groups included in the metal alkoxides)/(total of the number of moles of the compound represented by Formula (Si-1) and the number of moles of the metal alkoxides) is preferably 2.5 to 3.5 and more preferably 2.7 to 3.2.

By hydrolyzing and condensing the compound represented by Formula (Si-1) or a mixture of the compound represented by Formula (Si-1) and the above-described metal alkoxides, the silsesquioxane compound containing an epoxy group and an alkoxy group is obtained. By the hydrolysis reaction, the alkoxy group included in the compound represented by Formula (Si-1) and the above-described metal alkoxides forms a silanol group, and an alcohol is by-produced. As an amount of water required for the hydrolysis reaction, (number of moles of water used for the hydrolysis reaction)/(total number of moles of each alkoxy group included in the compound represented by Formula (Si-1) and the metal alkoxides) is preferably 0.2 to 1 and more preferably 0.3 to 0.7.

In reacting the compound having a hydroxy group and an epoxy group with the silsesquioxane compound having an epoxy group and an alkoxy group to obtain a polysiloxane resin which is a reactant thereof, the proportion of use of the compound having a hydroxy group and an epoxy group and the silsesquioxane compound having an epoxy group and an alkoxy group is preferably 20 to 800 parts by mass of the silsesquioxane compound having an epoxy group and an alkoxy group, and more preferably 50 to 500 parts by mass of the silsesquioxane compound having an epoxy group and an alkoxy group with respect to 100 parts by mass of the compound having a hydroxy group and an epoxy group.

Specific examples of the polysiloxane resin include compounds having the following structures.

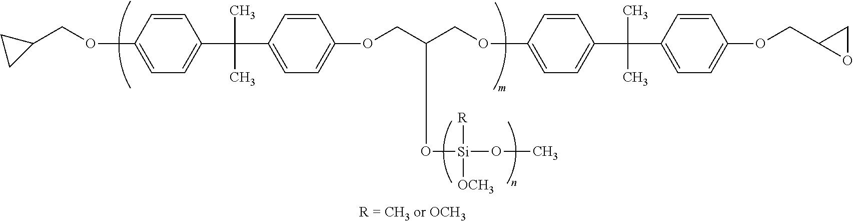

Examples of a commercially available product of the polysiloxane resin include KR-5230, RK-5234, and KR-5235 (all of which are manufactured by Shin-Etsu Chemical Co., Ltd.), and COMPOCERAN E103A, E103D, and E203 (all of which are manufactured by Arakawa Chemical Industries, Ltd.).

(Third Resin)

The coloring composition according to the embodiment of the present invention can further include a resin other than the above-described first resin and second resin (hereinafter, also referred to as a third resin). The third resin may be a resin as a binder or a resin as a dispersant.

A weight-average molecular weight (Mw) of the third resin is preferably a value exceeding 3000. The upper limit of the weight-average molecular weight (Mw) is preferably 1000000 or less and more preferably 500000 or less. The lower limit of the weight-average molecular weight (Mw) is preferably 3500 or more, more preferably 4000 or more, and still more preferably 5000 or more.

Examples of the third resin include a (meth)acrylic resin, a (meth)acrylamide resin, an epoxy resin, an ene-thiol resin, a polycarbonate resin, a polyether resin, a polyarylate resin, a polysulfone resin, a polyethersulfone resin, a polyphenylene resin, a polyarylene ether phosphine oxide resin, a polyolefin resin, a cyclic olefin resin, a polyester resin, a styrene resin, and a polyimine resin.

The third resin is also preferably a resin having an acid group. Examples of the acid group include a carboxyl group, a phosphoric acid group, a sulfo group, and a phenolic hydroxy group. The resin having an acid group can also be used as an alkali-soluble resin or a dispersant. An acid value of the resin having an acid group is preferably 30 to 500 mgKOH/g. The lower limit is more preferably 50 mgKOH/g or more and still more preferably 70 mgKOH/g or more. The upper limit is more preferably 400 mgKOH/g or less, still more preferably 200 mgKOH/g or less, even still more preferably 150 mgKOH/g or less, and most preferably 120 mgKOH/g or less.

The third resin is also preferably a resin including a repeating unit derived from a compound represented by Formula (ED1) and/or a compound represented by Formula (ED2) (hereinafter, these compounds will also be referred to as an “ether dimer”).

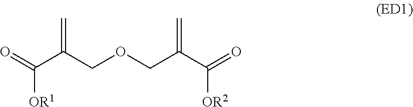

In Formula (ED1), R¹ and R² each independently represent a hydrogen atom or a hydrocarbon group having 1 to 25 carbon atoms, which may have a substituent.

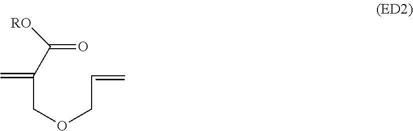

In Formula (ED2), R represents a hydrogen atom or an organic group having 1 to 30 carbon atoms. Specific examples of Formula (ED2) can be found in the description of JP2010-168539A.

Specific examples of the ether dimer can be found in paragraph No. 0317 of JP2013-029760A, the contents of which are incorporated herein by reference.

The third resin is also preferably a resin having an ethylenically unsaturated bond-containing group. Examples of the ethylenically unsaturated bond-containing group include a vinyl group, a vinylphenyl group, a (meth)allyl group, a (meth)acryloyl group, a (meth)acryloyloxy group, and a (meth)acryloylamide group. Among these, a (meth)allyl group, a (meth)acryloyl group, or a (meth)acryloyloxy group is preferable, and a (meth)acryloyloxy group is more preferable.

The third resin also preferably includes a resin including a repeating unit derived from a compound represented by Formula (X).

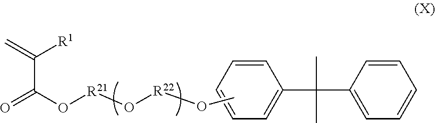

In the formula, R¹ represents a hydrogen atom or a methyl group, R²¹ and R² each independently represent an alkylene group, and n represents an integer of 0 to 15. The number of carbon atoms in the alkylene group represented by R²¹ and Ru is preferably 1 to 10, more preferably 1 to 5, still more preferably 1 to 3, and particularly preferably 2 or 3. n represents an integer of 0 to 15, and is preferably an integer of 0 or 5, more preferably an integer of 0 to 4, and still more preferably an integer of 0 to 3.

Examples of the compound represented by Formula (X) include ethylene oxide- or propylene oxide-modified (meth)acrylate of para-cumylphenol. Examples of a commercially available product thereof include ARONIX M-110 (manufactured by TOAGOSEI CO., LTD.).

The third resin may be a resin as a dispersant. Examples of the dispersant include an acidic dispersant (acidic resin) and a basic dispersant (basic resin). Here, the acidic dispersant (acidic resin) represents a resin in which the amount of the acid group is larger than the amount of the basic group. The acidic dispersant (acidic resin) is preferably a resin in which the amount of the acid group occupies 70 mol % or more in a case where the total amount of the acid group and the basic group is 100 mol %, and more preferably a resin substantially consisting of only an acid group. The acid group included in the acidic dispersant (acidic resin) is preferably a carboxyl group. An acid value of the acidic dispersant (acidic resin) is preferably 10 to 105 mgKOH/g. In addition, the basic dispersant (basic resin) represents a resin in which the amount of the basic group is larger than the amount of the acid group. The basic dispersant (basic resin) is preferably a resin in which the amount of the basic group is more than 50 mol % in a case where the total amount of the acid group and the basic group is 100 mol %. The basic group included in the basic dispersant is preferably an amino group.

The resin used as a dispersant preferably includes a repeating unit having an acid group.

In a case where the resin used as a dispersant includes a repeating unit having an acid group, the generation of the development residue can be further suppressed in the formation of a pattern by a photolithography method.

It is also preferable that the resin used as a dispersant is a graft resin. With regard to details of the graft resin, reference can be made to the description in paragraph Nos. 0025 to 0094 of JP2012-255128A, the contents of which are incorporated herein by reference.

It is also preferable that the resin used as a dispersant is a polyimine-based dispersant including a nitrogen atom in at least one of the main chain or the side chain. As the polyimine-based dispersant, a resin having a main chain which has a partial structure having a functional group of pKa 14 or less, and a side chain which has 40 to 10000 atoms, in which at least one of the main chain or the side chain has a basic nitrogen atom, is preferable. The basic nitrogen atom is not particularly limited as long as it is a nitrogen atom exhibiting basicity. With regard to the polyimine-based dispersant, reference can be made to the description in paragraph Nos. 0102 to 0166 of JP2012-255128A, the contents of which are incorporated herein by reference.

It is also preferable that the resin used as a dispersant is a resin having a structure in which a plurality of polymer chains are bonded to a core portion. Examples of such a resin include dendrimers (including star polymers). In addition, specific examples of the dendrimer include polymer compounds C-1 to C-31 described in paragraph Nos. 0196 to 0209 of JP2013-043962A.

A commercially available product is also available as the dispersant, and specific examples thereof include DISPERBYK series (for example, DISPERBYK-111, 2001, and the like) manufactured by BYK-Chemie Japan K.K., Solsperse series (for example, Solsperse 20000, 76500, and the like) manufactured by Lubrizol Corporation, and AJISPER series manufactured by Ajinomoto Fine-Techno Co., Inc. In addition, products described in paragraph No. 0129 of JP2012-137564A and products described in paragraph No. 0235 of JP2017-194662A can also be used as the dispersant.

In addition, as the third resin, the resin described in JP6349629B can also be used. In addition, as the resin as a dispersant or the alkali-soluble resin, a resin in which an acid anhydride is reacted with a hydroxy group generated by an epoxy ring opening to introduce an acid group may be used.

A content of the resin in the total solid content of the coloring composition is preferably 10% to 60% by mass. The lower limit is preferably 20% by mass or more and more preferably 30% by mass or more. The upper limit is preferably 55% by mass or less and more preferably 50% by mass or less.

A content of the first resin in the total solid content of the coloring composition is preferably 0.5% to 10% by mass. The lower limit is preferably 1% by mass or more and more preferably 2% by mass or more. The upper limit is preferably 9% by mass or less and more preferably 8% by mass or less.

In addition, a content of the second resin in the total solid content of the coloring composition is preferably 10% to 50% by mass. The lower limit is preferably 15% by mass or more and more preferably 20% by mass or more. The upper limit is preferably 40% by mass or less and more preferably 30% by mass or less.

In addition, from the reason that the effects of the present invention are more remarkably exhibited, the coloring composition preferably includes 100 to 1600 parts by mass of the second resin with respect to 100 parts by mass of the first resin. The lower limit is preferably 200 parts by mass or more and more preferably 300 parts by mass or more. The upper limit is preferably 1000 parts by mass or less and more preferably 600 parts by mass or less.

In addition, in a case where the second resin is a polyimide precursor, it is preferable to include 200 to 1400 parts by mass of the second resin with respect to 100 parts by mass of the first resin. The lower limit is preferably 300 parts by mass or more and more preferably 600 parts by mass or more. The upper limit is preferably 1200 parts by mass or less and more preferably 1000 parts by mass or less.

In addition, in a case where the second resin is a polybenzoxazole precursor, it is preferable to include 100 to 1600 parts by mass of the second resin with respect to 100 parts by mass of the first resin. The lower limit is preferably 200 parts by mass or more and more preferably 300 parts by mass or more. The upper limit is preferably 1000 parts by mass or less and more preferably 600 parts by mass or less.

In addition, in a case where the second resin is a polysiloxane resin, it is preferable to include 100 to 1600 parts by mass of the second resin with respect to 100 parts by mass of the first resin. The lower limit is preferably 200 parts by mass or more and more preferably 300 parts by mass or more. The upper limit is preferably 1000 parts by mass or less and more preferably 600 parts by mass or less.

From the reason that the effects of the present invention are excellent, the total content of the first resin and the second resin in the resins included in the coloring composition is preferably 70% to 100% by mass, more preferably 80% to 100% by mass, and still more preferably 90% to 100% by mass.

<<Polymerizable Monomer>>

It is preferable that the coloring composition according to the embodiment of the present invention contains a polymerizable monomer. Examples of the polymerizable monomer include a compound having an ethylenically unsaturated bond-containing group.

Examples of the ethylenically unsaturated bond-containing group include a vinyl group, a vinylphenyl group, a (meth)allyl group, a (meth)acryloyl group, a (meth)acryloyloxy group, and a (meth)acryloylamide group. Among these, a (meth)allyl group, a (meth)acryloyl group, or a (meth)acryloyloxy group is preferable, and a (meth)acryloyloxy group is more preferable.

The polymerizable monomer used in the present invention is preferably a radically polymerizable monomer.

A molecular weight of the polymerizable monomer is preferably 100 to 3000. The upper limit is more preferably 2000 or less and still more preferably 1500 or less. The lower limit is more preferably 150 or more and still more preferably 250 or more.

An ethylenically unsaturated bond-containing group value (hereinafter, referred to as a C═C value) of the polymerizable monomer is preferably 90 to 300 g/mol. The lower limit is preferably 93 g/mol or more and particularly preferably 96 g/mol or more. The upper limit is preferably 250 g/mol or less and particularly preferably 200 g/mol or less. The C═C value of the polymerizable monomer is calculated by dividing the molecular weight of the polymerizable monomer by the number of ethylenically unsaturated bond groups included in one molecule of the polymerizable monomer.

The polymerizable monomer is preferably a compound including 3 or more ethylenically unsaturated bond-containing groups, more preferably a compound including 3 to 15 ethylenically unsaturated bond-containing groups, and still more preferably a compound including 3 to 6 ethylenically unsaturated bond-containing groups. In addition, the polymerizable monomer is preferably a 3- to 15-functional (meth)acrylate compound and more preferably a 3- to 6-functional (meth)acrylate compound. Specific examples of the polymerizable monomer include the compounds described in paragraph Nos. 0095 to 0108 of JP2009-288705A, paragraph No. 0227 of JP2013-029760A, paragraph Nos. 0254 to 0257 of JP2008-292970A, paragraph Nos. 0034 to 0038 of JP2013-253224A, paragraph No. 0477 of JP2012-208494A, JP2017-048367A, JP6057891B, JP6031807B, and JP2017-194662A, the contents of which are incorporated herein by reference.

As the polymerizable monomer, dipentaerythritol tri(meth)acrylate (as a commercially available product, KAYARAD D-330 manufactured by Nippon Kayaku Co., Ltd.), dipentaerythritol tetra(meth)acrylate (as a commercially available product, KAYARAD D-320 manufactured by Nippon Kayaku Co., Ltd.), dipentaerythritol penta(meth)acrylate (as a commercially available product, KAYARAD D-310 manufactured by Nippon Kayaku Co., Ltd.), dipentaerythritol hexa(meth)acrylate (as a commercially available product, KAYARAD DPHA manufactured by Nippon Kayaku Co., Ltd., NK ESTER A-DPH-12E manufactured by Shin-Nakamura Chemical Co., Ltd.), or a compound having a structure in which these (meth)acryloyl groups are bonded through an ethylene glycol and/or a propylene glycol residue (for example, SR454 and SR499 which are commercially available products from Sartomer Company Inc.) is preferable. In addition, as the polymerizable monomer, diglycerin ethylene oxide (EO)-modified (meth)acrylate (as a commercially available product, M-460 manufactured by TOAGOSEI CO., LTD.), pentaerythritol tetraacrylate (NK ESTER A-TMMT manufactured by Shin-Nakamura Chemical Co., Ltd.), 1,6-hexanediol diacrylate (KAYARAD HDDA manufactured by Nippon Kayaku Co., Ltd.), RP-1040 (manufactured by Nippon Kayaku Co., Ltd.), ARONIX TO-2349 (manufactured by TOAGOSEI CO., LTD.), NK OLIGO UA-7200 (manufactured by Shin-Nakamura Chemical Co., Ltd.), 8UH-1006 and 8UH-1012 (manufactured by Taisei Fine Chemical Co., Ltd.), Light Acrylate POB-AO (manufactured by KYOEISHA CHEMICAL Co., Ltd.), and the like can also be used.

As the polymerizable monomer, it is also preferable to use a trifunctional (meth)acrylate compound such as trimethylolpropane tri(meth)acrylate, trimethylolpropane propyleneoxide-modified tri(meth)acrylate, trimethylolpropane ethyleneoxide-modified tri(meth)acrylate, isocyanuric acid ethyleneoxide-modified tri(meth)acrylate, and pentaerythritol tri(meth)acrylate. Examples of a commercially available product of the trifunctional (meth)acrylate compound include ARONIX M-309, M-310, M-321, M-350, M-360, M-313, M-315, M-306, M-305, M-303, M-452, and M-450 (manufactured by TOAGOSEI CO., LTD.), NK ESTER A9300, A-GLY-9E, A-GLY-20E, A-TMM-3, A-TMM-3L, A-TMM-3LM-N, A-TMPT, and TMPT (manufactured by Shin-Nakamura Chemical Co., Ltd.), and KAYARAD GPO-303, TMPTA, THE-330, TPA-330, and PET-30 (manufactured by Nippon Kayaku Co., Ltd.).

As the polymerizable monomer, a polymerizable monomer having an acid group can also be used. By using a polymerizable monomer having an acid group, a coloring composition in a non-exposed portion is easily removed during development and the generation of the development residue can be suppressed. Examples of the acid group include a carboxyl group, a sulfo group, and a phosphoric acid group, and a carboxyl group is preferable. Examples of a commercially available product of the polymerizable monomer having an acid group include ARONIX M-305, M-510, M-520, and ARONIX TO-2349 (manufactured by TOAGOSEI CO., LTD). An acid value of the polymerizable monomer having an acid group is preferably 0.1 to 40 mgKOH/g and more preferably 5 to 30 mgKOH/g.

As the polymerizable monomer, a polymerizable monomer having a caprolactone structure can also be used. Examples of the polymerizable monomer having a caprolactone structure include DPCA-20, DPCA-30, DPCA-60, and DPCA-120, each of which is commercially available as KAYARAD DPCA series from Nippon Kayaku Co., Ltd.

As the polymerizable monomer, a polymerizable monomer having an alkyleneoxy group can also be used. The polymerizable monomer having an alkyleneoxy group is preferably a polymerizable monomer having an ethyleneoxy group and/or a propyleneoxy group, more preferably a polymerizable monomer having an ethyleneoxy group, and still more preferably a trifunctional to hexafunctional (meth)acrylate compound having 4 to 20 ethyleneoxy groups. Examples of a commercially available product of the polymerizable monomer having an alkyleneoxy group include SR-494 manufactured by Sartomer Company Inc., which is a tetrafunctional (meth)acrylate having 4 ethyleneoxy groups, and KAYARAD TPA-330 manufactured by Nippon Kayaku Co., Ltd., which is a trifunctional (meth)acrylate having 3 isobutyleneoxy groups.

As the polymerizable monomer, a polymerizable monomer having a fluorene skeleton can also be used. Examples of a commercially available product of the polymerizable monomer having a fluorene skeleton include OGSOL EA-0200 and EA-0300 (manufactured by Osaka Gas Chemicals Co., Ltd., a (meth)acrylate monomer having a fluorene skeleton).

As the polymerizable monomer, it is also preferable to use a compound which does not substantially include environmentally regulated substances such as toluene. Examples of a commercially available product of such a compound include KAYARAD DPHA LT and KAYARAD DPEA-12 LT (manufactured by Nippon Kayaku Co., Ltd.).

The urethane acrylates described in JP1973-041708B (JP-S48-041708B), JP1976-037193A (JP-S51-037193A), JP1990-032293B (JP-H02-032293B), or JP1990-016765B (JP-H02-016765B), or the urethane compounds having an ethylene oxide skeleton described in JP1983-049860B (JP-S58-049860B), JP1981-017654B (JP-S56-017654B), JP1987-039417B (JP-S62-039417B), or JP1987-039418B (JP-S62-039418B) are also suitable as the polymerizable monomer. In addition, the polymerizable monomers having an amino structure or a sulfide structure in the molecule, described in JP1988-277653A (JP-S63-277653A), JP1988-260909A (JP-S63-260909A), or JP1989-105238A (JP-HO1-105238A), are also preferably used. In addition, as the polymerizable monomer, commercially available products such as UA-7200 (manufactured by Shin-Nakamura Chemical Co., Ltd.), DPHA-40H (manufactured by Nippon Kayaku Co., Ltd.), and UA-306H, UA-306T, UA-306I, AH-600, T-600, AI-600, and LINC-202UA (manufactured by KYOEISHA CHEMICAL Co., Ltd.) can also be used.

The polymerizable monomer used in the coloring composition according to the embodiment of the present invention preferably includes a tri- or lower functional polymerizable monomer C1 having 2 or 3 ethylenically unsaturated bond-containing groups and a tetra- or higher functional polymerizable monomer C2 having 4 or more ethylenically unsaturated bond-containing groups. According to this aspect, the effects of the present invention are more remarkably exhibited. In a case where the polymerizable monomer C1 and the polymerizable monomer C2 are used in combination, a proportion of both is preferably 10 to 1000 parts by mass, more preferably 30 to 300 parts by mass, and still more preferably 50 to 200 parts by mass of the polymerizable monomer C2 with respect to 100 parts by mass of the polymerizable monomer C1. In addition, a C═C value of the polymerizable monomer C1 is preferably 90 to 300 g/mol. The lower limit is preferably 93 g/mol or more and particularly preferably 96 g/mol or more. The upper limit is preferably 250 g/mol or less and particularly preferably 200 g/mol or less. In addition, a C═C value of the polymerizable monomer C2 is preferably 90 to 300 g/mol. The lower limit is preferably 93 g/mol or more and particularly preferably 96 g/mol or more. The upper limit is preferably 250 g/mol or less and particularly preferably 200 g/mol or less.

A content of the polymerizable monomer in the total solid content of the coloring composition is preferably more than 0% by mass and 30% by mass or less. The lower limit is preferably 0.1% by mass or more and more preferably 0.5% by mass or more. The upper limit is preferably 20% by mass or less, more preferably 15% by mass or less, and still more preferably 10% by mass or less.

<<Photopolymerization Initiator>>

It is preferable that the coloring composition according to the embodiment of the present invention includes a photopolymerization initiator. The photopolymerization initiator is not particularly limited, and can be appropriately selected from known photopolymerization initiators. For example, a compound having photosensitivity to light in a range from an ultraviolet range to a visible range is preferable. The photopolymerization initiator is preferably a photoradical polymerization initiator.

Examples of the photopolymerization initiator include a halogenated hydrocarbon derivative (for example, a compound having a triazine skeleton or a compound having an oxadiazole skeleton), an acylphosphine compound, a hexaarylbiimidazole, an oxime compound, an organic peroxide, a thio compound, a ketone compound, an aromatic onium salt, an α-hydroxyketone compound, and an α-aminoketone compound. From the viewpoint of exposure sensitivity, as the photopolymerization initiator, a trihalomethyltriazine compound, a benzyldimethylketal compound, an α-hydroxyketone compound, an α-aminoketone compound, an acylphosphine compound, a phosphine oxide compound, a metallocene compound, an oxime compound, a triarylimidazole dimer, an onium compound, a benzothiazole compound, a benzophenone compound, an acetophenone compound, a cyclopentadiene-benzene-iron complex, a halomethyl oxadiazole compound, or a 3-aryl-substituted coumarin compound is preferable, a compound selected from an oxime compound, an α-hydroxyketone compound, an α-aminoketone compound, or an acylphosphine compound is more preferable, an oxime compound or an α-aminoketone compound is still more preferable, and an oxime compound is particularly preferable. In addition, as the photopolymerization initiator, compounds described in paragraphs 0065 to 0111 of JP2014-130173A, compounds described in JP6301489B, peroxide-based photopolymerization initiators described in MATERIAL STAGE, p. 37 to 60, vol. 19, No. 3, 2019, photopolymerization initiators described in WO2018/221177A, photopolymerization initiators described in WO2018/110179A, photopolymerization initiators described in JP2019-043864A, and photopolymerization initiators described in JP2019-044030A, the contents of which are incorporated herein by reference.

Examples of a commercially available product of the α-hydroxyketone compound include Omnirad 184, Omnirad 1173, Omnirad 2959, and Omnirad 127 (all of which are manufactured by IGM Resins B.V.), Irgacure 184, Irgacure 1173, Irgacure 2959, and Irgacure 127 (all of which are manufactured by BASF SE). Examples of a commercially available product of the α-aminoketone compound include Omnirad 907, Omnirad 369, Omnirad 369E, and Omnirad 379EG (all of which are manufactured by IGM Resins B.V.), Irgacure 907, Irgacure 369, Irgacure 369E, and Irgacure 379EG (all of which are manufactured by BASF SE). Examples of a commercially available product of the acylphosphine compound include Omnirad 819 and Omnirad TPO (both of which are manufactured by IGM Resins B.V.), Irgacure 819 and Irgacure TPO (both of which are manufactured by BASF SE).

Examples of the oxime compound include the compounds described in JP2001-233842A, the compounds described in JP2000-080068A, the compounds described in JP2006-342166A, the compounds described in J. C. S. Perkin II (1979, pp. 1653 to 1660), the compounds described in J. C. S. Perkin II (1979, pp. 156 to 162), the compounds described in Journal of Photopolymer Science and Technology (1995, pp. 202 to 232), the compounds described in JP2000-066385A, the compounds described in JP2004-534797A, the compounds described in JP2006-342166A, the compounds described in JP2017-019766A, the compounds described in JP6065596B, the compounds described in WO2015/152153A, the compounds described in WO2017/051680A, the compounds described in JP2017-198865A, the compounds described in paragraph Nos. 0025 to 0038 of WO2017/164127A, and compounds described in WO2013/167515A. Specific examples of the oxime compound include 3-benzoyloxyiminobutane-2-one, 3-acetoxyiminobutane-2-one, 3-propionyloxyiminobutane-2-one, 2-acetoxyiminopentane-3-one, 2-acetoxyimino-1-phenylpropane-1-one, 2-benzoyloxyimino-1-phenylpropane-1-one, 3-(4-toluene sulfonyloxy)iminobutane-2-one, and 2-ethoxycarbonyloxyimino-1-phenylpropane-1-one. Examples of a commercially available product thereof include Irgacure OXE01, Irgacure OXE02, Irgacure OXE03, and Irgacure OXE04 (all of which are manufactured by BASF SE), TR-PBG-304 (manufactured by TRONLY), and ADEKA OPTOMER N-1919 (manufactured by ADEKA Corporation; photopolymerization initiator 2 described in JP2012-014052A). In addition, as the oxime compound, it is also preferable to use a compound having no colorability or a compound having high transparency and being resistant to discoloration. Examples of a commercially available product include ADEKA ARKLS NCI-730, NCI-831, and NCI-930 (all of which are manufactured by ADEKA Corporation).

An oxime compound having a fluorene ring can also be used as the photopolymerization initiator. Specific examples of the oxime compound having a fluorene ring include the compounds described in JP2014-137466A.

As the photopolymerization initiator, an oxime compound having a skeleton in which at least one benzene ring of a carbazole ring is a naphthalene ring can also be used. Specific examples of such an oxime compound include the compounds described in WO2013/083505A.

An oxime compound having a fluorine atom can also be used as the photopolymerization initiator. Specific examples of the oxime compound having a fluorine atom include the compounds described in JP2010-262028A, the compounds 24, and 36 to 40 described in JP2014-500852A, and the compound (C-3) described in JP2013-164471A.

An oxime compound having a nitro group can be used as the photopolymerization initiator. The oxime compound having a nitro group is also preferably used in the form of a dimer. Specific examples of the oxime compound having a nitro group include the compounds described in paragraph Nos. 0031 to 0047 of JP2013-114249A and paragraph Nos. 0008 to 0012 and 0070 to 0079 of JP2014-137466A, the compounds described in paragraph Nos. 0007 to 0025 of JP4223071B, and ADEKA ARKLS NCI-831 (manufactured by ADEKA Corporation).

An oxime compound having a benzofuran skeleton can also be used as the photopolymerization initiator. Specific examples thereof include OE-01 to OE-75 described in WO2015/036910A.

In the present invention, as the photopolymerization initiator, an oxime compound in which a substituent having a hydroxy group is bonded to a carbazole skeleton can also be used. Examples of such a photopolymerization initiator include compounds described in WO2019/088055A.

As the photopolymerization initiator, an oxime compound having an aromatic ring group Ar^{OX1} in which an electron withdrawing group is introduced into an aromatic ring (hereinafter, also referred to as an oxime compound OX) is used can also be used. Examples of the electron withdrawing group included in the above-described aromatic ring group Ar^{OX1} include an acyl group, a nitro group, a trifluoromethyl group, an alkylsulfinyl group, an arylsulfinyl group, an alkylsulfonyl group, an arylsulfonyl group, and a cyano group. Among these, an acyl group or a nitro group is preferable, and from the reason that it is easy to form a film with excellent light resistance, an acyl group is more preferable, and a benzoyl group is still more preferable. The benzoyl group may have a substituent. As the substituent, a halogen atom, a cyano group, a nitro group, a hydroxy group, an alkyl group, an alkoxy group, an aryl group, an aryloxy group, a heterocyclic group, a heterocyclic oxy group, an alkenyl group, an alkylsulfanyl group, an arylsulfanyl group, an acyl group, or an amino group is preferable, an alkyl group, an alkoxy group, an aryl group, an aryloxy group, a heterocyclic oxy group, an alkylsulfanyl group, an arylsulfanyl group, or an amino group is more preferable, and an alkoxy group, an alkylsulfanyl group, or an amino group is still more preferable.

The oxime compound OX is preferably at least one selected from a compound represented by Formula (OX1) or a compound represented by Formula (OX2), and more preferably a compound represented by Formula (OX2).

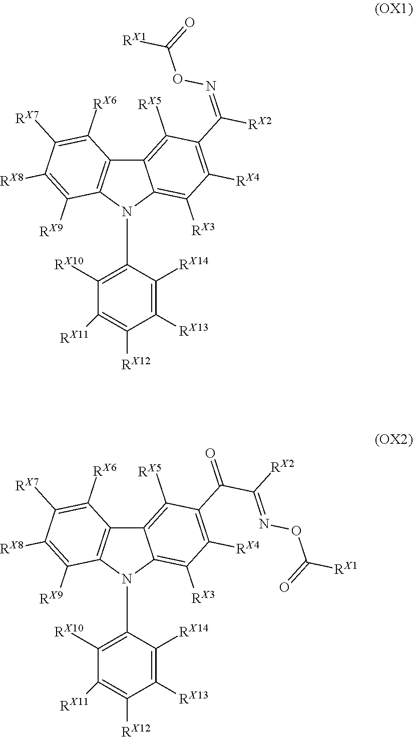

In the formula, R^{X1} represents an alkyl group, an alkenyl group, an alkoxy group, an aryl group, an aryloxy group, a heterocyclic group, a heterocyclic oxy group, an alkylsulfanyl group, an arylsulfanyl group, an alkylsulfinyl group, an arylsulfinyl group, an alkylsulfonyl group, an arylsulfonyl group, an acyl group, an acyloxy group, an amino group, a phosphinoyl group, a carbamoyl group, or a sulfamoyl group,

R^{X2} represents an alkyl group, an alkenyl group, an alkoxy group, an aryl group, an aryloxy group, a heterocyclic group, a heterocyclic oxy group, an alkylsulfanyl group, an arylsulfanyl group, an alkylsulfinyl group, an arylsulfinyl group, an alkylsulfonyl group, an arylsulfonyl group, an acyloxy group, or an amino group,

R^{X3} to R^{X14} each independently represent a hydrogen atom or a substituent, and

at least one of R^{X10}, . . . , or R^{X14} is an electron withdrawing group.

In the formulae, R^{X1} is preferably an alkyl group, an alkoxy group, an aryl group, an aryloxy group, or a heterocyclic group, more preferably an alkyl group, an aryl group, or a heterocyclic group, and still more preferably an alkyl group. In addition, R^{X2} is preferably an alkyl group, an alkenyl group, an alkoxy group, an aryl group, an aryloxy group, a heterocyclic group, a heterocyclic oxy group, or an acyloxy group, more preferably an alkyl group, an alkenyl group, an aryl group, or a heterocyclic group, and still more preferably an alkyl group.

In the formulae, R^{X3} to R^{X14} each independently represent a hydrogen atom or a substituent.

R^{X3} to R^{X14} are each independently preferably a hydrogen atom, a halogen atom, a cyano group, a nitro group, an alkyl group, an alkenyl group, an alkoxy group, an aryl group, an aryloxy group, a heterocyclic group, a heterocyclic oxy group, an alkylsulfanyl group, an arylsulfanyl group, an acyl group, or an amino group, more preferably a hydrogen atom, a halogen atom, a nitro group, an alkyl group, an aryl group, or a heterocyclic group, still more preferably a hydrogen atom, a nitro group, an alkyl group, or an aryl group, and particularly preferably a hydrogen atom.

R^{X6} to R^{X14} are each independently preferably a hydrogen atom, a halogen atom, a cyano group, an alkyl group, an alkenyl group, an alkoxy group, an aryl group, an aryloxy group, a heterocyclic group, a heterocyclic oxy group, an alkylsulfanyl group, an arylsulfanyl group, an alkylsulfinyl group, an arylsulfinyl group, an alkylsulfonyl group, an arylsulfonyl group, an amino group, a group represented by Formula (OR-li), or a group represented by Formula (OR-12), more preferably a hydrogen atom, a halogen atom, a cyano group, an alkyl group, an aryl group, a heterocyclic group, or an amino group, still more preferably a hydrogen atom, a cyano group, an alkyl group, or an aryl group, even more preferably a hydrogen atom, an alkyl group, or an aryl group, even still more preferably a hydrogen atom or an alkyl group, and particularly preferably a hydrogen atom.

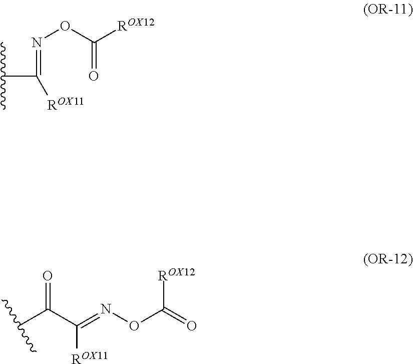

In the formula, R^{OX11} represents an alkyl group, an alkenyl group, an alkoxy group, an aryl group, an aryloxy group, a heterocyclic group, a heterocyclic oxy group, an alkylsulfanyl group, an arylsulfanyl group, an alkylsulfinyl group, an arylsulfinyl group, an alkylsulfonyl group, an arylsulfonyl group, an acyl group, an acyloxy group, an amino group, a phosphinoyl group, a carbamoyl group, or a sulfamoyl group,

R^{OX12} represents an alkyl group, an alkenyl group, an alkoxy group, an aryl group, an aryloxy group, a heterocyclic group, a heterocyclic oxy group, an alkylsulfanyl group, an arylsulfanyl group, an alkylsulfinyl group, an arylsulfinyl group, an alkylsulfonyl group, an arylsulfonyl group, an acyloxy group, or an amino group, and a wavy line represents a bonding site.

The substituent represented by R^{X10} to R^{X14} is preferably a nitro group, a halogen atom, a cyano group, an alkyl group, an alkoxy group, an aryl group, an aryloxy group, a heterocyclic group, a heterocyclic oxy group, an alkenyl group, an alkylsulfanyl group, an arylsulfanyl group, an acyl group, or an amino group. However, at least one of R^{X10}, . . . , or R^{X14} is an electron withdrawing group.

In addition, examples of the electron withdrawing group represented by R^{X10} to R^{X14} include an acyl group, a nitro group, a trifluoromethyl group, an alkylsulfinyl group, an arylsulfinyl group, an alkylsulfonyl group, an arylsulfonyl group, and a cyano group. Among these, an acyl group or a nitro group is preferable, and from the reason that it is easy to form a film with excellent light resistance, an acyl group is more preferable, and a benzoyl group is still more preferable. The benzoyl group may have a substituent. As the substituent, a halogen atom, a cyano group, a nitro group, a hydroxy group, an alkyl group, an alkoxy group, an aryl group, an aryloxy group, a heterocyclic group, a heterocyclic oxy group, an alkenyl group, an alkylsulfanyl group, an arylsulfanyl group, an acyl group, or an amino group is preferable, an alkyl group, an alkoxy group, an aryl group, an aryloxy group, a heterocyclic oxy group, an alkylsulfanyl group, an arylsulfanyl group, or an amino group is more preferable, and an alkoxy group, an alkylsulfanyl group, or an amino group is still more preferable.

In the formulae, it is preferable that R^{X12} is an electron withdrawing group, and R^{X10}, R^{X11}, R_{X13}, and R^{X14} are hydrogen atoms.

Specific examples of the oxime compound OX include compounds described in paragraph Nos. 0083 to 0105 of JP4600600B.

Specific examples of the oxime compound which are preferably used in the present invention are shown below, but the present invention is not limited thereto.

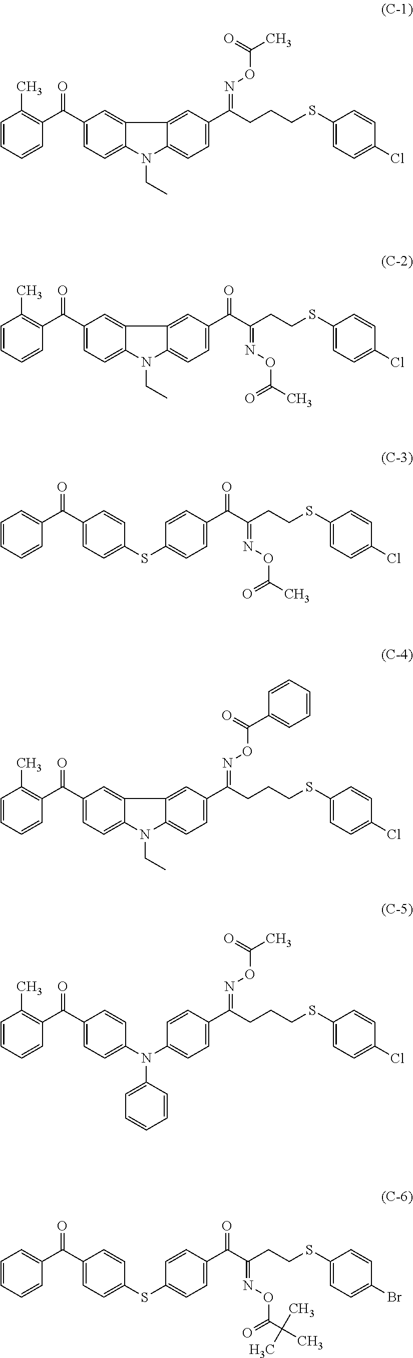 [SMILES: CCn1c2ccc(C(=O)c3ccccc3C)cc2c2cc(/C(CCCSc3ccc(Cl)cc3)=N/OC(C)=O)ccc21 ; CCn1c2ccc(C(=O)/C(CCSc3ccc(Cl)cc3)=N/OC(C)=O)cc2c2cc(C(=O)c3ccccc3C)ccc21 ; CC(=O)O/N=C(\CCSc1ccc(Cl)cc1)C(=O)c1ccc(Sc2ccc(C(=O)c3ccccc3)cc2)cc1 ; CCn1c2ccc(C(=O)c3ccccc3C)cc2c2cc(/C(CCCSc3ccc(Cl)cc3)=N/OC(=O)c3ccccc3)ccc21 ; CC(=O)O/N=C(\CCCSc1ccc(Cl)cc1)c1ccc(N(c2ccccc2)c2ccc(C(=O)c3ccccc3C)cc2)cc1 ; CC(C)(C)C(=O)O/N=C(\CCSc1ccc(Br)cc1)C(=O)c1ccc(Sc2ccc(C(=O)c3ccccc3)cc2)cc1]

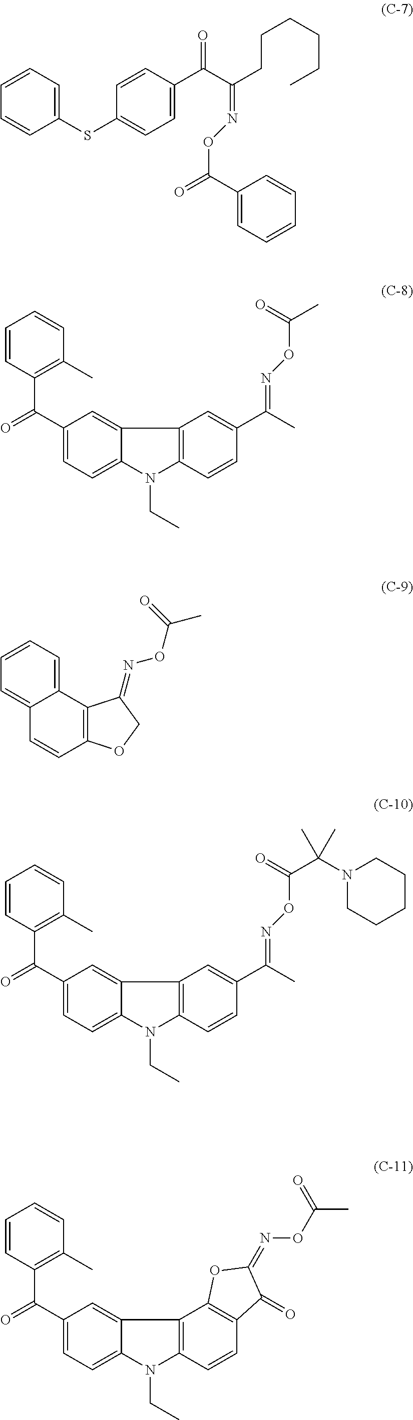 [SMILES: CCCCCC/C(=N/OC(=O)c1ccccc1)C(=O)c1ccc(Sc2ccccc2)cc1 ; CCn1c2ccc(C(=O)c3ccccc3C)cc2c2cc(/C(C)=N/OC(C)=O)ccc21 ; CC(=O)O/N=C1\COc2ccc3ccccc3c21 ; CCn1c2ccc(C(=O)c3ccccc3C)cc2c2cc(/C(C)=N/OC(=O)C(C)(C)N3CCCCC3)ccc21 ; CCn1c2ccc(C(=O)c3ccccc3C)cc2c2c3c(ccc21)C(=O)/C(=N\OC(C)=O)O3]

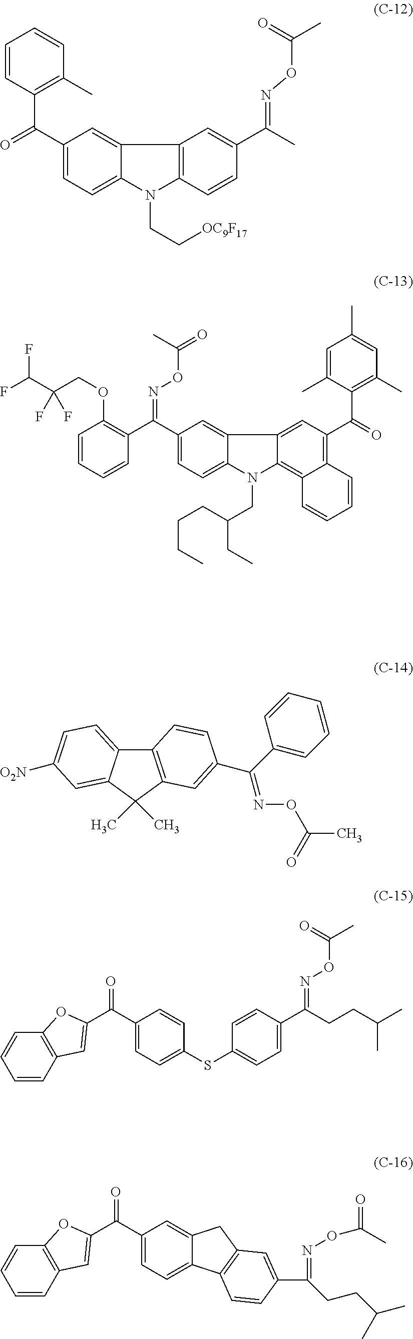

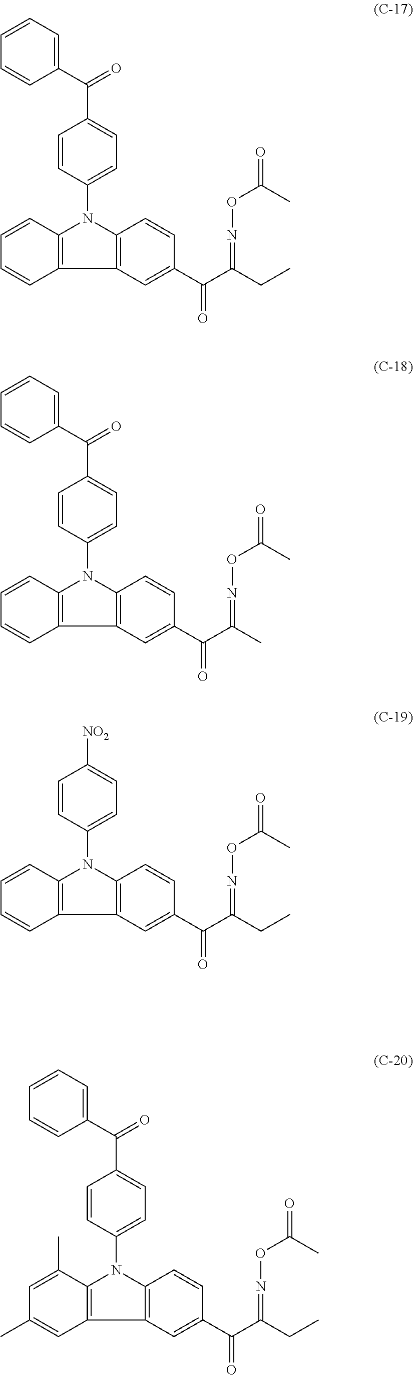

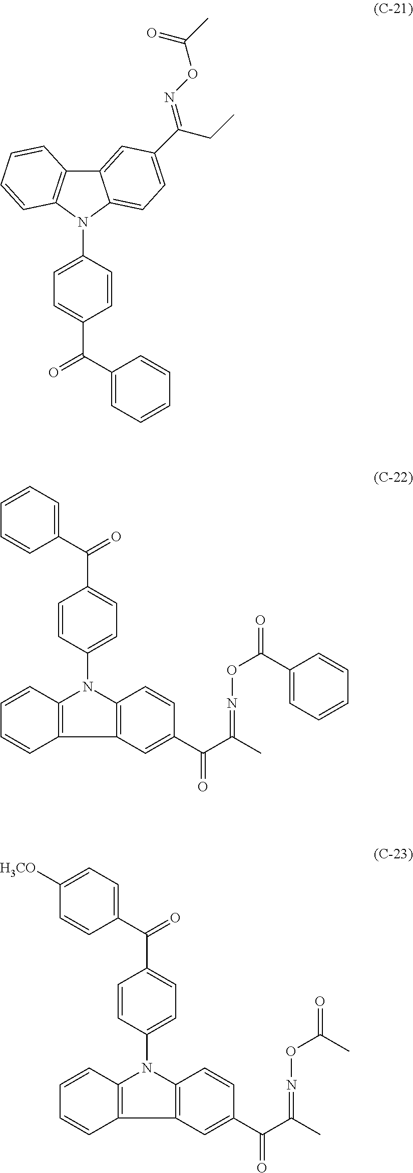 [SMILES: CC/C(=N\OC(C)=O)c1ccc2c(c1)c1ccccc1n2-c1ccc(C(=O)c2ccccc2)cc1 ; CC(=NOC(=O)c1ccccc1)C(=O)c1ccc2c(c1)c1ccccc1n2-c1ccc(C(=O)c2ccccc2)cc1 ; COc1ccc(C(=O)c2ccc(-n3c4ccccc4c4cc(C(=O)C(C)=NOC(C)=O)ccc43)cc2)cc1]

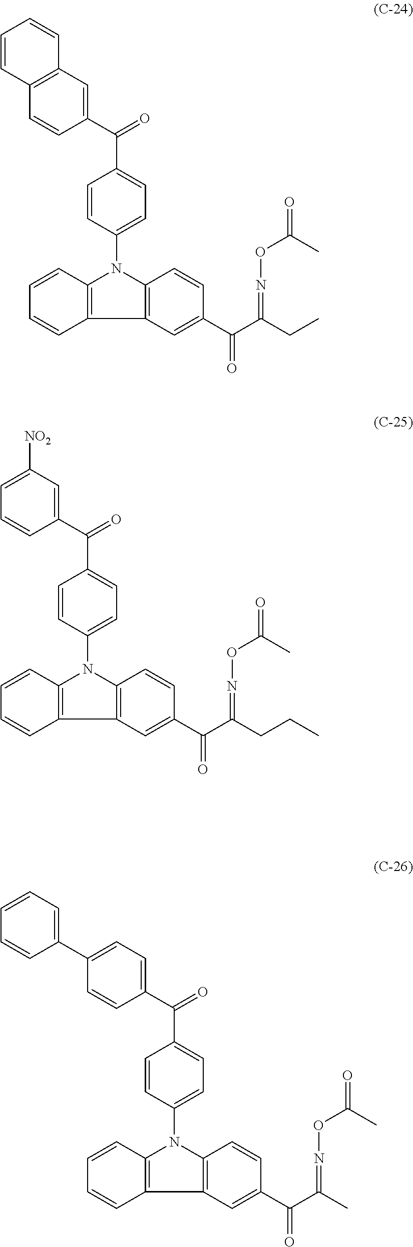 [SMILES: CCC(=NOC(C)=O)C(=O)c1ccc2c(c1)c1ccccc1n2-c1ccc(C(=O)c2ccc3ccccc3c2)cc1 ; CCCC(=NOC(C)=O)C(=O)c1ccc2c(c1)c1ccccc1n2-c1ccc(C(=O)c2cccc([N+](=O)[O-])c2)cc1 ; CC(=O)ON=C(C)C(=O)c1ccc2c(c1)c1ccccc1n2-c1ccc(C(=O)c2ccc(-c3ccccc3)cc2)cc1]

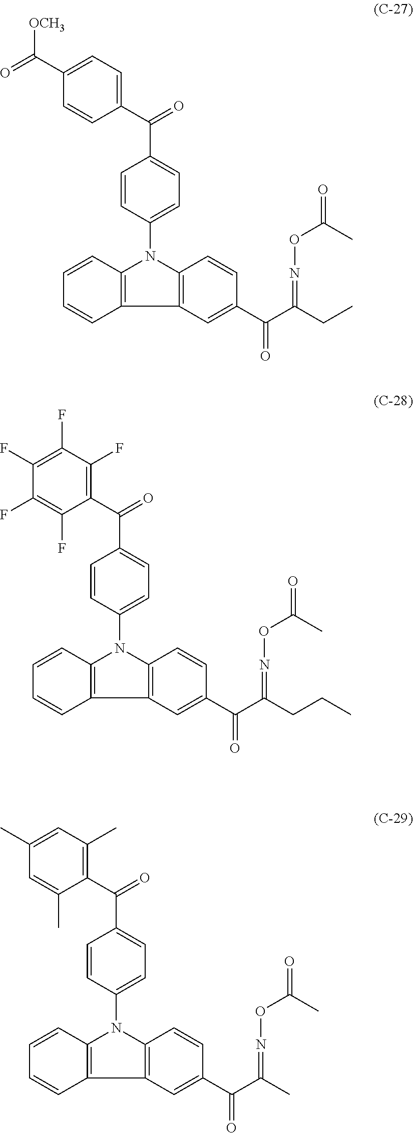

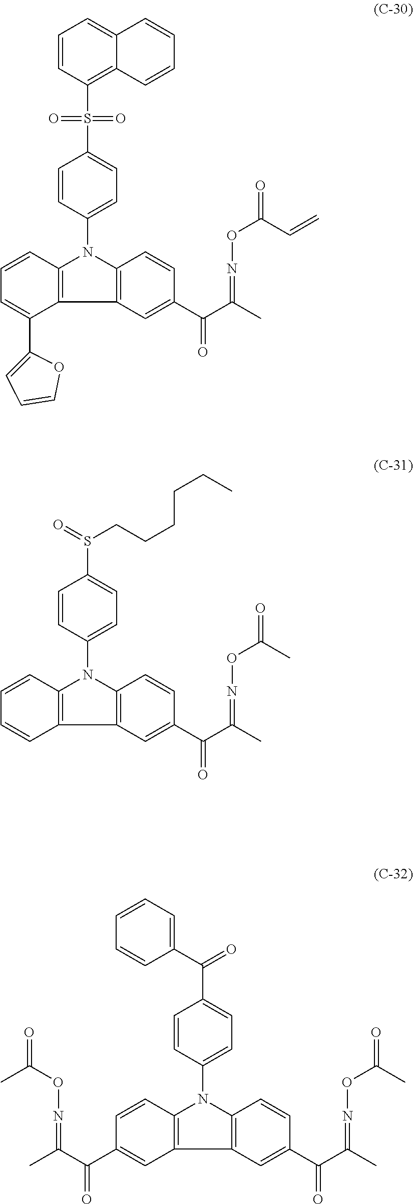

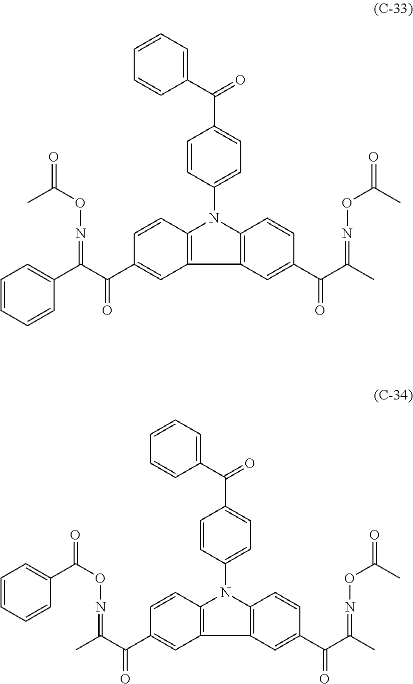 [SMILES: CC(=O)ON=C(C)C(=O)c1ccc2c(c1)c1cc(C(=O)C(=NOC(C)=O)c3ccccc3)ccc1n2-c1ccc(C(=O)c2ccccc2)cc1 ; CC(=O)ON=C(C)C(=O)c1ccc2c(c1)c1cc(C(=O)C(C)=NOC(=O)c3ccccc3)ccc1n2-c1ccc(C(=O)c2ccccc2)cc1]

The oxime compound is preferably a compound having a maximal absorption wavelength in a wavelength range of 350 to 500 nm and more preferably a compound having a maximal absorption wavelength in a wavelength range of 360 to 480 nm. In addition, from the viewpoint of sensitivity, a molar absorption coefficient of the oxime compound at a wavelength of 365 nm or 405 nm is preferably high, more preferably 1000 to 300000, still more preferably 2000 to 300000, and particularly preferably 5000 to 200000. The molar absorption coefficient of a compound can be measured using a known method. For example, the molar absorption coefficient is preferably measured by a spectrophotometer (Cary-5 spectrophotometer, manufactured by Varian Medical Systems, Inc.) using an ethyl acetate solvent at a concentration of 0.01 g/L.

As the photopolymerization initiator, a bifunctional or tri- or higher functional photoradical polymerization initiator may be used. By using such a photoradical polymerization initiator, two or more radicals are generated from one molecule of the photoradical polymerization initiator, and as a result, good sensitivity is obtained. In addition, in a case of using a compound having an asymmetric structure, crystallinity is reduced so that solubility in a solvent or the like is improved, precipitation is to be difficult over time, and temporal stability of the coloring composition can be improved. Specific examples of the bifunctional or tri- or higher functional photoradical polymerization initiator include dimers of the oxime compounds described in JP2010-527339A, JP2011-524436A, WO2015/004565A, paragraph Nos. 0407 to 0412 of JP2016-532675A, and paragraph Nos. 0039 to 0055 of WO2017/033680A; the compound (E) and compound (G) described in JP2013-522445A; Cmpd 1 to 7 described in WO2016/034963A; the oxime ester photoinitiators described in paragraph No. 0007 of JP2017-523465A; the photoinitiators described in paragraph Nos. 0020 to 0033 of JP2017-167399A; the photopolymerization initiator (A) described in paragraph Nos. 0017 to 0026 of JP2017-151342A; and the oxime ester photoinitiators described in JP6469669B.

A content of the photopolymerization initiator in the total solid content of the coloring composition is preferably 0.1% to 20% by mass. The lower limit is preferably 0.5% by mass or more and more preferably 1% by mass or more. The upper limit is preferably 10% by mass or less, more preferably 7.5% by mass or less, and still more preferably 5% by mass or less. The photopolymerization initiator may be used singly or in a combination of two or more kinds thereof. In a case where two or more kinds thereof are used in combination, the total thereof is preferably within the above-described range.

<<Compound Having Cyclic Ether Group>>

The coloring composition according to the embodiment of the present invention can contain a compound having a cyclic ether group as a component other than the above-described resins. Examples of the cyclic ether group include an epoxy group and an oxetanyl group. It is preferable that the compound having a cyclic ether group is a compound having an epoxy group (hereinafter, also referred to as an “epoxy compound”). Examples of the epoxy compound include a compound having one or more epoxy groups in one molecule, and a compound having two or more epoxy groups in one molecule is preferable. The epoxy compound is preferably a compound having 1 to 100 epoxy groups in one molecule. The upper limit of the number of epoxy groups included in the epoxy compound may be, for example, 10 or less or 5 or less. The lower limit of the epoxy group included in the epoxy compound is preferably 2 or more. As the epoxy compound, the compounds described in paragraph Nos. 0034 to 0036 of JP2013-011869A, paragraph Nos. 0147 to 0156 of JP2014-043556A, and paragraph Nos. 0085 to 0092 of JP2014-089408A, and the compounds described in JP2017-179172A can also be used. The contents of the publications are incorporated herein by reference.

The epoxy compound may be a low-molecular-weight compound (for example, having a molecular weight of less than 2000, and further, a molecular weight of less than 1000) or a high-molecular-weight compound (macromolecule) (for example, having a molecular weight of 1000 or more, and in a case of a polymer, having a weight-average molecular weight of 1000 or more). A weight-average molecular weight of the compound having an epoxy group is preferably 200 to 100000 and more preferably 500 to 50000. The upper limit of the weight-average molecular weight is still more preferably 10000 or less, particularly preferably 5000 or less, and even more preferably 3000 or less.

Examples of a commercially available product of the compound having a cyclic ether group include EHPE 3150 (manufactured by Daicel Corporation), EPICLON N-695 (manufactured by DIC Corporation), and MARPROOF G-0150M, G-0105SA, G-0130SP, G-0250SP, G-1005S, G-1005SA, G-1010S, G-2050M, G-01100, and G-01758 (all of which are manufactured by NOF Corporation., an epoxy group-containing polymer).

In a case where the coloring composition according to the embodiment of the present invention contains a compound having a cyclic ether group, the content of the compound having a cyclic ether group in the total solid content of the coloring composition is preferably 0.1% to 20% by mass. The lower limit is, for example, more preferably 0.5% by mass or more and still more preferably 1% by mass or more. The upper limit is, for example, more preferably 15% by mass or less and still more preferably 10% by mass or less. The compound having a cyclic ether group may be used singly or in a combination of two or more kinds thereof. In a case where two or more kinds thereof are used, the total amount thereof is preferably within the above-described range.

<<Silane Coupling Agent>>

The coloring composition according to the embodiment of the present invention can contain a silane coupling agent. According to this aspect, adhesiveness of a film to be obtained with a support can be further improved. In the present specification, the silane coupling agent means a silane compound having a hydrolyzable group and other functional groups. In addition, the hydrolyzable group refers to a substituent directly linked to a silicon atom and capable of forming a siloxane bond due to at least one of a hydrolysis reaction or a condensation reaction. Examples of the hydrolyzable group include a halogen atom, an alkoxy group, and an acyloxy group, and an alkoxy group is preferable. That is, it is preferable that the silane coupling agent is a compound having an alkoxysilyl group. Examples of the functional group other than the hydrolyzable group include a vinyl group, a (meth)allyl group, a (meth)acryloyl group, a mercapto group, an epoxy group, an oxetanyl group, an amino group, a ureido group, a sulfide group, an isocyanate group, and a phenyl group, and an amino group, a (meth)acryloyl group, or an epoxy group is preferable. Specific examples of the silane coupling agent include N-β-aminoethyl-α-aminopropyl methyldimethoxysilane (trade name: KBM-602, manufactured by Shin-Etsu Chemical Co., Ltd.), N-β-aminoethyl-γ-aminopropyl trimethoxysilane (trade name: KBM-603, manufactured by Shin-Etsu Chemical Co., Ltd.), N-β-aminoethyl-γ-aminopropyl triethoxysilane (trade name: KBE-602, manufactured by Shin-Etsu Chemical Co., Ltd.), γ-aminopropyl trimethoxysilane (trade name: KBM-903, manufactured by Shin-Etsu Chemical Co., Ltd.), γ-aminopropyl triethoxysilane (trade name: KBE-903, manufactured by Shin-Etsu Chemical Co., Ltd.), 3-methacryloxypropylmethyl dimethoxysilane (trade name: KBM-502, manufactured by Shin-Etsu Chemical Co., Ltd.), and 3-methacryloxypropyl trimethoxysilane (trade name: KBM-503, manufactured by Shin-Etsu Chemical Co., Ltd.). In addition, specific examples of the silane coupling agent include the compounds described in paragraph Nos. 0018 to 0036 of JP2009-288703A and the compounds described in paragraph Nos. 0056 to 0066 of JP2009-242604A, the contents of which are incorporated herein by reference.

A content of the silane coupling agent in the total solid content of the coloring composition is preferably 0.1% to 5% by mass. The upper limit is more preferably 3% by mass or less and still more preferably 2% by mass or less. The lower limit is more preferably 0.5% by mass or more and still more preferably 1% by mass or more. The silane coupling agent may be used singly or in a combination of two or more kinds thereof. In a case where two or more kinds thereof are used, the total amount thereof is preferably within the above-described range.

<<Surfactant>>

The coloring composition according to the embodiment of the present invention can contain a surfactant. As the surfactant, various surfactants such as a fluorine-based surfactant, a nonionic surfactant, a cationic surfactant, an anionic surfactant, and a silicon-based surfactant can be used. Examples of the surfactant include surfactants described in paragraph Nos. 0238 to 0245 of WO2015/166779A, the contents of which are incorporated herein by reference.

It is preferable that the surfactant is a fluorine-based surfactant. By containing a fluorine-based surfactant in the coloring composition, liquid characteristics (particularly, fluidity) are further improved, and liquid saving properties can be further improved. In addition, it is possible to form a film with a small thickness unevenness.

A fluorine content in the fluorine-based surfactant is suitably 3% to 40% by mass, and more preferably 5% to 30% by mass and particularly preferably 7% to 25% by mass. The fluorine-based surfactant in which the fluorine content is within the above-described range is effective in terms of the evenness of the thickness of the coating film or liquid saving properties and the solubility of the surfactant in the coloring composition is also good.

Examples of the fluorine-based surfactant include surfactants described in paragraph Nos. 0060 to 0064 of JP2014-041318A (paragraph Nos. 0060 to 0064 of the corresponding WO2014/017669A) and the like, and surfactants described in paragraph Nos. 0117 to 0132 of JP2011-132503A, the contents of which are incorporated herein by reference. Examples of a commercially available product of the fluorine-based surfactant include: MEGAFACE F171, F172, F173, F176, F177, F141, F142, F143, F144, R30, F437, F475, F479, F482, F554, F780, EXP, and MFS-330 (all of which are manufactured by DIC Corporation); FLUORAD FC430, FC431, and FC171 (all of which are manufactured by Sumitomo 3M Ltd.); SURFLON S-382, SC-101, SC-103, SC-104, SC-105, SC-1068, SC-381, SC-383, S-393, and KH-40 (all of which are manufactured by Asahi Glass Co., Ltd.); and POLYFOX PF636, PF656, PF6320, PF6520, and PF7002 (all of which are manufactured by OMNOVA Solutions Inc.).

In addition, as the fluorine-based surfactant, an acrylic compound, which has a molecular structure having a functional group containing a fluorine atom and in which, by applying heat to the molecular structure, the functional group containing a fluorine atom is broken to volatilize a fluorine atom, can also be suitably used. Examples of such a fluorine-based surfactant include MEGAFACE DS series manufactured by DIC Corporation (The Chemical Daily, Feb. 22, 2016; Nikkei Business Daily, Feb. 23, 2016) such as MEGAFACE DS-21.

In addition, it is also preferable that a polymer of a fluorine atom-containing vinyl ether compound having a fluorinated alkyl group or a fluorinated alkylene ether group, and a hydrophilic vinyl ether compound is used as the fluorine-based surfactant. Examples of such a fluorine-based surfactant include fluorine-based surfactants described in JP2016-216602A, the contents of which are incorporated herein by reference.

A block polymer can also be used as the fluorine-based surfactant. As the fluorine-based surfactant, a fluorine-containing polymer compound including a repeating unit derived from a (meth)acrylate compound having a fluorine atom and a repeating unit derived from a (meth)acrylate compound having 2 or more (preferably 5 or more) alkyleneoxy groups (preferably ethyleneoxy groups or propyleneoxy groups) can also be preferably used. In addition, fluorine-containing surfactants described in paragraph Nos. 0016 to 0037 of JP2010-032698A, or the following compounds are also exemplified as the fluorine-based surfactant used in the present invention.

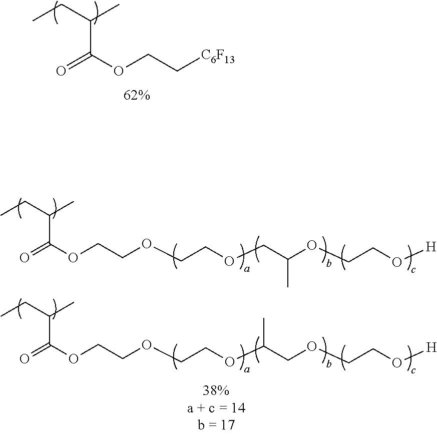

A weight-average molecular weight of the compound is preferably 3000 to 50000 and, for example, 14000. In the compound, “%” representing the proportion of a repeating unit is mol %.

In addition, as the fluorine-based surfactant, a fluorine-containing polymer having an ethylenically unsaturated bond-containing group in the side chain can be used. Specific examples thereof include compounds described in paragraph Nos. 0050 to 0090 and paragraph Nos. 0289 to 0295 of JP2010-164965A, and MEGAFACE RS-101, RS-102, RS-718K, and RS-72-K manufactured by DIC Corporation. In addition, as the fluorine-based surfactant, compounds described in paragraph Nos. 0015 to 0158 of JP2015-117327A can also be used.

A content of the surfactant in the total solid content of the coloring composition is preferably 0.001% by mass to 5.0% by mass and more preferably 0.005% to 3.0% by mass.

The surfactant may be used singly or in a combination of two or more kinds thereof. In a case where two or more kinds thereof are used, the total amount thereof is preferably within the above-described range.

<<Ultraviolet Absorber>>

The coloring composition according to the embodiment of the present invention can contain an ultraviolet absorber. As the ultraviolet absorber, a conjugated diene compound, an aminodiene compound, a salicylate compound, a benzophenone compound, a benzotriazole compound, an acrylonitrile compound, a hydroxyphenyltriazine compound, an indole compound, a triazine compound, or the like can be used. Examples of such a compound include compounds described in paragraph Nos. 0038 to 0052 of JP2009-217221A, paragraph Nos. 0052 to 0072 of JP2012-208374A, paragraph Nos. 0317 to 0334 of JP2013-068814A, and paragraph Nos. 0061 to 0080 of JP2016-162946A, the contents of which are incorporated herein by reference. Examples of a commercially available product of the ultraviolet absorber include UV-503 (manufactured by Daito Chemical Co., Ltd). In addition, examples of the benzotriazole compound include MYUA series manufactured by Miyoshi Oil & Fat Co., Ltd. (The Chemical Daily, Feb. 1, 2016). In addition, as the ultraviolet absorber, compounds described in paragraph Nos. 0049 to 0059 of JP6268967B can also be used. A content of the ultraviolet absorber in the total solid content of the coloring composition is preferably 0.01% to 10% by mass and more preferably 0.01% to 5% by mass. The ultraviolet absorber may be used singly or in a combination of two or more kinds thereof. In a case where two or more kinds thereof are used, the total amount thereof is preferably within the above-described range.

<<Antioxidant>>

The coloring composition according to the embodiment of the present invention can contain an antioxidant. Examples of the antioxidant include a phenol compound, a phosphite ester compound, and a thioether compound. As the phenol compound, any phenol compound which is known as a phenol-based antioxidant can be used. Preferred examples of the phenol compound include a hindered phenol compound. A compound having a substituent at a site (ortho position) adjacent to a phenolic hydroxy group is preferable. As the substituent, a substituted or unsubstituted alkyl group having 1 to 22 carbon atoms is preferable. In addition, as the antioxidant, a compound having a phenol group and a phosphite ester group in the same molecule is also preferable. In addition, as the antioxidant, a phosphorus antioxidant can also be suitably used. In addition, as the antioxidant, compounds described in KR10-2019-0059371A can also be used. A content of the antioxidant in the total solid content of the coloring composition is preferably 0.01% to 20% by mass and more preferably 0.3% to 15% by mass. The antioxidant may be used singly or in a combination of two or more kinds thereof. In a case of using two or more kinds thereof, the total amount thereof is preferably within the above-described range.

<<Polymerization Inhibitor>>

The coloring composition according to the embodiment of the present invention can contain a polymerization inhibitor. Examples of the polymerization inhibitor include hydroquinone, p-methoxyphenol, di-tert-butyl-p-cresol, pyrogallol, tert-butyl catechol, benzoquinone, 4,4′-thiobis(3-methyl-6-tert-butylphenol), 2,2′-methylenebis(4-methyl-6-t-butylphenol), and an N-nitrosophenylhydroxylamine salt (an ammonium salt, a cerous salt, or the like). Among these, p-methoxyphenol is preferable. A content of the polymerization inhibitor in the total solid content of the coloring composition is preferably 0.0001% to 5% by mass. The polymerization inhibitor may be used singly or in a combination of two or more kinds thereof. In a case of two or more kinds thereof, the total amount thereof is preferably within the above-described range.

<<Solvent>>

The coloring composition according to the embodiment of the present invention can contain a solvent. As the solvent, an organic solvent is preferable. Basically, the organic solvent is not particularly limited as long as it satisfies solubility of the respective components and coating properties of the coloring composition. Examples of the organic solvent include an ester-based solvent, a ketone-based solvent, an alcohol-based solvent, an amide-based solvent, an ether-based solvent, and a hydrocarbon-based solvent. The details of the organic solvent can be found in paragraph No. 0223 of WO2015/166779A, the content of which is incorporated herein by reference. In addition, an ester-based solvent in which a cyclic alkyl group is substituted or a ketone-based solvent in which a cyclic alkyl group is substituted can also be preferably used. Specific examples of the organic solvent include polyethylene glycol monomethyl ether, dichloromethane, methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, cyclohexyl acetate, cyclopentanone, ethyl carbitol acetate, butyl carbitol acetate, propylene glycol monomethyl ether, propylene glycol monomethyl ether acetate, 3-methoxy-N,N-dimethylpropanamide, and 3-butoxy-N,N-dimethylpropanamide. In this case, it may be preferable that the content of aromatic hydrocarbons (such as benzene, toluene, xylene, and ethylbenzene) as the organic solvent is low (for example, 50 parts per million (ppm) by mass or less, 10 ppm by mass or less, or 1 ppm by mass or less with respect to the total amount of the organic solvent) in consideration of environmental aspects and the like.

The content of the solvent in the coloring composition is preferably 10% to 95% by mass. The upper limit is preferably 92.5% by mass or less and more preferably 90% by mass or less. From the viewpoint of coating properties, the lower limit is preferably 20% by mass or more, more preferably 30% by mass or more, still more preferably 50% by mass or more, and even more preferably 75% by mass or more.

<<Other Components>>

In the present invention, optionally, the coloring composition may further contain a sensitizer, a curing accelerator, a filler, a thermal curing accelerator, a plasticizer, and other auxiliary agents (for example, conductive particles, an antifoaming agent, a flame retardant, a leveling agent, a peeling accelerator, an aromatic chemical, a surface tension adjuster, or a chain transfer agent). By appropriately containing these components, properties such as film properties can be adjusted. The details of the components can be found in, for example, paragraph No. 0183 of JP2012-003225A (corresponding to paragraph No. 0237 of US2013/0034812A) and paragraph Nos. 0101 to 0104 and 0107 to 0109 of JP2008-250074A, the contents of which are incorporated herein by reference. In addition, optionally, the coloring composition according to the embodiment of the present invention may contain a potential antioxidant. Examples of the potential antioxidant include a compound in which a site functioning as an antioxidant is protected by a protective group, and the protective group is eliminated by heating the compound at 100° C. to 250° C. or heating the compound at 80° C. to 200° C. in the presence of an acid or base catalyst so that the compound functions as an antioxidant. Examples of the potential antioxidant include compounds described in WO2014/021023A, WO2017/030005A, and JP2017-008219A. Examples of a commercially available product of the potential antioxidant include ADEKA ARKLS GPA-5001 (manufactured by ADEKA Corporation).

<Storage Container>

A storage container for the coloring composition is not particularly limited, and a known storage container can be used. In addition, as the storage container, it is also preferable to use a multilayer bottle having an interior wall constituted with six layers from six kinds of resins or a bottle having a 7-layer structure from 6 kinds of resins for the purpose of suppressing infiltration of impurities into raw materials or coloring compositions. Examples of such a container include the containers described in JP2015-123351A. In addition, for the purpose of preventing metal elution from the container interior wall, improving storage stability of the coloring composition, and suppressing the alteration of components, it is also preferable that the container interior wall is formed of glass, stainless steel, or the like.

<Method of Preparing Coloring Composition>

The coloring composition according to the embodiment of the present invention can be prepared by mixing the above-described components with each other. In the preparation of the coloring composition, all the components may be dissolved and/or dispersed at the same time in a solvent to prepare the coloring composition, or the respective components may be appropriately left in two or more solutions or dispersion liquids and mixed to prepare the coloring composition upon use (during coating), as desired.

In addition, in the preparation of the coloring composition, a process of dispersing the pigment is preferably included. In the process for dispersing the pigment, examples of a mechanical force which is used for dispersing the pigment include compression, pressing, impact, shear, and cavitation. Specific examples of these processes include a beads mill, a sand mill, a roll mill, a ball mill, a paint shaker, a microfluidizer, a high-speed impeller, a sand grinder, a flow jet mixer, high-pressure wet atomization, and ultrasonic dispersion. In addition, in the pulverization of the pigment in a sand mill (beads mill), it is preferable to perform a treatment under the condition for increasing a pulverization efficiency by using beads having small diameters; increasing the filling rate of the beads; or the like. Incidentally, it is preferable to remove coarse particles by filtration, centrifugation, or the like after the pulverization treatment. In addition, as the process and the dispersing machine for dispersing the pigment, the process and the dispersing machine described in “Dispersion Technology Comprehension, published by Johokiko Co., Ltd., Jul. 15, 2005”, “Actual comprehensive data collection on dispersion technology and industrial application centered on suspension (solid/liquid dispersion system), published by Publication Department, Management Development Center, Oct. 10, 1978”, and paragraph No. 0022 of JP2015-157893A can be suitably used. In addition, in the process for dispersing the pigment, a refining treatment of particles in a salt milling step may be performed. With regard to the materials, equipment, treatment conditions, and the like used in the salt milling step, reference can be made to, for example, the description in JP2015-194521A and JP2012-046629A.

During the preparation of the coloring composition, it is preferable that the coloring composition is filtered through a filter, for example, in order to remove foreign matter or to reduce defects. As the filter, any filters that have been used in the related art for filtration use and the like may be used without particular limitation. Examples of a material of the filter include: a fluororesin such as polytetrafluoroethylene (PTFE) and polyvinylidene fluoride (PVDF); a polyamide resin such as nylon (for example, nylon-6 or nylon-6,6); and a polyolefin resin (including a polyolefin resin having a high density and an ultrahigh molecular weight) such as polyethylene or polypropylene (PP). Among these materials, polypropylene (including a high-density polypropylene) and nylon are preferable.

The pore size of the filter is preferably 0.01 to 7.0 μm, more preferably 0.01 to 3.0 μm, and still more preferably 0.05 to 0.5 μm. In a case where the pore size of the filter is within the above-described range, fine foreign matters can be reliably removed. With regard to the pore size value of the filter, reference can be made to a nominal value of filter manufacturers.

As the filter, various filters provided by Nihon Pall Corporation (DFA4201NXEY, DFA4201NAEY, DFA4201J006P, and the like), Toyo Roshi Kaisha., Ltd., Nihon Entegris K.K. (formerly Nippon Microlith Co., Ltd.), Kitz Micro Filter Corporation, and the like can be used.

In addition, it is preferable that a fibrous filter material is used as the filter. Examples of the fibrous filter material include a polypropylene fiber, a nylon fiber, and a glass fiber. Examples of a commercially available product include SBP type series (SBP008 and the like), TPR type series (TPR002, TPR005, and the like), or SHPX type series (SHPX003 and the like), all manufactured by Roki Techno Co., Ltd.

In a case of using a filter, different filters (for example, a first filter, a second filter, and the like) may be combined. In this case, the filtration with each of the filters may be performed once or may be performed twice or more times. In addition, filters having different pore sizes within the above-described range may be combined. In addition, the filtration through the first filter may be performed with only a dispersion liquid, the other components may be mixed therewith, and then the filtration through the second filter may be performed.

<Film>

A film according to an embodiment of the present invention is a film obtained from the above-described coloring composition according to the embodiment of the present invention. A thickness of the film according to the embodiment of the present invention can be adjusted according to the purpose. For example, the film thickness is preferably 20 μm or less, more preferably 10 μm or less, and still more preferably 5 μm or less. The lower limit of the film thickness is preferably 0.1 μm or more, more preferably 0.2 μm or more, and still more preferably 0.3 μm or more.

The film according to the embodiment of the present invention can be used for a color filter, a near-infrared transmitting filter, a black matrix, a light-shielding film, and the like.

The film according to the embodiment of the present invention can be preferably used as a colored pixel of a color filter. Examples of the colored pixel include a red pixel, a blue pixel, a green pixel, a yellow pixel, a cyan pixel, and a magenta pixel.

<Method for Producing Film>

The film according to the embodiment of the present invention can be manufactured through a step of applying the coloring composition according to the embodiment of the present invention on a support. The method for manufacturing the film according to the embodiment of the present invention preferably further includes a step of forming a pattern (pixel). Examples of a method for forming the pattern (pixel) include a photolithography method and a dry etching method, and a photolithography method is preferable.

(Photolithography Method)

First, a case of forming the pattern by a photolithography method to manufacture a film will be described. Pattern formation by a photolithography method preferably includes a step of forming a coloring composition layer on a support using the coloring composition according to the embodiment of the present invention, a step of exposing the coloring composition layer in a patterned manner, and a step of removing a non-exposed portion of the coloring composition layer by development to form a pattern (pixel). A step (pre-baking step) of baking the coloring composition layer and a step (post-baking step) of baking the developed pattern (pixel) may be provided, optionally.

In the step of forming a coloring composition layer, the coloring composition layer is formed on a support, using the coloring composition. The support is not particularly limited, and can be appropriately selected depending on applications. Examples thereof include a glass substrate and a silicon substrate, and a silicon substrate is preferable. In addition, a charge coupled device (CCD), a complementary metal-oxide semiconductor (CMOS), a transparent conductive film, or the like may be formed on the silicon substrate. In some cases, a black matrix for isolating each pixel is formed on the silicon substrate. In addition, a base layer may be provided on the silicon substrate so as to improve adhesiveness to an upper layer, prevent the diffusion of materials, or planarize the surface of the substrate. A surface contact angle of the base layer is preferably 20° to 70° in a case of being measured with diiodomethane. In addition, the surface contact angle of the base layer is preferably 30° to 80° in a case of being measured with water. In a case where the surface contact angle of the base layer is within the above-described range, coating property of the coloring composition is good. The surface contact angle of the base layer can be adjusted by, for example, adding a surfactant.

As a method of applying the coloring composition, a known method can be used. Examples thereof include a dropping method (drop casting); a slit coating method; a spray method; a roll coating method; a spin coating method (spin coating); a cast coating method; a slit and spin method; a pre-wet method (for example, a method described in JP2009-145395A), various printing methods such as an ink jet (for example, on-demand type, piezo type, thermal type), a discharge printing such as nozzle jet, a flexo printing, a screen printing, a gravure printing, a reverse offset printing, and a metal mask printing; a transfer method using molds and the like; and a nanoimprinting method. A method for applying the ink jet is not particularly limited, and examples thereof include a method described in “Extension of Use of Ink Jet-Infinite Possibilities in Patent-” (February, 2005, S. B. Research Co., Ltd.) (particularly pp. 115 to 133) and methods described in JP2003-262716A, JP2003-185831A, JP2003-261827A, JP2012-126830A, and JP2006-169325A. In addition, with regard to the method for applying the coloring composition, reference can be made to the description in WO2017/030174A and WO2017/018419A, the contents of which are incorporated herein by reference.

The coloring composition layer formed on the support may be dried (pre-baked). In a case of producing a film by a low-temperature process, pre-baking may not be performed. In a case of performing the pre-baking, the pre-baking temperature is preferably 150° C. or lower, more preferably 120° C. or lower, and still more preferably 110° C. or lower. The lower limit may be set to, for example, 50° C. or higher, or to 80° C. or higher. The pre-baking time is preferably 10 to 300 seconds, more preferably 40 to 250 seconds, and still more preferably 80 to 220 seconds. The pre-baking can be performed using a hot plate, an oven, or the like.

Next, the coloring composition layer is exposed in a patterned manner (exposing step). For example, the coloring composition layer can be exposed in a patterned manner using a stepper exposure device or a scanner exposure device through a mask having a predetermined mask pattern. Thus, the exposed portion can be cured.

Examples of the radiation (light) which can be used during the exposure include g-rays and i-rays. In addition, light (preferably light having a wavelength of 180 to 300 nm) having a wavelength of 300 nm or less can be used. Examples of the light having a wavelength of 300 nm or less include KrF-rays (wavelength: 248 nm) and ArF-rays (wavelength: 193 nm), and KrF-rays (wavelength: 248 nm) are preferable. In addition, a long-wave light source of 300 nm or more can be used.

In addition, in a case of exposure, the photosensitive composition layer may be irradiated with light continuously to expose the photosensitive composition layer, or the photosensitive composition layer may be irradiated with light in a pulse to expose the photosensitive composition layer (pulse exposure). The pulse exposure refers to an exposing method in which light irradiation and resting are repeatedly performed in a short cycle (for example, millisecond-level or less).

The irradiation amount (exposure amount) is, for example, preferably 0.03 to 2.5 J/cm² and more preferably 0.05 to 1.0 J/cm². The oxygen concentration during the exposure can be appropriately selected, and the exposure may also be performed, for example, in a low-oxygen atmosphere having an oxygen concentration of 19% by volume or less (for example, 15% by volume, 5% by volume, and substantially oxygen-free) or in a high-oxygen atmosphere having an oxygen concentration of more than 21% by volume (for example, 22% by volume, 30% by volume, and 50% by volume), in addition to an atmospheric air. In addition, the exposure illuminance can be appropriately set, and can be usually selected from a range of 1000 W/m² to 100000 W/m² (for example, 5000 W/m², 15000 W/m², or 35000 W/m²). Appropriate conditions of each of the oxygen concentration and the exposure illuminance may be combined, and for example, a combination of the oxygen concentration of 10% by volume and the illuminance of 10000 W/m², a combination of the oxygen concentration of 35% by volume and the illuminance of 20000 W/m², or the like is available.

Next, the non-exposed portion of the coloring composition layer is removed by development to form a pattern (pixel). The non-exposed portion of the coloring composition layer can be removed by development using a developer. Thus, the coloring composition layer of the non-exposed portion in the exposing step is eluted into the developer, and as a result, only a photocured portion remains. The temperature of the developer is preferably, for example, 20° C. to 30° C. The development time is preferably 20 to 180 seconds. In addition, in order to improve residue removing properties, a step of removing the developer by shaking off per 60 seconds and supplying a fresh developer may be repeated multiple times.

Examples of the developer include an organic solvent and an alkali developer, and an alkali developer is preferably used. As the alkali developer, an alkaline aqueous solution (alkali developer) in which an alkali agent is diluted with pure water is preferable. Examples of the alkali agent include organic alkaline compounds such as ammonia, ethylamine, diethylamine, dimethylethanolamine, diglycol amine, diethanolamine, hydroxyamine, ethylenediamine, tetramethylammonium hydroxide, tetraethylammonium hydroxide, tetrapropylammonium hydroxide, tetrabutylammonium hydroxide, ethyltrimethylammonium hydroxide, benzyltrimethylammonium hydroxide, dimethylbis(2-hydroxyethyl)ammonium hydroxide, choline, pyrrole, piperidine, and 1,8-diazabicyclo[5.4.0]-7-undecene, and inorganic alkaline compounds such as sodium hydroxide, potassium hydroxide, sodium carbonate, sodium hydrogen carbonate, sodium silicate, and sodium metasilicate. In consideration of environmental aspects and safety aspects, the alkali agent is preferably a compound having a high molecular weight. The concentration of the alkali agent in the alkaline aqueous solution is preferably 0.001% to 10% by mass and more preferably 0.01% to 1% by mass. In addition, the developer may further contain a surfactant. Examples of the surfactant include the surfactants described above, and the surfactant is preferably a nonionic surfactant. From the viewpoint of transportation, storage, and the like, the developer may be first produced as a concentrated solution and then diluted to a concentration required upon the use. The dilution ratio is not particularly limited, and can be set to, for example, a range of 1.5 to 100 times. In addition, it is also preferable to wash (rinse) with pure water after development. In addition, it is preferable that the rinsing is performed by supplying a rinsing liquid to the coloring composition layer after development while rotating the support on which the coloring composition layer after development is formed. In addition, it is preferable that the rinsing is performed by moving a nozzle discharging the rinsing liquid from a center of the support to a peripheral edge of the support. In this case, in the movement of the nozzle from the center of the support to the peripheral edge of the support, the nozzle may be moved while gradually decreasing the moving speed of the nozzle. By performing rinsing in this manner, in-plane variation of rinsing can be suppressed. In addition, the same effect can be obtained by gradually decreasing the rotating speed of the support while moving the nozzle from the center of the support to the peripheral edge of the support.

After the development, it is preferable to carry out an additional exposure treatment or a heating treatment (post-baking) after carrying out drying. The additional exposure treatment or the post-baking is a curing treatment after development in order to complete curing. The heating temperature in the post-baking is preferably, for example, 100° C. to 240° C. and more preferably 200° C. to 240° C. The film after development is post-baked continuously or batchwise using a heating unit such as a hot plate, a convection oven (hot air circulation dryer), and a high-frequency heater under the above-described conditions. In a case of performing the additional exposure treatment, light used for the exposure is preferably light having a wavelength of 400 nm or less. In addition, the additional exposure treatment may be carried out by the method described in KR10-2017-0122130A.

In this way, the pixel can be formed. A film thickness of the formed pixel can be adjusted according to the purpose. For example, the film thickness is preferably 10 μm or less, more preferably 5 μm or less, still more preferably 1 μm or less, and even more preferably 0.5 μm or less. The lower limit of the film thickness is preferably 0.1 μm or more, more preferably 0.2 μm or more, and still more preferably 0.3 μm or more.

A line width (size) of the formed pixel can be adjusted according to the purpose. For example, the line width is preferably 5 μm or less, more preferably 3 μm or less, and still more preferably 1.5 μm or less. The lower limit of the line width is preferably 0.1 μm or more, more preferably 0.2 μm or more, and still more preferably 0.3 μm or more.

(Dry etching method) Pattern formation by a dry etching method preferably includes a step of forming a coloring composition layer on a support using the coloring composition according to the embodiment of the present invention and curing the entire coloring composition layer to form a cured composition layer, a step of forming a photoresist layer on the cured composition layer, a step of exposing the photoresist layer in a patterned manner and then developing the photoresist layer to form a resist pattern, and a step of dry-etching the cured composition layer through this resist pattern as a mask and using an etching gas. It is preferable that pre-baking treatment is further performed in order to form the photoresist layer. In particular, as the forming process of the photoresist layer, it is desirable that a heating treatment after exposure and a heating treatment after development (post-baking treatment) are performed. The details of the pattern formation by the dry etching method can be found in paragraph Nos. 0010 to 0067 of JP2013-064993A, the content of which is incorporated herein by reference.

<Optical filter>

An optical filter according to an embodiment of the present invention has the above-described film according to the embodiment of the present invention. Examples of the type of the optical filter include a color filter and a near-infrared transmitting filter, and a color filter is preferable. The color filter preferably has the film according to the embodiment of the present invention as a colored pixel thereof.

In the optical filter, a protective layer may be provided on the surface of the film according to the embodiment of the present invention. By providing the protective layer, various functions such as oxygen shielding, low reflection, hydrophilicity/hydrophobicity, and shielding of light (ultraviolet rays, near-infrared rays, and the like) having a specific wavelength can be imparted. The thickness of the protective layer is preferably 0.01 to 10 μm and more preferably 0.1 to 5 μm. Examples of a method for forming the protective layer include a method of forming the protective layer by applying a resin composition dissolved in an organic solvent, a chemical vapor deposition method, and a method of attaching a molded resin with an adhesive material. Examples of components constituting the protective layer include a (meth)acrylic resin, an ene-thiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamidoimide resin, a polyolefin resin, a cyclic olefin resin, a polyester resin, a styrene resin, a polyol resin, a polyvinylidene chloride resin, a melamine resin, a urethane resin, an aramid resin, a polyamide resin, an alkyd resin, an epoxy resin, a modified silicone resin, a fluororesin, a polyacrylonitrile resin, a cellulose resin, Si, C, W, Al₂O₃, Mo, SiO₂, and Si₂N₄, and two or more kinds of these components may be contained. For example, in a case of a protective layer for oxygen shielding, it is preferable that the protective layer contains a polyol resin, SiO₂, and Si₂N₄. In addition, in a case of a protective layer for low reflection, it is preferable that the protective layer contains a (meth)acrylic resin and a fluororesin.

In a case of forming the protective layer by applying a resin composition, as a method for applying the resin composition, a known method such as a spin coating method, a casting method, a screen printing method, and an ink jet method can be used. As the organic solvent included in the resin composition, a known organic solvent (for example, propylene glycol 1-monomethyl ether 2-acetate, cyclopentanone, ethyl lactate, and the like) can be used. In a case of forming the protective layer by a chemical vapor deposition method, as the chemical vapor deposition method, a known chemical vapor deposition method (thermochemical vapor deposition method, plasma chemical vapor deposition method, and photochemical vapor deposition method) can be used.

The protective layer may contain, as desired, an additive such as organic or inorganic fine particles, an absorber of light (for example, ultraviolet rays, near-infrared rays, and the like) having a specific wavelength, a refractive index adjusting agent, an antioxidant, an adhesive agent, and a surfactant. Examples of the organic or inorganic fine particles include polymer fine particles (for example, silicone resin fine particles, polystyrene fine particles, and melamine resin fine particles), titanium oxide, zinc oxide, zirconium oxide, indium oxide, aluminum oxide, titanium nitride, titanium oxynitride, magnesium fluoride, hollow silica, silica, calcium carbonate, and barium sulfate. As the absorber of light having a specific wavelength, a known absorber can be used. The content of these additives can be appropriately adjusted, but is preferably 0.1% to 70% by mass and still more preferably 1% to 60% by mass with respect to the total mass of the protective layer.

In addition, as the protective layer, the protective layers described in paragraph Nos. 0073 to 0092 of JP2017-151176A can also be used.

The optical filter may have a structure in which each pixel is embedded in a space partitioned in, for example, a lattice form by a partition wall.

<Solid-State Imaging Element>

A solid-state imaging element according to an embodiment of the present invention has the film according to the embodiment of the present invention. The configuration of the solid-state imaging element according to the embodiment of the present invention is not particularly limited as long as the solid-state imaging element is configured to include the film according to the embodiment of the present invention and functions as a solid-state imaging element. Examples of the configuration include the following configurations.

The solid-state imaging element is configured to have a plurality of photodiodes constituting a light receiving area of the solid-state imaging element (a charge coupled device (CCD) image sensor, a complementary metal-oxide semiconductor (CMOS) image sensor, or the like), and a transfer electrode formed of polysilicon or the like on a substrate; have a light-shielding film having openings only over the light receiving section of the photodiodes on the photodiodes and the transfer electrodes; have a device-protective film formed of silicon nitride or the like, which is formed to coat the entire surface of the light-shielding film and the light receiving section of the photodiodes, on the light-shielding film; and have a color filter on the device-protective film. Further, the solid-state imaging element may also be configured, for example, such that it has a light collecting unit (for example, a microlens, which is the same hereinafter) on a device-protective film under a color filter (a side closer to the substrate), or has a light collecting unit on a color filter. In addition, the color filter may have a structure in which each colored pixel is embedded in a space partitioned in, for example, a lattice shape by a partition wall. The partition wall in this case preferably has a low refractive index for each colored pixel. Examples of an imaging device having such a structure include the devices described in JP2012-227478A, JP2014-179577A, and WO2018/043654A. In addition, as described in JP2019-211559A, an ultraviolet absorbing layer may be provided in the structure of the solid-state imaging element to improve light resistance. An imaging device including the solid-state imaging element according to the embodiment of the present invention can also be used as a vehicle camera or a surveillance camera, in addition to a digital camera or electronic apparatus (mobile phones or the like) having an imaging function.

<Image Display Device>

An image display device according to an embodiment of the present invention has the film according to the embodiment of the present invention. Examples of the image display device include a liquid crystal display device or an organic electroluminescent display device. The definitions of image display devices or the details of the respective image display devices are described in, for example, “Electronic Display Device (Akio Sasaki, Kogyo Chosakai Publishing Co., Ltd., published in 1990)”, “Display Device (Sumiaki Ibuki, Sangyo Tosho Co., Ltd.)”, and the like. In addition, the liquid crystal display device is described in, for example, “Liquid Crystal Display Technology for Next Generation (edited by Tatsuo Uchida, Kogyo Chosakai Publishing Co., Ltd., published in 1994)”. The liquid crystal display device to which the present invention can be applied is not particularly limited, and can be applied to, for example, liquid crystal display devices employing various systems described in the “Liquid Crystal Display Technology for Next Generation”.

### EXAMPLES

Hereinafter, the present invention will be described in more detail with reference to Examples. The materials, the amounts of materials to be used, the proportions, the treatment details, the treatment procedure, or the like shown in the examples below may be modified appropriately as long as the modifications do not depart from the spirit of the present invention. Therefore, the scope of the present invention is not limited to the specific examples shown below.

<Evaluation of Resin>

(Weight-Average Molecular Weight (Mw))

A weight-average molecular weight (Mw) of a resin was measured by gel permeation chromatography (GPC) equipped with a differential refractometer (RI) detector. HLC-8220GPC (manufactured by Tosoh Corporation) was used as a device. Two separation columns were connected in series, and “TSK-GEL SUPER HZM-N” was connected in two to both separation columns. The oven temperature was set to 40° C., tetrahydrofuran was used as an eluent, and the measurement was performed at a flow rate of 0.35 ml/min. A sample was dissolved in a solvent consisting of 1% by mass of the above-described eluent and injected in 20 μL. All molecular weights are values in terms of polystyrene.

(Acid Value of Resin)

The acid value of a resin was a value expressed in terms of solid contents of an acid value (mgKOH/g) measured according to a potentiometric titration method of JIS K 0070.

### Production of Polymer Dispersant

### Production Example 1-1

### Production of Polymer Dispersant (D-1)

50 parts by mass of methyl methacrylate, 50 parts by mass of n-butyl acrylate, and 45.4 parts by mass of propylene glycol monomethyl ether acetate (PGMEA) were charged into a reaction container equipped with gas inlet pipe, thermometer, condenser, and stirrer, and the inside of the reaction container was replaced with nitrogen gas. The inside of the reaction container was heated to 70° C., 6 parts by mass of 3-mercapto-1,2-propanediol was added thereto, 0.12 parts by mass of azobisisobutyronitrile (AIBN) was further added thereto, and the mixture was reacted for 12 hours. It was confirmed by solid content measurement that 95% thereof was reacted. Next, 9.7 parts by mass of pyromellitic acid anhydride, 70.3 parts by mass of PGMEA, and 0.20 parts by mass of 1,8-diazabicyclo-[5.4.0]-7-undecene (DBU) as a catalyst were added thereto, and the mixture was reacted at 120° C. for 7 hours. It was confirmed by acid value measurement that 98% or more of the acid anhydride was half-esterified, and the reaction was terminated. By adding PGMEA to adjust the solid content, a solution of a polymer dispersant (D-1) having the following structure (concentration of solid contents: 50% by mass) was obtained. The acid value of the obtained polymer dispersant (D-1) was 43 mgKOH/g and the weight-average molecular weight was 9000.

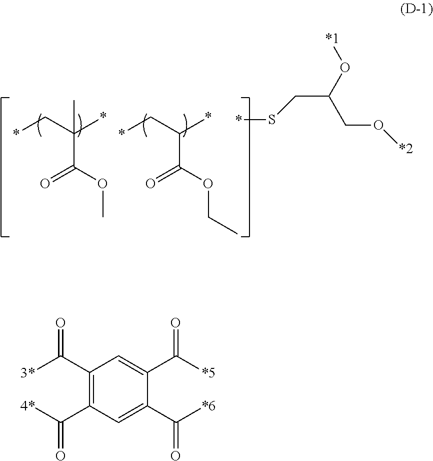

In the formula, one of *1 and *2 is bonded to *5 or *6 to form a polyester main chain, and the other is bonded to *3 or *4 to form a polyester main chain. One of *3 and *4 is bonded to *1 or *2 to form a polyester main chain, and the other is integrated with an OH group to form a carboxyl group. One of *5 and *6 is bonded to *1 or *2 to form a polyester main chain, and the other is integrated with an OH group to form a carboxyl group.

### Production Example 1-2

### Production of Polymer Dispersant (D-2)

8 parts by mass of 3-mercapto-1,2-propanediol, 12 parts by mass of pyromellitic acid anhydride, 80 parts by mass of PGMEA, and 0.2 parts by mass of monobutyltin oxide as a reaction catalyst were charged into a reaction container equipped with gas inlet pipe, thermometer, condenser, and stirrer, the inside of the reaction container was replaced with nitrogen gas, and the mixture was reacted at 120° C. for 5 hours (first step). It was confirmed by acid value measurement that 95% or more of the acid anhydride was half-esterified. Next, 25 parts by mass of methyl methacrylate, 10 parts by mass of t-butyl acrylate, 10 parts by mass of ethyl acrylate, 5 parts by mass of methacrylic acid, 10 parts by mass of benzyl methacrylate, and 40 parts by mass of 2-hydroxyethyl methacrylate were charged thereto, the inside of the reaction container was heated to 80° C., 1 part by mass of 2,2′-azobis(2,4-dimethylvaleronitrile) was added thereto, and the mixture was reacted for 12 hours (second step). It was confirmed by solid content measurement that 95% thereof was reacted. Next, the inside of a flask was replaced with air, 43 parts by mass of 2-methacryloyloxyethyl isocyanate and 0.1 parts by mass of hydroquinone were charged thereto, and the mixture was reacted at 70° C. for 4 hours (third step). After confirming by infrared absorption spectroscopy that the peak of 2270 cm⁻¹ based on the isocyanate group disappeared, the reaction solution was cooled, and the solid content was adjusted with PGMEA, thereby obtaining a solution of a polymer dispersant (D-2) having the following structure (concentration of solid contents: 40% by mass). The acid value of the obtained polymer dispersant (D-2) was 40 mgKOH/g, the weight-average molecular weight was 12000, and the ethylenically unsaturated bond-containing group value (C═C value) was 588 g/mol.

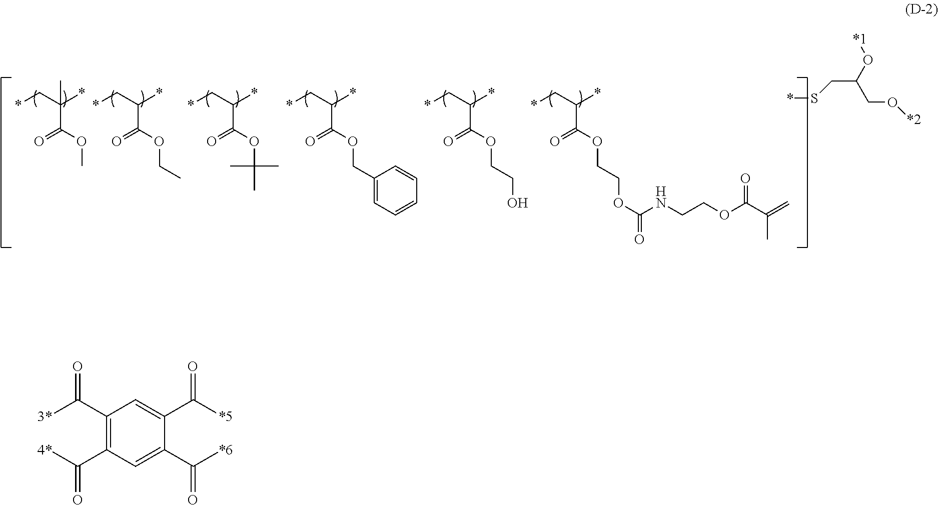

In the formula, one of *1 and *2 is bonded to *5 or *6 to form a polyester main chain, and the other is bonded to *3 or *4 to form a polyester main chain. One of *3 and *4 is bonded to *1 or *2 to form a polyester main chain, and the other is integrated with an OH group to form a carboxyl group. One of *5 and *6 is bonded to *1 or *2 to form a polyester main chain, and the other is integrated with an OH group to form a carboxyl group.

### Production Example 1-3

### Production of Polymer Dispersant (D-3)

8 parts by mass of 3-mercapto-1,2-propanediol, 12 parts by mass of pyromellitic acid anhydride, 80 parts by mass of PGMEA, and 0.2 parts by mass of monobutyltin oxide as a reaction catalyst were charged into a reaction container equipped with gas inlet pipe, thermometer, condenser, and stirrer, the inside of the reaction container was replaced with nitrogen gas, and the mixture was reacted at 120° C. for 5 hours (first step). It was confirmed by acid value measurement that 95% or more of the acid anhydride was half-esterified. Next, 25 parts by mass of methyl methacrylate, 10 parts by mass of t-butyl acrylate, 10 parts by mass of (3-ethyloxetan-yl)methyl acrylate, 5 parts by mass of methacrylic acid, 10 parts by mass of benzyl methacrylate, and 40 parts by mass of 2-hydroxyethyl methacrylate were charged thereto, the inside of the reaction container was heated to 80° C., 1 part by mass of 2,2′-azobis(2,4-dimethylvaleronitrile) was added thereto, and the mixture was reacted for 12 hours (second step). It was confirmed by solid content measurement that 95% thereof was reacted. Next, the inside of a flask was replaced with air, 43 parts by mass of 2-methacryloyloxyethyl isocyanate and 0.1 parts by mass of hydroquinone were charged thereto, and the mixture was reacted at 70° C. for 4 hours (third step). After confirming by infrared absorption spectroscopy that the peak of 2270 cm¹ based on the isocyanate group disappeared, the reaction solution was cooled, and the solid content was adjusted with PGMEA, thereby obtaining a solution of a polymer dispersant (D-3) having the following structure (concentration of solid contents: 40% by mass). The acid value of the obtained polymer dispersant (D-3) was 40 mgKOH/g, the weight-average molecular weight was 10000, and the ethylenically unsaturated bond-containing group value (C═C value) was 588 g/mol.

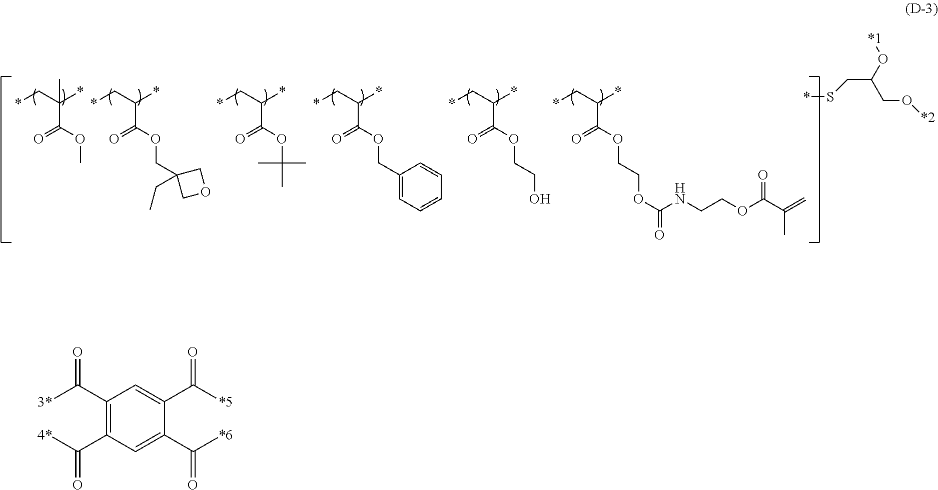

In the formula, one of *1 and *2 is bonded to *5 or *6 to form a polyester main chain, and the other is bonded to *3 or *4 to form a polyester main chain. One of *3 and *4 is bonded to *1 or *2 to form a polyester main chain, and the other is integrated with an OH group to form a carboxyl group. One of *5 and *6 is bonded to *1 or *2 to form a polyester main chain, and the other is integrated with an OH group to form a carboxyl group.

The polymer dispersants (D-1) to (D-3) are materials corresponding the first resin in the present invention.

### Production of Miniaturization Pigment

### Production Example 2-1

### Production of Miniaturization Pigment (PR254M)

100 parts by mass of C. I. Pigment Red 254 (“B-CF” manufactured by BASF SE), 1200 parts by mass of sodium chloride, and 120 parts by mass of diethylene glycol were charged into a stainless steel 1-gallon kneader (manufactured by INOUE MFG., INC.) and kneaded at 60° C. for 4 hours. The obtained kneading composition was put into 3000 parts by mass of warm water and stirred for 1 hour to form a slurry, and the slurry was filtered and washed with water repeatedly to remove sodium chloride and diethylene glycol, and dried at 80° C. for 24 hours to obtain a miniaturization pigment (PR254M).

### Production Examples 2-2 to 2-21

Each miniaturization pigment was obtained by the same treatment as in Production Example 2-1, except that, in Production Example 2-1, the pigment used was changed from C. I. Pigment Red 254 to the pigment shown in the table below.

TABLE 1

| Production | Miniaturization | |
|---|---|---|
| Example | pigment | Pigment as raw material |
| 2-1 | (PR254M) | C. I. Pigment Red 254 |
| | | (“B-CF” manufactured by BASF SE) |
| 2-2 | (PR122M) | C. I. Pigment Red 122 |
| 2-3 | (PR177M) | C. I. Pigment Red 177 |
| | | (“B-CF” manufactured by BASF SE) |
| 2-4 | (PR264M) | C. I. Pigment Red 264 |
| | | (“Irgazin DPP Rubine TR” |
| | | manufactured by BASF SE) |
| 2-5 | (PR272M) | C. I. Pigment Red 272 |
| | | (“Cromophtal DPP Red FP” |
| | | manufactured by BASF SE) |
| 2-6 | (PY139M) | C. I. Pigment Yellow 139 |
| | | (“Paliotol Yellow L 2146HD” |
| | | manufactured by BASF SE) |
| 2-7 | (PY150M) | C. I. Pigment Yellow 150 |
| | | (“E-4GN” manufactured by LANXESS) |
| 2-8 | (PY185M) | C. I. Pigment Yellow 185 |
| | | (“Paliotol Yellow L 1155” |
| | | manufactured by BASF SE) |
| 2-9 | (PY215M) | C. I. Pigment Yellow 215 |
| 2-10 | (PY-1M) | Quinophthalone compound described in |
| | | Synthesis Example 3 of paragraph No. |
| | | 0061 of JP6607427B |
| 2-11 | (PG63M) | C. I. Pigment Green 63 (aluminum |
| | | phthalocyanine pigment) |
| | | (“Optlion Green 8890” manufactured by |
| | | TOYOCOLOR CO., LTD.) |
| 2-12 | (PG62M) | C. I. Pigment Green 62 (aluminum |
| | | phthalocyanine pigment) |
| | | (“Optlion Green 8880” manufactured by |
| | | TOYOCOLOR CO., LTD.) |
| 2-13 | (PG58M) | C. I. Pigment Green 58 |
| | | (“FASTOGEN Green 8880” manufactured |
| | | by DIC Corporation) |
| 2-14 | (PG36M) | C. I. Pigment Green 36 |
| | | (“Green8G” manufactured by CLARIANT) |
| 2-15 | (PG7M) | C. I. Pigment Green 7 |
| | | (“GreenGNX” manufactured by |
| | | CLARIANT) |
| 2-16 | (PB15:6M) | C. I. Pigment Blue 15:6 |
| | | (“LIONOL BLUE ES” manufactured by |
| | | TOYOCOLOR CO., LTD.) |
| 2-17 | (PB15:3M) | C. I. Pigment Blue 15:3 |
| 2-18 | (PB15:4M) | C. I. Pigment Blue 15:4 |
| 2-19 | (PB16M) | C. I. Pigment Blue 16 |
| 2-20 | (PV23M) | C. I. Pigment Violet 23 |
| | | (“LIONOGEN VIOLET RL” manufactured |
| | | by TOYOCOLOR CO., LTD.) |
| 2-21 | (PO71) | C. I. Pigment Orange 71 |

### Production of Pigment Dispersion Liquid

### Production Example 3-11

### Production of Pigment Dispersion Liquid (GB-1)

Materials shown below were mixed by the parts by mass shown below, and then using zirconia beads having a diameter of 0.5 mm, the mixture was dispersed for 3 hours with an Eiger mill (“Mini Model M-250 MKII” manufactured by Eiger Japan Co., Ltd.). Thereafter, the obtained mixture was filtered through a filter having a pore size of 5.0 μm to produce a pigment dispersion liquid (GB-1). In the following, the value of the blending amount of the polymer dispersant (D-1) is a value in a case of being converted to 100% of concentration of solid contents. The value of the blending amount of the solvent is a value obtained by totaling the amount of solvents included in the polymer dispersant.

Miniaturization pigment (PG36M): 11.0 parts by mass
Pigment derivative (Derivative 1): 0.6 parts by mass
Polymer dispersant (D-1): 1.5 parts by mass
Resin 1: 2.0 parts by mass
PGMEA: 84.9 parts by mass

Here, the derivative 1 and the resin 1 are compound represented by the following structural formulae.

Derivative 1: Compound Having the Following Structure

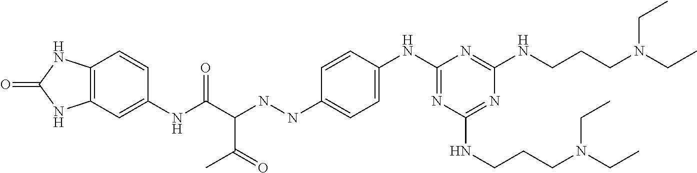 [SMILES: CCN(CC)CCCNc1nc(NCCCN(CC)CC)nc(Nc2ccc(NNC(C(C)=O)C(=O)Nc3ccc4[nH]c(=O)[nH]c4c3)cc2)n1]

Resin 1: resin consisting of a constitutional unit represented by Formula (1-1), a constitutional unit represented by Formula (1-2), and a constitutional unit represented by Formula (1-3) (polyimide precursor, weight-average molecular weight: 24000, solid content: 100% by mass)

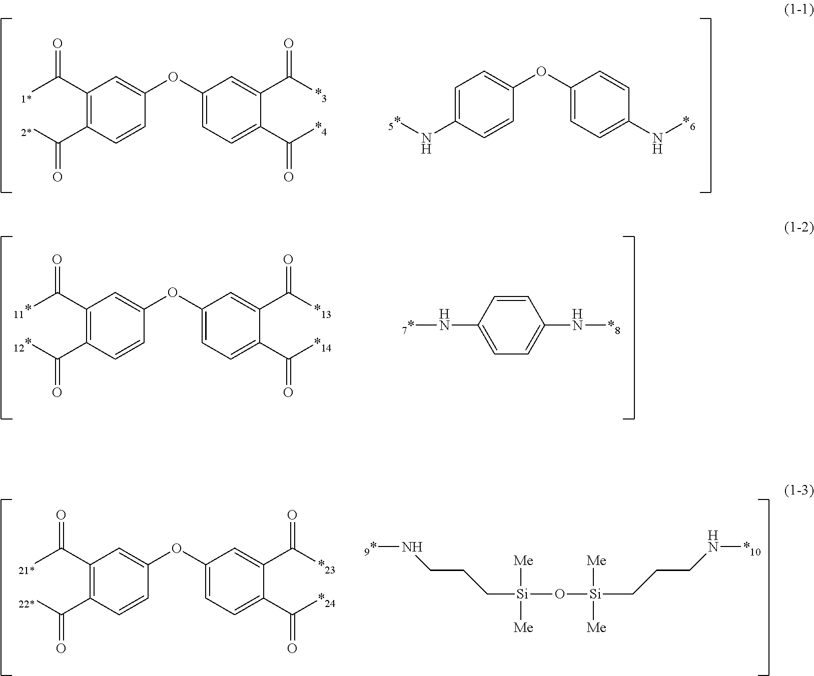

In the formulae, one of *3 and *4 is bonded to *5 to form a main chain of the polyimide precursor, and the other bonded to an OH group or —NH—(CH₂)₂—O—(C═O)—C(CH₃)═CH₂; and one of *1 and *2 is bonded to an OH group or —NH—(CH₂)₂—O—(C═O)—C(CH₃)═CH₂, and the other is bonded to any one of *6, *8, or *10 to form the main chain of the polyimide precursor;

one of *13 and *14 is bonded to *7 to form a main chain of the polyimide precursor, and the other bonded to an OH group or —NH—(CH₂)₂—O—(C═O)—C(CH₃)═CH₂; and one of *11 and *12 is bonded to an OH group or —NH—(CH₂)₂—O—(C═O)—C(CH₃)═CH₂, and the other is bonded to any one of *6, *8, or *10 to form the main chain of the polyimide precursor; and

one of *23 and *24 is bonded to *9 to form a main chain of the polyimide precursor, and the other bonded to an OH group or —NH—(CH₂)₂—O—(C═O)—C(CH₃)═CH₂; and one of *21 and *22 is bonded to an OH group or —NH—(CH₂)₂—O—(C═O)—C(CH₃)═CH₂, and the other is bonded to any one of *6, *8, or *10 to form the main chain of the polyimide precursor.

The resin 1 is a material corresponding to the second resin in the present invention.

### Production Examples 3-2 to 3-89

(Production of pigment dispersion liquids (GB-2) to (GB-17), (RB-1) to (RB-19), (YB-1) to (YB-21), (BB-1) to (BB-16), (VB-1) to (VB-3), (OB-1) to (OB-3), (KB-1) to (KB-6), (GB-c1), (GB-c2), (YB-c1), and (YB-c2))

Pigment dispersion liquids (GB-2) to (GB-17), (RB-1) to (RB-19), (YB-1) to (YB-21), (BB-1) to (BB-16), (VB-1) to (VB-3), (OB-1) to (OB-3), (KB-1) to (KB-6), (GB-c1), (GB-c2), (YB-c1), and (YB-c2) were produced by the same method as in Production Example 3-1, except that the types and addition amounts (parts by mass) of the miniaturization pigments, pigment derivatives, polymer dispersants, resins, and solvents used were changed as shown in the tables below. The values of the blending amounts of the polymer dispersant and the resin are values in a case of being converted to 100% of concentration of solid contents. The value of the blending amount of the solvent is a value obtained by totaling the amount of solvents included in the polymer dispersant and the resin.

TABLE 2

| | | Miniaturization | | Pigment | | Polymer | | | | | |
|---|---|---|---|---|---|---|---|---|---|---|---|
| | Pigment | pigment | | derivative | | dispersant | | Resin | | Solvent | |
| Production | dispersion | | Part by | | Part by | | Part by | | Part by | | Part by |
| Example | liquid | Type | mass | Type | mass | Type | mass | Type | mass | Type | mass |
| 3-1 | (GB-1) | (PG36M) | 11.0 | Derivative 1 | 0.6 | (D-1) | 1.5 | Resin 1 | 2.0 | PGMEA | 84.9 |
| 3-2 | (GB-2) | (PG36M) | 11.0 | Derivative 1 | 0.6 | (D-2) | 1.5 | Resin 1 | 2.0 | PGMEA | 84.9 |
| 3-3 | (GB-3) | (PG36M) | 11.0 | Derivative 1 | 0.6 | (D-3) | 1.5 | Resin 1 | 2.0 | PGMEA | 84.9 |
| 3-4 | (GB-4) | (PG36M) | 11.0 | Derivative 1 | 0.6 | (D-3) | 1.5 | Resin 2 | 2.0 | PGMEA | 84.9 |
| 3-5 | (GB-5) | (PG36M) | 11.0 | Derivative 1 | 0.6 | (D-3) | 1.5 | Resin 3 | 2.0 | PGMEA | 84.9 |
| 3-6 | (GB-6) | (PG7M) | 11.0 | Derivative 1 | 0.6 | (D-3) | 1.5 | Resin 1 | 2.0 | PGMEA | 84.9 |
| 3-7 | (GB-7) | (PG7M) | 11.0 | Derivative 1 | 0.6 | (D-3) | 1.5 | Resin 2 | 2.0 | PGMEA | 84.9 |
| 3-8 | (GB-8) | (PG7M) | 11.0 | Derivative 1 | 0.6 | (D-3) | 1.5 | Resin 3 | 2.0 | PGMEA | 84.9 |
| 3-9 | (GB-9) | (PG58M) | 11.0 | Derivative 1 | 0.6 | (D-3) | 1.5 | Resin 1 | 2.0 | PGMEA | 84.9 |
| 3-10 | (GB-10) | (PG58M) | 11.0 | Derivative 1 | 0.6 | (D-3) | 1.5 | Resin 2 | 2.0 | PGMEA | 84.9 |
| 3-11 | (GB-11) | (PG58M) | 11.0 | Derivative 1 | 0.6 | (D-3) | 1.5 | Resin 3 | 2.0 | PGMEA | 84.9 |
| 3-12 | (GB-12) | (PG62M) | 11.0 | Derivative 1 | 0.6 | (D-3) | 1.5 | Resin 1 | 2.0 | PGMEA | 84.9 |
| 3-13 | (GB-13) | (PG62M) | 11.0 | Derivative 1 | 0.6 | (D-3) | 1.5 | Resin 2 | 2.0 | PGMEA | 84.9 |
| 3-14 | (GB-14) | (PG62M) | 11.0 | Derivative 1 | 0.6 | (D-3) | 1.5 | Resin 3 | 2.0 | PGMEA | 84.9 |
| 3-15 | (GB-15) | (PG63M) | 11.0 | Derivative 1 | 0.6 | (D-3) | 1.5 | Resin 1 | 2.0 | PGMEA | 84.9 |
| 3-16 | (GB-16) | (PG63M) | 11.0 | Derivative 1 | 0.6 | (D-3) | 1.5 | Resin 2 | 2.0 | PGMEA | 84.9 |
| 3-17 | (GB-17) | (PG63M) | 11.0 | Derivative 1 | 0.6 | (D-3) | 1.5 | Resin 3 | 2.0 | PGMEA | 84.9 |
| 3-18 | (RB-1) | (PR122M) | 11.0 | Derivative 1 | 0.6 | (D-3) | 1.5 | Resin 1 | 2.0 | PGMEA | 84.9 |
| 3-19 | (RB-2) | (PR122M) | 11.0 | Derivative 1 | 0.6 | (D-3) | 1.5 | Resin 2 | 2.0 | PGMEA | 84.9 |
| 3-20 | (RB-3) | (PR122M) | 11.0 | Derivative 1 | 0.6 | (D-3) | 1.5 | Resin 3 | 2.0 | PGMEA | 84.9 |
| 3-21 | (RB-4) | (PR177M) | 11.0 | Derivative 1 | 0.6 | (D-3) | 1.5 | Resin 1 | 2.0 | PGMEA | 84.9 |
| 3-22 | (RB-5) | (PR177M) | 11.0 | Derivative 1 | 0.6 | (D-3) | 1.5 | Resin 2 | 2.0 | PGMEA | 84.9 |
| 3-23 | (RB-6) | (PR177M) | 11.0 | Derivative 1 | 0.6 | (D-3) | 1.5 | Resin 3 | 2.0 | PGMEA | 84.9 |
| 3-24 | (RB-7) | (PR254M) | 11.0 | Derivative 1 | 0.6 | (D-3) | 1.5 | Resin 1 | 2.0 | PGMEA | 84.9 |
| 3-25 | (RB-8) | (PR254M) | 11.0 | Derivative 1 | 0.6 | (D-3) | 1.5 | Resin 2 | 2.0 | PGMEA | 84.9 |
| 3-26 | (RB-9) | (PR254M) | 11.0 | Derivative 1 | 0.6 | (D-3) | 1.5 | Resin 3 | 2.0 | PGMEA | 84.9 |
| 3-27 | (RB-10) | (PR264M) | 11.0 | Derivative 1 | 0.6 | (D-3) | 1.5 | Resin 1 | 2.0 | PGMEA | 84.9 |
| 3-28 | (RB-11) | (PR264M) | 11.0 | Derivative 1 | 0.6 | (D-3) | 1.5 | Resin 2 | 2.0 | PGMEA | 84.9 |
| 3-29 | (RB-12) | (PR264M) | 11.0 | Derivative 1 | 0.6 | (D-3) | 1.5 | Resin 3 | 2.0 | PGMEA | 84.9 |
| 3-30 | (RB-13) | (PR264M) | 11.0 | Derivative 1 | 0.6 | (D-3) | 1.5 | Resin 4 | 2.0 | PGMEA | 84.9 |
| 3-31 | (RB-14) | (PR264M) | 11.0 | Derivative 1 | 0.6 | (D-3) | 1.5 | Resin 5 | 2.0 | PGMEA | 84.9 |
| 3-32 | (RB-15) | (PR264M) | 11.0 | Derivative 1 | 0.6 | (D-3) | 0.8 | Resin 1 | 2.7 | PGMEA | 84.9 |
| 3-33 | (RB-16) | (PR264M) | 11.0 | Derivative 1 | 0.6 | (D-3) | 2.9 | Resin 1 | 0.6 | PGMEA | 84.9 |
| 3-34 | (RB-17) | (PR272M) | 11.0 | Derivative 1 | 0.6 | (D-3) | 1.5 | Resin 1 | 2.0 | PGMEA | 84.9 |
| 3-35 | (RB-18) | (PR272M) | 11.0 | Derivative 1 | 0.6 | (D-3) | 1.5 | Resin 2 | 2.0 | PGMEA | 84.9 |
| 3-36 | (RB-19) | (PR272M) | 11.0 | Derivative 1 | 0.6 | (D-3) | 1.5 | Resin 3 | 2.0 | PGMEA | 84.9 |
| 3-37 | (YB-1) | (PY139M) | 11.0 | Derivative 1 | 0.6 | (D-3) | 1.5 | Resin 1 | 2.0 | PGMEA | 84.9 |
| 3-38 | (YB-2) | (PY139M) | 11.0 | Derivative 1 | 0.6 | (D-3) | 1.5 | Resin 2 | 2.0 | PGMEA | 84.9 |
| 3-39 | (YB-3) | (PY139M) | 11.0 | Derivative 1 | 0.6 | (D-3) | 1.5 | Resin 3 | 2.0 | PGMEA | 84.9 |
| 3-40 | (YB-4) | (PY150M) | 11.0 | Derivative 1 | 0.6 | (D-1) | 1.5 | Resin 1 | 2.0 | PGMEA | 84.9 |

TABLE 3

| | | Miniaturization | | Pigment | | Polymer | | | | | |
|---|---|---|---|---|---|---|---|---|---|---|---|
| | Pigment | pigment | | derivative | | dispersant | | Resin | | Solvent | |
| Production | dispersion | | Part by | | Part by | | Part by | | Part by | | Part by |
| Example | liquid | Type | mass | Type | mass | Type | mass | Type | mass | Type | mass |
| 3-41 | (YB-5) | (PY150M) | 11.0 | Derivative 1 | 0.6 | (D-2) | 1.5 | Resin 1 | 2.0 | PGMEA | 84.9 |
| 3-42 | (YB-6) | (PY150M) | 11.0 | Derivative 1 | 0.6 | (D-3) | 1.5 | Resin 1 | 2.0 | PGMEA | 84.9 |
| 3-43 | (YB-7) | (PY150M) | 11.0 | Derivative 1 | 0.6 | (D-3) | 1.5 | Resin 2 | 2.0 | PGMEA | 84.9 |
| 3-44 | (YB-8) | (PY150M) | 11.0 | Derivative 1 | 0.6 | (D-3) | 1.5 | Resin 3 | 2.0 | PGMEA | 84.9 |
| 3-45 | (YB-9) | (PY185M) | 11.0 | Derivative 1 | 0.6 | (D-3) | 1.5 | Resin 1 | 2.0 | PGMEA | 84.9 |
| 3-46 | (YB-10) | (PY185M) | 11.0 | Derivative 1 | 0.6 | (D-3) | 1.5 | Resin 2 | 2.0 | PGMEA | 84.9 |
| 3-47 | (YB-11) | (PY185M) | 11.0 | Derivative 1 | 0.6 | (D-3) | 1.5 | Resin 3 | 2.0 | PGMEA | 84.9 |
| 3-48 | (YB-12) | (PY215M) | 11.0 | Derivative 1 | 0.6 | (D-3) | 1.5 | Resin 1 | 2.0 | PGMEA | 84.9 |
| 3-49 | (YB-13) | (PY215M) | 11.0 | Derivative 1 | 0.6 | (D-3) | 1.5 | Resin 2 | 2.0 | PGMEA | 84.9 |
| 3-50 | (YB-14) | (PY215M) | 11.0 | Derivative 1 | 0.6 | (D-3) | 1.5 | Resin 3 | 2.0 | PGMEA | 84.9 |
| 3-51 | (YB-15) | (PY215M) | 11.0 | Derivative 1 | 0.6 | (D-3) | 1.5 | Resin 4 | 2.0 | PGMEA | 84.9 |
| 3-52 | (YB-16) | (PY215M) | 11.0 | Derivative 1 | 0.6 | (D-3) | 1.5 | Resin 5 | 2.0 | PGMEA | 84.9 |
| 3-53 | (YB-17) | (PY215M) | 11.0 | Derivative 1 | 0.6 | (D-3) | 0.8 | Resin 1 | 2.7 | PGMEA | 84.9 |
| 3-54 | (YB-18) | (PY215M) | 11.0 | Derivative 1 | 0.6 | (D-3) | 2.9 | Resin 1 | 0.6 | PGMEA | 84.9 |
| 3-55 | (YB-19) | (PY-1M) | 11.0 | Derivative 1 | 0.6 | (D-3) | 1.5 | Resin 1 | 2.0 | PGMEA | 84.9 |
| 3-56 | (YB-20) | (PY-1M) | 11.0 | Derivative 1 | 0.6 | (D-3) | 1.5 | Resin 2 | 2.0 | PGMEA | 84.9 |
| 3-57 | (YB-21) | (PY-1M) | 11.0 | Derivative 1 | 0.6 | (D-3) | 1.5 | Resin 3 | 2.0 | PGMEA | 84.9 |
| 3-58 | (BB-1) | (PB15:6M) | 11.0 | Derivative 2 | 0.6 | (D-3) | 1.5 | Resin 1 | 2.0 | PGMEA | 84.9 |
| 3-59 | (BB-2) | (PB15:6M) | 11.0 | Derivative 2 | 0.6 | (D-3) | 1.5 | Resin 2 | 2.0 | PGMEA | 84.9 |
| 3-60 | (BB-3) | (PB15:6M) | 11.0 | Derivative 2 | 0.6 | (D-3) | 1.5 | Resin 3 | 2.0 | PGMEA | 84.9 |
| 3-61 | (BB-4) | (PB15:3M) | 11.0 | Derivative 2 | 0.6 | (D-3) | 1.5 | Resin 1 | 2.0 | PGMEA | 84.9 |
| 3-62 | (BB-5) | (PB15:3M) | 11.0 | Derivative 2 | 0.6 | (D-3) | 1.5 | Resin 2 | 2.0 | PGMEA | 84.9 |
| 3-63 | (BB-6) | (PB15:3M) | 11.0 | Derivative 2 | 0.6 | (D-3) | 1.5 | Resin 3 | 2.0 | PGMEA | 84.9 |
| 3-64 | (BB-7) | (PB15:4M) | 11.0 | Derivative 2 | 0.6 | (D-3) | 1.5 | Resin 1 | 2.0 | PGMEA | 84.9 |
| 3-65 | (BB-8) | (PB15:4M) | 11.0 | Derivative 2 | 0.6 | (D-3) | 1.5 | Resin 2 | 2.0 | PGMEA | 84.9 |
| 3-66 | (BB-9) | (PB15:4M) | 11.0 | Derivative 2 | 0.6 | (D-3) | 1.5 | Resin 3 | 2.0 | PGMEA | 84.9 |
| 3-67 | (BB-10) | (PB16M) | 11.0 | Derivative 2 | 0.6 | (D-3) | 1.5 | Resin 1 | 2.0 | PGMEA | 84.9 |
| 3-68 | (BB-11) | (PB16M) | 11.0 | Derivative 2 | 0.6 | (D-3) | 1.5 | Resin 2 | 2.0 | PGMEA | 84.9 |
| 3-69 | (BB-12) | (PB16M) | 11.0 | Derivative 2 | 0.6 | (D-3) | 1.5 | Resin 3 | 2.0 | PGMEA | 84.9 |
| 3-70 | (BB-13) | (PB16M) | 11.0 | Derivative 2 | 0.6 | (D-3) | 1.5 | Resin 4 | 2.0 | PGMEA | 84.9 |
| 3-71 | (BB-14) | (PB16M) | 11.0 | Derivative 2 | 0.6 | (D-3) | 1.5 | Resin 5 | 2.0 | PGMEA | 84.9 |
| 3-72 | (BB-15) | (PB16M) | 11.0 | Derivative 2 | 0.6 | (D-3) | 0.8 | Resin 1 | 2.7 | PGMEA | 84.9 |
| 3-73 | (BB-16) | (PB16M) | 11.0 | Derivative 2 | 0.6 | (D-3) | 2.9 | Resin 1 | 0.6 | PGMEA | 84.9 |
| 3-74 | (VB-1) | (PV23M) | 11.0 | Derivative 3 | 0.6 | (D-3) | 1.5 | Resin 1 | 2.0 | PGMEA | 84.9 |
| 3-75 | (VB-2) | (PV23M) | 11.0 | Derivative 3 | 0.6 | (D-3) | 1.5 | Resin 2 | 2.0 | PGMEA | 84.9 |
| 3-76 | (VB-3) | (PV23M) | 11.0 | Derivative 3 | 0.6 | (D-3) | 1.5 | Resin 3 | 2.0 | PGMEA | 84.9 |
| 3-77 | (OB-1) | (PO71) | 11.0 | Derivative 1 | 0.6 | (D-3) | 1.5 | Resin 1 | 2.0 | PGMEA | 84.9 |
| 3-78 | (OB-2) | (PO71) | 11.0 | Derivative 1 | 0.6 | (D-3) | 1.5 | Resin 2 | 2.0 | PGMEA | 84.9 |
| 3-79 | (OB-3) | (PO71) | 11.0 | Derivative 1 | 0.6 | (D-3) | 1.5 | Resin 3 | 2.0 | PGMEA | 84.9 |
| 3-80 | (KB-1) | (CB) | 11.0 | Derivative 1 | 0.6 | (D-3) | 1.5 | Resin 1 | 2.0 | PGMEA | 84.9 |
| 3-81 | (KB-2) | (CB) | 11.0 | Derivative 1 | 0.6 | (D-3) | 1.5 | Resin 2 | 2.0 | PGMEA | 84.9 |
| 3-82 | (KB-3) | (CB) | 11.0 | Derivative 1 | 0.6 | (D-3) | 1.5 | Resin 3 | 2.0 | PGMEA | 84.9 |
| 3-83 | (KB-4) | (TiB) | 11.0 | Derivative 1 | 0.6 | (D-3) | 1.5 | Resin 1 | 2.0 | PGMEA | 84.9 |
| 3-84 | (KB-5) | (TiB) | 11.0 | Derivative 1 | 0.6 | (D-3) | 1.5 | Resin 2 | 2.0 | PGMEA | 84.9 |
| 3-85 | (KB-6) | (TiB) | 11.0 | Derivative 1 | 0.6 | (D-3) | 1.5 | Resin 3 | 2.0 | PGMEA | 84.9 |
| 3-86 | (GB-c1) | (PG36M) | 11.0 | Derivative 1 | 0.6 | (D-1) | 1.5 | Resin c1 | 2.0 | PGMEA | 84.9 |
| 3-87 | (GB-c2) | (PG36M) | 11.0 | Derivative 1 | 0.6 | | | Resin 1 | 3.5 | PGMEA | 84.9 |
| 3-88 | (YB-c1) | (PY150M) | 11.0 | Derivative 1 | 0.6 | (D-1) | 1.5 | Resin c1 | 2.0 | PGMEA | 84.9 |
| 3-89 | (YB-c2) | (PY150M) | 11.0 | Derivative 1 | 0.6 | | | Resin 1 | 3.5 | PGMEA | 84.9 |

In the above tables, TiB is titanium nitride particles (manufactured by Mitsubishi Materials Electronic Chemicals Co., Ltd.), and CB is carbon black particles (manufactured by Cabot Corporation). The derivatives 2 and 3 are the following compounds. The resins 2 to 5 are resins having the following structures.

(Pigment Derivative)

Derivative 2: Compound Having the Following Structure

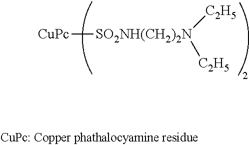

Derivative 3: Compound Having the Following Structure

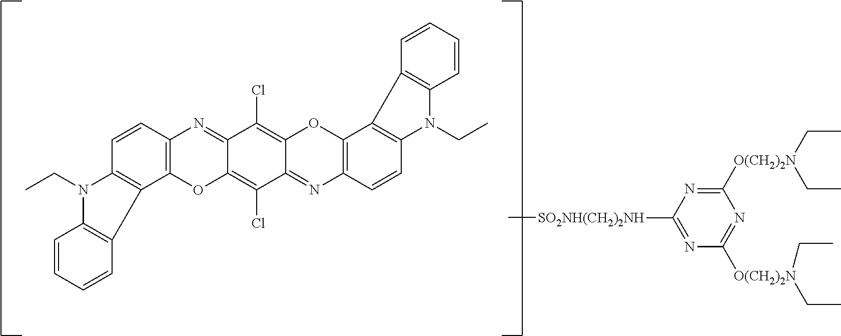

(Resin)

Resin 2: resin having the following structure (polybenzoxazole precursor, weight-average molecular weight: 21000, solid content: 100% mass)

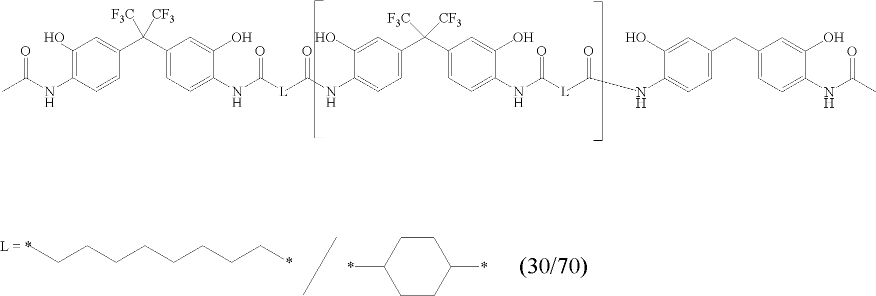

Resin 3: resin having the following structure (epoxy-modified polysiloxane resin, COMPOCERAN E103D, manufactured by Arakawa Chemical Industries, Ltd., solid content: 49% b mass

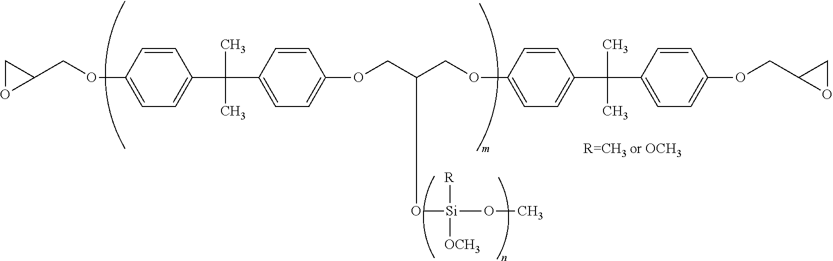

Resin 4: resin consisting of a constitutional unit represented by Formula (4-1) and a constitutional unit represented by Formula (4-2) (polyimide precursor, weight-average molecular weight: 18000, solid content: 100% by mass)

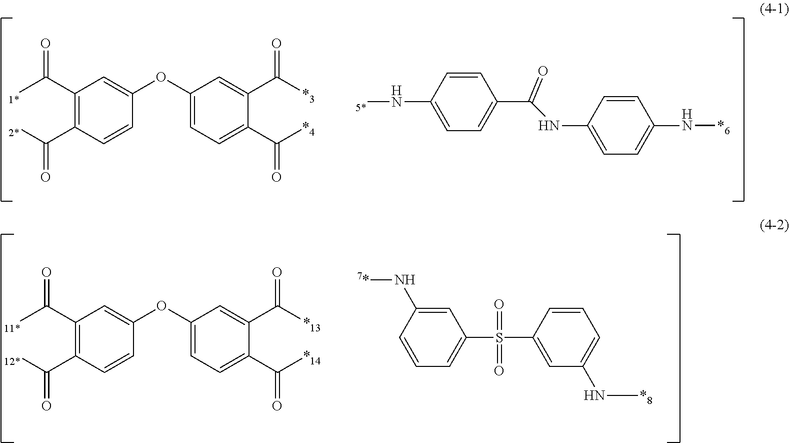

In the formulae, one of *3 and *4 is bonded to *5 to form a main chain of the polyimide precursor, and the other bonded to an OH group to form a carboxyl group; and one of *1 and *2 is bonded to an OH group to form a carboxyl group, and the other is bonded to any one of *6 or *8 to form the main chain of the polyimide precursor; and

one of *13 and *14 is bonded to *7 to form a main chain of the polyimide precursor, and the other bonded to an OH group to form a carboxyl group; and one of *11 and *12 is bonded to an OH group to form a carboxyl group, and the other is bonded to any one of *6 or *8 to form the main chain of the polyimide precursor.

Resin 5: resin consisting of a constitutional unit represented by Formula (5-1) and a constitutional unit represented by Formula (5-2) (polyimide precursor, weight-average molecular weight 2000, solid content: 10%

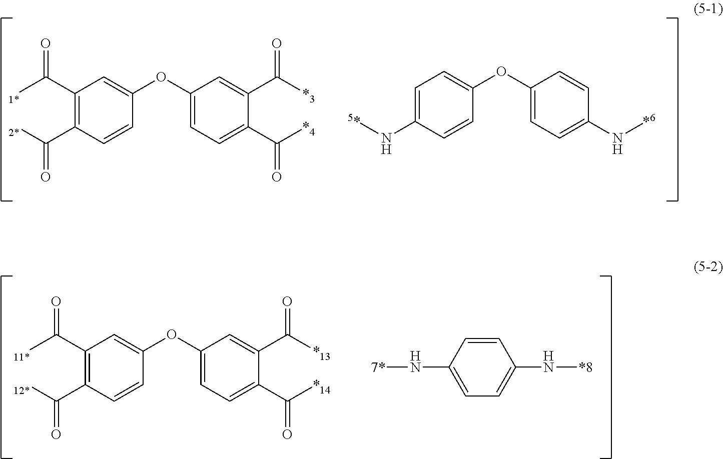

In the formulae, one of *3 and *4 is bonded to *5 to form a main chain of the polyimide precursor, and the other bonded to an OH group to form a carboxyl group; and one of *1 and *2 is bonded to an OH group to form a carboxyl group or bonded to —NH—(CH₂)₂—O—(C═O)—C(CH₃)═CH₂, and the other is bonded to any one of *6 or *8 to form the main chain of the polyimide precursor; and

one of *13 and *14 is bonded to *7 to form a main chain of the polyimide precursor, and the other bonded to an OH group to form a carboxyl group; and one of *11 and *12 is bonded to an OH group to form a carboxyl group or bonded to —NH—(CH₂)₂—O—(C═O)—C(CH₃)═CH₂, and the other is bonded to any one of *6 or *8 to form the main chain of the polyimide precursor.

Resin c1: resin having the following structure (acrylic resin, weight-average molecular weight: 12000, solid content: 100%)

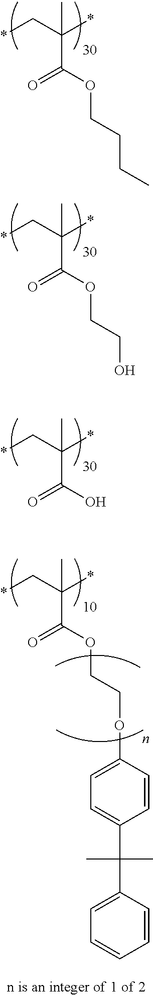

The resins 2 to 5 are materials corresponding to the second resin in the present invention, and the resin c1 is a material (third resin) not corresponding to any of the first resin or the second resin in the present invention.

(Solvent)

PGMEA: propylene glycol monomethyl ether acetate

### Production of Coloring Composition

### Production Example 4-1

### (Production of Coloring Composition (GR-1))

Materials shown below were mixed by the parts by mass shown below, and then filtered through a filter having a pore size of 1 μm to produce a coloring composition (GR-1).

Pigment dispersion liquid (GB-1): 44.5 parts by mass

Pigment dispersion liquid (YB-4): 40.5 parts by mass

Resin 1: 0.7 parts by mass

Polymerizable monomer (M-1): 1.2 parts by mass

Photopolymerization initiator (I-1): 0.6 parts by mass

Ultraviolet absorber (U-1): 0.4 parts by mass

Surfactant (S-1): 4.2 parts by mass

Polymerization inhibitor (IN-1): 0.005 parts by mass

PGMEA: 7.9 parts by mass

Here, abbreviations for the various materials represent the following.

Polymerizable monomer (M-1): 7:3 mixture of dipentaerythritol hexaacrylate (DPHA) and dipentaerythritol pentaacrylate (manufactured by Nippon Kayaku Co., Ltd., KAYARAD DPHA)

Photopolymerization initiator (I-1): Irgacure OXE-01 (manufactured by BASF SE)

Ultraviolet absorber (U-1): triazine-based ultraviolet absorber “Tinuvin 477” (manufactured by BASF SE)

Surfactant (S-1): 1% by mass PGMEA solution of a compound having the following structure (Mw=14000; the numerical value “%” representing the proportion of the repeating unit is mol %)

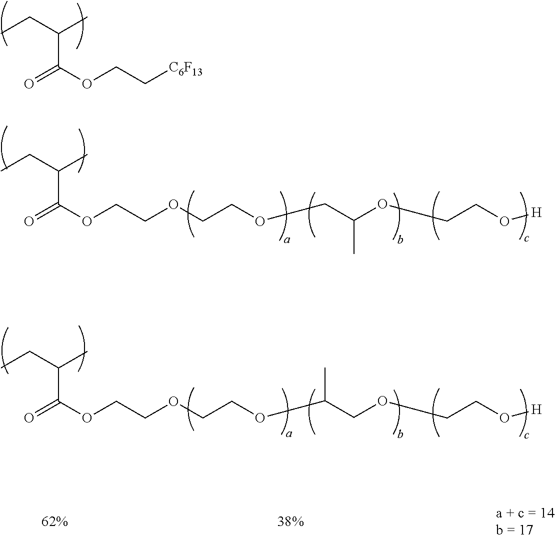

### Polymerization Inhibitor (IN-1): p-Methoxyphenol

### Production Examples 4-2 to 4-70

Each coloring composition was produced by the same method as in Production Example 4-1, except that the materials used were changed as shown in the tables below. The value of the blending amount of the resin is a value in a case of being converted to 100% of concentration of solid contents. The value of the blending amount of the solvent is a value obtained by totaling the amount of solvents included in the resin.

TABLE 4

| | | Pigment | | Pigment | | Pigment | | Pigment | | | | | |
|---|---|---|---|---|---|---|---|---|---|---|---|---|---|
| | | dispersion | | dispersion | | dispersion | | dispersion | | | | Polymerizable | |
| | | liquid 1 | | liquid 2 | | liquid 3 | | liquid 4 | | Resin | | monomer | |
| Production | Coloring | | Part by | | Part by | | Part by | | Part by | | Part by | | Part by |
| Example | composition | Type | mass | Type | mass | Type | mass | Type | mass | Type | mass | Type | mass |
| 4-1 | (GR-1) | (GB-1) | 44.5 | (YB-4) | 40.5 | | | | | Resin 1 | 0.7 | (M-1) | 1.2 |
| 4-2 | (GR-2) | (GB-2) | 44.5 | (YB-5) | 40.5 | | | | | Resin 1 | 0.7 | (M-1) | 1.2 |
| 4-3 | (GR-3) | (GB-3) | 44.5 | (YB-6) | 40.5 | | | | | Resin 1 | 0.7 | (M-1) | 1.2 |
| 4-4 | (GR-4) | (GB-4) | 44.5 | (YB-7) | 40.5 | | | | | Resin 2 | 0.7 | (M-1) | 1.2 |
| 4-5 | (GR-5) | (GB-5) | 44.5 | (YB-8) | 40.5 | | | | | Resin 3 | 0.7 | (M-1) | 1.2 |
| 4-6 | (GR-6) | (GB-9) | 67.3 | (YB-9) | 16.4 | | | | | Resin 1 | 2.2 | (M-1) | 2.2 |
| 4-7 | (GR-7) | (GB-10) | 67.3 | (YB-10) | 16.4 | | | | | Resin 2 | 2.2 | (M-1) | 2.2 |
| 4-8 | (GR-8) | (GB-11) | 67.3 | (YB-11) | 16.4 | | | | | Resin 3 | 2.2 | (M-1) | 2.2 |
| 4-9 | (GR-9) | (GB-3) | 24.5 | (GB-6) | 20.0 | (YB-6) | 40.5 | | | Resin 1 | 0.7 | (M-1) | 1.2 |
| 4-10 | (GR-10) | (GB-4) | 24.5 | (GB-7) | 20.0 | (YB-7) | 40.5 | | | Resin 2 | 0.7 | (M-1) | 1.2 |
| 4-11 | (GR-11) | (GB-5) | 24.5 | (GB-8) | 20.0 | (YB-8) | 40.5 | | | Resin 3 | 0.7 | (M-1) | 1.2 |
| 4-12 | (GR-12) | (GB-12) | 67.3 | (YB-9) | 16.4 | | | | | Resin 1 | 2.2 | (M-1) | 2.2 |
| 4-13 | (GR-13) | (GB-13) | 67.3 | (YB-10) | 16.4 | | | | | Resin 2 | 2.2 | (M-1) | 2.2 |
| 4-14 | (GR-14) | (GB-14) | 67.3 | (YB-11) | 16.4 | | | | | Resin 3 | 2.2 | (M-1) | 2.2 |
| 4-15 | (GR-15) | (GB-15) | 67.3 | (YB-9) | 16.4 | | | | | Resin 1 | 2.2 | (M-1) | 2.2 |
| 4-16 | (GR-16) | (GB-16) | 67.3 | (YB-10) | 16.4 | | | | | Resin 2 | 2.2 | (M-1) | 2.2 |
| 4-17 | (GR-17) | (GB-17) | 67.3 | (YB-11) | 16.4 | | | | | Resin 3 | 2.2 | (M-1) | 2.2 |
| 4-18 | (GR-18) | (GB-15) | 67.3 | (YB-19) | 16.4 | | | | | Resin 1 | 2.2 | (M-1) | 2.2 |
| 4-19 | (GR-19) | (GB-16) | 67.3 | (YB-20) | 16.4 | | | | | Resin 2 | 2.2 | (M-1) | 2.2 |
| 4-20 | (GR-20) | (GB-17) | 67.3 | (YB-21) | 16.4 | | | | | Resin 3 | 2.2 | (M-1) | 2.2 |
| 4-21 | (RR-1) | (RB-7) | 38.2 | (YB-1) | 17.3 | | | | | Resin 1 | 3.0 | (M-1) | 0.6 |
| 4-22 | (RR-2) | (RB-8) | 38.2 | (YB-2) | 17.3 | | | | | Resin 2 | 3.0 | (M-1) | 0.6 |
| 4-23 | (RR-3) | (RB-9) | 38.2 | (YB-3) | 17.3 | | | | | Resin 3 | 3.0 | (M-1) | 0.6 |
| 4-24 | (RR-4) | (RB-4) | 55.8 | (RB-7) | 25.8 | | | | | Resin 1 | 4.6 | (M-1) | 4.1 |
| 4-25 | (RR-5) | (RB-5) | 55.8 | (RB-8) | 25.8 | | | | | Resin 2 | 4.6 | (M-1) | 4.1 |

TABLE 5

| | | Photopolymerization | | Ultraviolet | | | | | | | |
|---|---|---|---|---|---|---|---|---|---|---|---|
| | | initiator | | absorber | | Additive | | Surfactant | | Solvent | |
| Production | Coloring | | Part by | | Part by | | Part by | | Part by | | Part by |
| Example | composition | Type | mass | Type | mass | Type | mass | Type | mass | Type | mass |
| 4-1 | (GR-1) | (I-1) | 0.6 | (U-1) | 0.4 | | | (S-1) | 4.2 | PGMEA | 7.9 |
| 4-2 | (GR-2) | (I-1) | 0.6 | (U-1) | 0.4 | | | (S-1) | 4.2 | PGMEA | 7.9 |
| 4-3 | (GR-3) | (I-1) | 0.6 | (U-1) | 0.4 | | | (S-1) | 4.2 | PGMEA | 7.9 |
| 4-4 | (GR-4) | (I-1) | 0.6 | (U-1) | 0.4 | | | (S-1) | 4.2 | PGMEA | 7.9 |
| 4-5 | (GR-5) | (I-1) | 0.6 | (U-1) | 0.4 | | | (S-1) | 4.2 | PGMEA | 7.9 |
| 4-6 | (GR-6) | (I-1) | 0.9 | | | (F-1) | 0.4 | (S-1) | 4.2 | PGMEA | 6.4 |
| 4-7 | (GR-7) | (I-1) | 0.9 | | | (F-1) | 0.4 | (S-1) | 4.2 | PGMEA | 6.4 |
| 4-8 | (GR-8) | (I-1) | 0.9 | | | (F-1) | 0.4 | (S-1) | 4.2 | PGMEA | 6.4 |
| 4-9 | (GR-9) | (I-1) | 0.6 | (U-1) | 0.4 | | | (S-1) | 4.2 | PGMEA | 7.9 |
| 4-10 | (GR-10) | (I-1) | 0.6 | (U-1) | 0.4 | | | (S-1) | 4.2 | PGMEA | 7.9 |
| 4-11 | (GR-11) | (I-1) | 0.6 | (U-1) | 0.4 | | | (S-1) | 4.2 | PGMEA | 7.9 |
| 4-12 | (GR-12) | (I-1) | 0.9 | | | (F-1) | 0.4 | (S-1) | 4.2 | PGMEA | 6.4 |
| 4-13 | (GR-13) | (I-1) | 0.9 | | | (F-1) | 0.4 | (S-1) | 4.2 | PGMEA | 6.4 |
| 4-14 | (GR-14) | (I-1) | 0.9 | | | (F-1) | 0.4 | (S-1) | 4.2 | PGMEA | 6.4 |
| 4-15 | (GR-15) | (I-1) | 0.9 | | | (F-1) | 0.4 | (S-1) | 4.2 | PGMEA | 6.4 |
| 4-16 | (GR-16) | (I-1) | 0.9 | | | (F-1) | 0.4 | (S-1) | 4.2 | PGMEA | 6.4 |
| 4-17 | (GR-17) | (I-1) | 0.9 | | | (F-1) | 0.4 | (S-1) | 4.2 | PGMEA | 6.4 |
| 4-18 | (GR-18) | (I-1) | 0.9 | | | (F-1) | 0.4 | (S-1) | 4.2 | PGMEA | 6.4 |
| 4-19 | (GR-19) | (I-1) | 0.9 | | | (F-1) | 0.4 | (S-1) | 4.2 | PGMEA | 6.4 |
| 4-20 | (GR-20) | (I-1) | 0.9 | | | (F-1) | 0.4 | (S-1) | 4.2 | PGMEA | 6.4 |
| 4-21 | (RR-1) | (I-1) | 0.3 | | | | | (S-1) | 4.2 | PGMEA | 36.4 |
| 4-22 | (RR-2) | (I-1) | 0.3 | | | | | (S-1) | 4.2 | PGMEA | 36.4 |
| 4-23 | (RR-3) | (I-1) | 0.3 | | | | | (S-1) | 4.2 | PGMEA | 36.4 |
| 4-24 | (RR-4) | (I-1) | 0.2 | | | | | (S-1) | 4.2 | PGMEA | 5.3 |
| 4-25 | (RR-5) | (I-1) | 0.2 | | | | | (S-1) | 4.2 | PGMEA | 5.3 |

TABLE 6

| | | Pigment | | Pigment | | Pigment | | Pigment | | | | | |
|---|---|---|---|---|---|---|---|---|---|---|---|---|---|
| | | dispersion | | dispersion | | dispersion | | dispersion | | | | Polymerizable | |
| | | liquid 1 | | liquid 2 | | liquid 3 | | liquid 4 | | Resin | | monomer | |
| Production | Coloring | | Part by | | Part by | | Part by | | Part by | | Part by | | Part by |
| Example | composition | Type | mass | Type | mass | Type | mass | Type | mass | Type | mass | Type | mass |
| 4-26 | (RR-6) | (RB-6) | 55.8 | (RB-9) | 25.8 | | | | | Resin 3 | 4.6 | (M-1) | 4.1 |
| 4-27 | (RR-7) | (RB-7) | 20.2 | (RB-17) | 18.0 | (YB-1) | 17.3 | | | Resin 1 | 3.0 | (M-1) | 0.6 |
| 4-28 | (RR-8) | (RB-8) | 20.2 | (RB-18) | 18.0 | (YB-2) | 17.3 | | | Resin 2 | 3.0 | (M-1) | 0.6 |
| 4-29 | (RR-9) | (RB-9) | 20.2 | (RB-19) | 18.0 | (YB-3) | 17.3 | | | Resin 3 | 3.0 | (M-1) | 0.6 |
| 4-30 | (BR-1) | (BB-1) | 44.5 | (VB-1) | 11.8 | | | | | Resin 1 | 1.5 | (M-1) | 2.2 |
| 4-31 | (BR-2) | (BB-2) | 44.5 | (VB-2) | 11.8 | | | | | Resin 2 | 1.5 | (M-1) | 2.2 |
| 4-32 | (BR-3) | (BB-3) | 44.5 | (VB-3) | 11.8 | | | | | Resin 3 | 1.5 | (M-1) | 2.2 |
| 4-33 | (CR-1) | (BB-4) | 34.3 | | | | | | | Resin 1 | 7.5 | (M-1) | 6.7 |
| 4-34 | (CR-2) | (BB-5) | 34.3 | | | | | | | Resin 2 | 7.5 | (M-1) | 6.7 |
| 4-35 | (CR-3) | (BB-6) | 34.3 | | | | | | | Resin 3 | 7.5 | (M-1) | 6.7 |
| 4-36 | (CR-4) | (BB-7) | 34.3 | | | | | | | Resin 1 | 7.5 | (M-1) | 6.7 |
| 4-37 | (CR-5) | (BB-8) | 34.3 | | | | | | | Resin 2 | 7.5 | (M-1) | 6.7 |
| 4-38 | (CR-6) | (BB-9) | 34.3 | | | | | | | Resin 3 | 7.5 | (M-1) | 6.7 |
| 4-39 | (CR-7) | (BB-10) | 34.3 | | | | | | | Resin 1 | 7.5 | (M-1) | 6.7 |
| 4-40 | (CR-8) | (BB-11) | 34.3 | | | | | | | Resin 2 | 7.5 | (M-1) | 6.7 |
| 4-41 | (CR-9) | (BB-12) | 34.3 | | | | | | | Resin 3 | 7.5 | (M-1) | 6.7 |
| 4-42 | (MR-1) | (RB-1) | 69.0 | | | | | | | Resin 1 | 3.7 | (M-1) | 7.2 |
| 4-43 | (MR-2) | (RB-2) | 69.0 | | | | | | | Resin 2 | 3.7 | (M-1) | 7.2 |
| 4-44 | (MR-3) | (RB-3) | 69.0 | | | | | | | Resin 3 | 3.7 | (M-1) | 7.2 |
| 4-45 | (YR-1) | (YB-9) | 46.4 | | | | | | | Resin 1 | 7.0 | (M-1) | 6.2 |
| 4-46 | (YR-2) | (YB-10) | 46.4 | | | | | | | Resin 2 | 7.0 | (M-1) | 6.2 |
| 4-47 | (YR-3) | (YB-11) | 46.4 | | | | | | | Resin 3 | 7.0 | (M-1) | 6.2 |
| 4-48 | (KR-1) | (RB-10) | 31.8 | (BB-10) | 20.9 | (YB-12) | 4.5 | | | Resin 1 | 6.6 | (M-1) | 1.6 |
| 4-49 | (KR-2) | (RB-10) | 42.9 | (BB-10) | 28.2 | (YB-12) | 6.1 | | | Resin 1 | 4.9 | (M-1) | 1.2 |
| 4-50 | (KR-3) | (RB-10) | 49.3 | (BB-10) | 32.4 | (YB-12) | 7.0 | | | Resin 1 | 4.3 | (M-1) | 1.0 |

TABLE 7

| | | Photopolymerization | | Ultraviolet | | | | | | | |
|---|---|---|---|---|---|---|---|---|---|---|---|
| | | initiator | | absorber | | Additive | | Surfactant | | Solvent | |
| Production | Coloring | | Part by | | Part by | | Part by | | Part by | | Part by |
| Example | composition | Type | mass | Type | mass | Type | mass | Type | mass | Type | mass |

| | | | | | | | |
|---|---|---|---|---|---|---|---|
| 4-26 | (RR-6) | (I-1) | 0.2 | (S-1) | 4.2 | PGMEA | 5.3 |
| 4-27 | (RR-7) | (I-1) | 0.3 | (S-1) | 4.2 | PGMEA | 36.4 |
| 4-28 | (RR-8) | (I-1) | 0.3 | (S-1) | 4.2 | PGMEA | 36.4 |
| 4-29 | (RR-9) | (I-1) | 0.3 | (S-1) | 4.2 | PGMEA | 36.4 |
| 4-30 | (BR-1) | (I-1) | 0.8 | (S-1) | 4.2 | PGMEA | 35.0 |
| 4-31 | (BR-2) | (I-1) | 0.8 | (S-1) | 4.2 | PGMEA | 35.0 |
| 4-32 | (BR-3) | (I-1) | 0.8 | (S-1) | 4.2 | PGMEA | 35.0 |
| 4-33 | (CR-1) | (I-1) | 0.8 | (S-1) | 4.2 | PGMEA | 46.5 |
| 4-34 | (CR-2) | (I-1) | 0.8 | (S-1) | 4.2 | PGMEA | 46.5 |
| 4-35 | (CR-3) | (I-1) | 0.8 | (S-1) | 4.2 | PGMEA | 46.5 |
| 4-36 | (CR-4) | (I-1) | 0.8 | (S-1) | 4.2 | PGMEA | 46.5 |
| 4-37 | (CR-5) | (I-1) | 0.8 | (S-1) | 4.2 | PGMEA | 46.5 |
| 4-38 | (CR-6) | (I-1) | 0.8 | (S-1) | 4.2 | PGMEA | 46.5 |
| 4-39 | (CR-7) | (I-1) | 0.8 | (S-1) | 4.2 | PGMEA | 46.5 |
| 4-40 | (CR-8) | (I-1) | 0.8 | (S-1) | 4.2 | PGMEA | 46.5 |
| 4-41 | (CR-9) | (I-1) | 0.8 | (S-1) | 4.2 | PGMEA | 46.5 |
| 4-42 | (MR-1) | (I-1) | 0.5 | (S-1) | 4.2 | PGMEA | 15.4 |
| 4-43 | (MR-2) | (I-1) | 0.5 | (S-1) | 4.2 | PGMEA | 15.4 |
| 4-44 | (MR-3) | (I-1) | 0.5 | (S-1) | 4.2 | PGMEA | 15.4 |
| 4-45 | (YR-1) | (I-1) | 1.0 | (S-1) | 4.2 | PGMEA | 35.2 |
| 4-46 | (YR-2) | (I-1) | 1.0 | (S-1) | 4.2 | PGMEA | 35.2 |
| 4-47 | (YR-3) | (I-1) | 1.0 | (S-1) | 4.2 | PGMEA | 35.2 |
| 4-48 | (KR-1) | (I-1) | 0.5 | (S-1) | 4.2 | PGMEA | 29.9 |
| 4-49 | (KR-2) | (I-1) | 0.4 | (S-1) | 4.2 | PGMEA | 12.1 |
| 4-50 | (KR-3) | (I-1) | 0.3 | (S-1) | 4.2 | PGMEA | 1.5 |

TABLE 8

| | | Pigment | | Pigment | | Pigment | | Pigment | | | | | |
|---|---|---|---|---|---|---|---|---|---|---|---|---|---|
| | | dispersion | | dispersion | | dispersion | | dispersion | | | | Polymerizable | |
| | | liquid 1 | | liquid 2 | | liquid 3 | | liquid 4 | | Resin | | monomer | |
| Production | Coloring | | Part by | | Part by | | Part by | | Part by | | Part by | | Part by |
| Example | composition | Type | mass | Type | mass | Type | mass | Type | mass | Type | mass | Type | mass |
| 4-51 | (KR-4) | (RB-11) | 31.8 | (BB-11) | 20.9 | (YB-13) | 4.5 | | | Resin 2 | 6.6 | (M-1) | 1.6 |
| 4-52 | (KR-5) | (RB-12) | 31.8 | (BB-12) | 20.9 | (YB-14) | 4.5 | | | Resin 3 | 6.6 | (M-1) | 1.6 |
| 4-53 | (KR-6) | (RB-13) | 31.8 | (BB-13) | 20.9 | (YB-15) | 4.5 | | | Resin 4 | 6.6 | (M-1) | 1.6 |
| 4-54 | (KR-7) | (RB-14) | 31.8 | (BB-14) | 20.9 | (YB-16) | 4.5 | | | Resin 5 | 6.6 | (M-1) | 1.6 |
| 4-55 | (KR-8) | (RB-15) | 31.8 | (BB-15) | 20.9 | (YB-17) | 4.5 | | | Resin 1 | 6.6 | (M-1) | 1.6 |
| 4-56 | (KR-9) | (RB-16) | 31.8 | (BB-16) | 20.9 | (YB-18) | 4.5 | | | Resin 1 | 1.2 | (M-1) | 7.0 |
| 4-57 | (KR-10) | (RB-10) | 31.8 | (BB-10) | 20.9 | (YB-12) | 4.5 | | | Resin 1 | 6.6 | (M-2)/ | 0.8/0.8 |
| | | | | | | | | | | | | (M-3) | |
| 4-58 | (KR-11) | (RB-10) | 31.8 | (BB-10) | 20.9 | (YB-12) | 4.5 | | | Resin 1 | 6.6 | (M-2)/ | 0.8/0.8 |
| | | | | | | | | | | | | (M-3) | |
| 4-59 | (KR-12) | (RB-10) | 31.8 | (BB-10) | 20.9 | (YB-12) | 4.5 | | | Resin 1 | 6.6 | (M-2)/ | 0.8/0.8 |
| | | | | | | | | | | | | (M-3) | |
| 4-60 | (KR-13) | (KB-1) | 50.0 | | | | | | | Resin 1 | 0.5 | (M-1) | 2.0 |
| 4-61 | (KR-14) | (KB-2) | 50.0 | | | | | | | Resin 2 | 0.5 | (M-1) | 2.0 |
| 4-62 | (KR-15) | (KB-3) | 50.0 | | | | | | | Resin 3 | 0.5 | (M-1) | 2.0 |
| 4-63 | (KR-16) | (KB-4) | 50.0 | | | | | | | Resin 1 | 0.5 | (M-1) | 2.0 |
| 4-64 | (KR-17) | (KB-5) | 50.0 | | | | | | | Resin 2 | 0.5 | (M-1) | 2.0 |
| 4-65 | (KR-18) | (KB-6) | 50.0 | | | | | | | Resin 3 | 0.5 | (M-1) | 2.0 |
| 4-66 | (KR-19) | (KB-4) | 30.0 | (VB-1) | 6.0 | (YB-6) | 8.0 | (OB-1) | 6.0 | Resin 1 | 0.5 | (M-1) | 2.0 |
| 4-67 | (KR-20) | (KB-5) | 30.0 | (VB-2) | 6.0 | (YB-7) | 8.0 | (OB-2) | 6.0 | Resin 2 | 0.5 | (M-1) | 2.0 |
| 4-68 | (KR-21) | (KB-6) | 30.0 | (VB-3) | 6.0 | (YB-8) | 8.0 | (OB-3) | 6.0 | Resin 3 | 0.5 | (M-1) | 2.0 |
| 4-69 | (GR-c1) | (GB-c1) | 44.5 | (YB-c1) | 40.5 | | | | | Resin c1 | 0.7 | (M-1) | 1.2 |
| 4-70 | (GR-c2) | (GB-c1) | 44.5 | (YB-c2) | 40.5 | | | | | Resin 1 | 0.7 | (M-1) | 1.2 |

TABLE 9

| | | Photopolymerization | | Ultraviolet | | | | | | | |
|---|---|---|---|---|---|---|---|---|---|---|---|
| | | initiator | | absorber | | Additive | | Surfactant | | Solvent | |
| Production | Coloring | | Part by | | Part by | | Part by | | Part by | | Part by |
| Example | composition | Type | mass | Type | mass | Type | mass | Type | mass | Type | mass |
| 4-51 | (KR-4) | (I-1) | 0.5 | | | | | (S-1) | 4.2 | PGMEA | 29.9 |
| 4-52 | (KR-5) | (I-1) | 0.5 | | | | | (S-1) | 4.2 | PGMEA | 29.9 |
| 4-53 | (KR-6) | (I-1) | 0.5 | | | | | (S-1) | 4.2 | PGMEA | 29.9 |
| 4-54 | (KR-7) | (I-1) | 0.5 | | | | | (S-1) | 4.2 | PGMEA | 29.9 |
| 4-55 | (KR-8) | (I-1) | 0.5 | | | | | (S-1) | 4.2 | PGMEA | 29.9 |
| 4-56 | (KR-9) | (I-1) | 0.5 | | | | | (S-1) | 4.2 | PGMEA | 29.9 |
| 4-57 | (KR-10) | (I-1)/(I-2) | 0.25/0.25 | | | | | (S-1) | 4.2 | PGMEA | 29.9 |
| 4-58 | (KR-11) | (I-1)/(I-3)/(I-4) | 0.2/0.2/0.1 | | | | | (S-1) | 4.2 | PGMEA | 29.9 |
| 4-59 | (KR-12) | (I-5) | 0.5 | | | | | (S-1) | 4.2 | PGMEA | 29.9 |
| 4-60 | (KR-13) | (I-1) | 0.6 | | | | | (S-1) | 4.2 | PGMEA | 42.7 |
| 4-61 | (KR-14) | (I-1) | 0.6 | | | | | (S-1) | 4.2 | PGMEA | 42.7 |
| 4-62 | (KR-15) | (I-1) | 0.6 | | | | | (S-1) | 4.2 | PGMEA | 42.7 |
| 4-63 | (KR-16) | (I-1) | 0.6 | | | | | (S-1) | 4.2 | PGMEA | 42.7 |
| 4-64 | (KR-17) | (I-1) | 0.6 | | | | | (S-1) | 4.2 | PGMEA | 42.7 |
| 4-65 | (KR-18) | (I-1) | 0.6 | | | | | (S-1) | 4.2 | PGMEA | 42.7 |
| 4-66 | (KR-19) | (I-1) | 0.6 | | | | | (S-1) | 4.2 | PGMEA | 42.7 |
| 4-67 | (KR-20) | (I-1) | 0.6 | | | | | (S-1) | 4.2 | PGMEA | 42.7 |
| 4-68 | (KR-21) | (I-1) | 0.6 | | | | | (S-1) | 4.2 | PGMEA | 42.7 |
| 4-69 | (GR-c1) | (I-1) | 0.6 | (U-1) | 0.4 | | | (S-1) | 4.2 | PGMEA | 7.9 |
| 4-70 | (GR-c2) | (I-1) | 0.6 | (U-1) | 0.4 | | | (S-1) | 4.2 | PGMEA | 7.9 |

In the above tables, details of the materials shown by abbreviations are as follows.

Polymerizable monomer (M-2): trimethylolpropane triacrylate (manufactured by Shin-Nakamura Chemical Co., Ltd., A-TMPT)

Polymerizable monomer (M-3): compound represented by the following formula (manufactured by Shin-Nakamura Chemical Co., Ltd., A-DPH-12E)

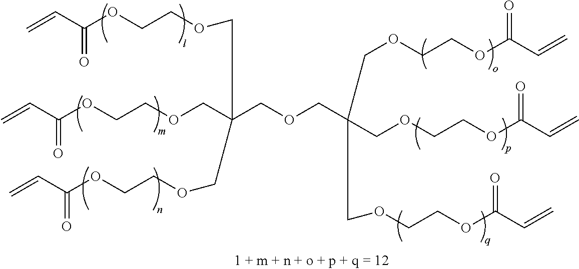

Photopolymerization initiator (I-2): Irgacure OXE-02 (manufactured by BASF SE)

Photopolymerization initiator I-3: compound having the following structure

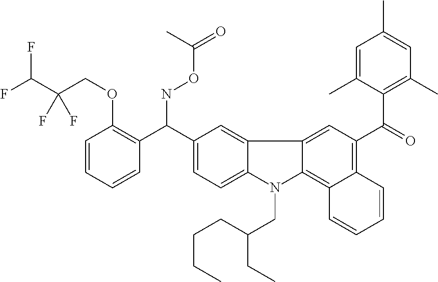 [SMILES: CCCCC(CC)CN1c2ccc(C(NOC(C)=O)c3ccccc3OCC(F)(F)C(F)F)cc2Cc2cc(C(=O)c3c(C)cc(C)cc3C)c3ccccc3c21]

Photopolymerization initiator (I4): Omnirad 369 (manufactured by IGM Resins B.V.)

Photopolymerization initiator (I-5): compound having the following structure

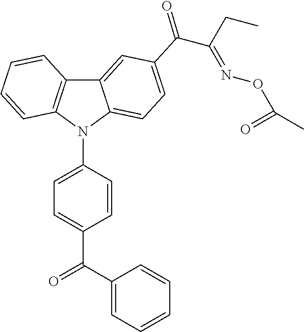 [SMILES: CC/C(=N\OC(C)=O)C(=O)c1ccc2c(c1)c1ccccc1n2-c1ccc(C(=O)c2ccccc2)cc1]

Additive (F-1): epoxy compound (manufactured by Daicel Corporation, EHPE 3150)

<Evaluation>

(Heat Resistance)

A 5 cm×5 cm glass substrate was coated with each coloring composition prepared above using a spin coater so that a thickness of a film after drying was 0.6 μm. and pre-baking was performed at 100° C. for 120 seconds to obtain a film. The glass substrate on which the film was formed was placed on a hot plate at 300° C. such that the substrate surface was in contact with the hot plate, and was heated for 5 hours. Thereafter, using a colorimeter MCPD-1000 (manufactured by OTSUKA ELECTRONICS Co., Ltd.), the color difference (ΔE*ab value) before and after heating was measured, and the heat resistance was evaluated according to the following determination criterion. As the ΔE*ab value is smaller, the heat resistance is better. The ΔE*ab value is a value acquired using the following color difference expression based on the CIE1976 (L*, a*, b*) space color system (The Color Science Handbook (1985), new edition, p. 266, edited by The Color Science Association of Japan).

ΔE*ab={(ΔL*)²+(Δa*)²+(Δb*)²}^{1/2}

### [Evaluation Standard]

5: ΔE*ab value was 0 or more and less than 2.0.

4: ΔE*ab value was 2.0 or more and less than 4.0.

3: ΔE*ab value was 4.0 or more and less than 6.0.

2: ΔE*ab value was 6.0 or more and less than 8.0.

1: ΔE*ab value was 8.0 or more.

<Moisture Resistance>

CT-4000 (manufactured by Fujifilm Electronic Materials Co., Ltd.) was applied to a glass substrate by a spin coating method so that a film thickness was 0.1 μm, and the glass substrate was heated at 220° C. for 1 hour using a hot plate to form a base layer. Each coloring composition prepared above was applied to this glass substrate with a base layer using a spin coating method, and then the glass substrate with a base layer was heated at 100° C. for 2 minutes using a hot plate to obtain a coating film. The obtained coating film was irradiated with light having a wavelength of 365 nm at an exposure amount of 500 mJ/cm². Next, the coating film was heated using a hot plate at 220° C. for 5 minutes to obtain a film having a film thickness of 0.5 μm. Light transmittance (transmittance) of the obtained film in a range of 400 to 700 nm was measured by using MCPD-3000 manufactured by OTSUKA ELECTRONICS Co., LTD.

Next, the film produced above was allowed to stand for 1000 hours at a constant temperature and humidity of 85° C. and a humidity of 85% to perform a moisture resistance test. Transmittance of the film after the moisture resistance test was measured, the maximum value of variation of transmittance was determined, and then the moisture resistance was evaluated based on the following standard. In addition, the measurement of transmittance was performed 5 times for each sample, and the average value of the 3 times result except the maximum value and the minimum value was adopted. In addition, the maximum value of the variation of transmittance means a variation of transmittance of the film in a wavelength which has the largest variation of transmittance in a range of 400 to 700 nm before and after the moisture resistance test.

(Evaluation Standard)

5: maximum value of variation of transmittance was 1% or less.

4: maximum value of variation of transmittance was more than 1% and 1.5% or less.

3: maximum value of variation of transmittance was more than 1.5% and 2.0% or less.

2: maximum value of variation of transmittance was more than 2.0% and 2.5% or less.

1: maximum value of variation of transmittance was more than 2.5%.

The results of each evaluation are shown in the tables below. In the column of “Content” in the tables below, the value of the content of each material (colorant, first resin, second resin, and third resin) in the total solid content of the coloring composition is described. Moreover, the type of the colorant, the type of the first resin, the type of the second resin, and the type of the third resin included in the coloring composition are described.

TABLE 10

| | Coloring composition | | | | | | | | | | | |
|---|---|---|---|---|---|---|---|---|---|---|---|---|
| | | | | | | | | | | Proportion | | |
| | | | | | | | | | | of second | | |
| | | | | | | | | | | resin with | | |
| | | | | | | | | | | respect | | |
| | | | | | | | | | | to 100 | | |
| | | | | | | | | | | parts | | |
| | | Colorant | | First resin | | Second resin | | Third resin | | by mass | | |
| | | | Content | | Content | | Content | | Content | of first | | |
| | | | (% by | | (% by | | (% by | | (% by | resin (part | Moisture | Heat |
| | Type | Type | mass) | Type | mass) | Type | mass) | Type | mass) | by mass) | resistance | resistance |
| Example 1 | (GR-1) | PG36/PY150 | 59.3 | (D-1) | 8.1 | Resin 1 | 15.2 | — | — | 188 | 3 | 3 |
| Example 2 | (GR-2) | PG36/PY150 | 59.3 | (D-2) | 8.1 | Resin 1 | 15.2 | — | — | 188 | 4 | 3 |
| Example 3 | (GR-3) | PG36/PY150 | 59.3 | (D-3) | 8.1 | Resin 1 | 15.2 | — | — | 188 | 5 | 4 |
| Example 4 | (GR-4) | PG36/PY150 | 59.3 | (D-3) | 8.1 | Resin 2 | 15.2 | — | — | 188 | 4 | 3 |
| Example 5 | (GR-5) | PG36/PY150 | 59.3 | (D-3) | 8.1 | Resin 3 | 15.2 | — | — | 188 | 4 | 4 |
| Example 6 | (GR-6) | PG58/PY185 | 50.1 | (D-3) | 6.8 | Resin 1 | 21.1 | — | — | 309 | 5 | 4 |
| Example 7 | (GR-7) | PG58/PY185 | 50.1 | (D-3) | 6.8 | Resin 2 | 21.1 | — | — | 309 | 4 | 3 |
| Example 8 | (GR-8) | PG58/PY185 | 50.1 | (D-3) | 6.8 | Resin 3 | 21.1 | — | — | 309 | 4 | 4 |
| Example 9 | (GR-9) | PG7/PG36/PY150 | 59.3 | (D-3) | 8.1 | Resin 1 | 15.2 | — | — | 188 | 5 | 4 |
| Example 10 | (GR-10) | PG7/PG36/PY150 | 59.3 | (D-3) | 8.1 | Resin 2 | 15.2 | — | — | 188 | 4 | 3 |
| Example 11 | (GR-11) | PG7/PG36/PY150 | 59.3 | (D-3) | 8.1 | Resin 3 | 15.2 | — | — | 188 | 4 | 4 |
| Example 12 | (GR-12) | PG62/PY185 | 50.1 | (D-3) | 6.8 | Resin 1 | 21.1 | — | — | 309 | 5 | 4 |
| Example 13 | (GR-13) | PG62/PY185 | 50.1 | (D-3) | 6.8 | Resin 2 | 21.1 | — | — | 309 | 4 | 3 |
| Example 14 | (GR-14) | PG62/PY185 | 50.1 | (D-3) | 6.8 | Resin 3 | 21.1 | — | — | 309 | 4 | 4 |
| Example 15 | (GR-15) | PG63/PY185 | 50.1 | (D-3) | 6.8 | Resin 1 | 21.1 | — | — | 309 | 5 | 4 |
| Example 16 | (GR-16) | PG63/PY185 | 50.1 | (D-3) | 6.8 | Resin 2 | 21.1 | — | — | 309 | 4 | 3 |
| Example 17 | (GR-17) | PG63/PY185 | 50.1 | (D-3) | 6.8 | Resin 3 | 21.1 | — | — | 309 | 4 | 4 |
| Example 18 | (GR-18) | PG63/PY-1 | 50.1 | (D-3) | 6.8 | Resin 1 | 21.1 | — | — | 309 | 5 | 4 |
| Example 19 | (GR-19) | PG63/PY-1 | 50.1 | (D-3) | 6.8 | Resin 2 | 21.1 | — | — | 309 | 4 | 3 |
| Example 20 | (GR-20) | PG63/PY-1 | 50.1 | (D-3) | 6.8 | Resin 3 | 21.1 | — | — | 309 | 4 | 4 |
| Example 21 | (RR-1) | PR254/PY139 | 49.5 | (D-3) | 6.8 | Resin 1 | 33.4 | — | — | 494 | 5 | 4 |
| Example 22 | (RR-2) | PR254/PY139 | 49.5 | (D-3) | 6.8 | Resin 2 | 33.4 | — | — | 494 | 4 | 3 |
| Example 23 | (RR-3) | PR254/PY139 | 49.5 | (D-3) | 6.8 | Resin 3 | 33.4 | — | — | 494 | 4 | 4 |
| Example 24 | (RR-4) | PR177/PR254 | 42.2 | (D-3) | 5.8 | Resin 1 | 29.3 | — | — | 509 | 5 | 4 |
| Example 25 | (RR-5) | PR177/PR254 | 42.2 | (D-3) | 5.8 | Resin 2 | 29.3 | — | — | 509 | 4 | 3 |

TABLE 11

| | Coloring composition | | | | | | | | | | | |
|---|---|---|---|---|---|---|---|---|---|---|---|---|
| | | | | | | | | | | Proportion of | | |
| | | | | First | | Second | | Third | | second resin with | | |
| | | Colorant | | resin | | resin | | resin | | respect to 100 | | |
| | | | Content | | Content | | Content | | Content | parts by mass | Moisture | Heat |
| | | | (% by | | (% by | | (% by | | (% by | of first resin | resist- | resist- |
| | Type | Type | mass) | Type | mass) | Type | mass) | Type | mass) | (part by mass) | ance | ance |
| Example 26 | (RR-6) | PR177/PR254 | 42.2 | (D-3) | 5.8 | Resin 3 | 29.3 | — | — | 509 | 4 | 4 |
| Example 27 | (RR-7) | PR254/PR272/ | 49.5 | (D-3) | 6.8 | Resin 1 | 33.4 | — | — | 494 | 5 | 5 |
| | | PY139 | | | | | | | | | | |
| Example 28 | (RR-8) | PR254/PR272/ | 49.5 | (D-3) | 6.8 | Resin 2 | 33.4 | — | — | 494 | 4 | 3 |
| | | PY139 | | | | | | | | | | |
| Example 29 | (RR-9) | PR254/PR272/ | 49.5 | (D-3) | 6.8 | Resin 3 | 33.4 | — | — | 494 | 4 | 4 |
| | | PY139 | | | | | | | | | | |
| Example 30 | (BR-1) | PB15:6/PV23 | 47.5 | (D-3) | 6.5 | Resin 1 | 20.1 | — | — | 311 | 5 | 4 |
| Example 31 | (BR-2) | PB15:6/PV23 | 47.5 | (D-3) | 6.5 | Resin 2 | 20.1 | — | — | 311 | 4 | 3 |
| Example 32 | (BR-3) | PB15:6/PV23 | 47.5 | (D-3) | 6.5 | Resin 3 | 20.1 | — | — | 311 | 4 | 4 |
| Example 33 | (CR-1) | PB15:3 | 18.7 | (D-3) | 2.5 | Resin 1 | 40.5 | — | — | 1591 | 4 | 4 |
| Example 34 | (CR-2) | PB15:3 | 18.7 | (D-3) | 2.5 | Resin 2 | 40.5 | — | — | 1591 | 3 | 3 |
| Example 35 | (CR-3) | PB15:3 | 18.7 | (D-3) | 2.5 | Resin 3 | 40.5 | — | — | 1591 | 3 | 4 |
| Example 36 | (CR-4) | PB15:4 | 18.7 | (D-3) | 2.5 | Resin 1 | 40.5 | — | — | 1591 | 4 | 4 |
| Example 37 | (CR-5) | PB15:4 | 18.7 | (D-3) | 2.5 | Resin 2 | 40.5 | — | — | 1591 | 3 | 3 |
| Example 38 | (CR-6) | PB15:4 | 18.7 | (D-3) | 2.5 | Resin 3 | 40.5 | — | — | 1591 | 3 | 4 |
| Example 39 | (CR-7) | PB16 | 18.7 | (D-3) | 2.5 | Resin 1 | 40.5 | — | — | 1591 | 4 | 4 |
| Example 40 | (CR-8) | PB16 | 18.7 | (D-3) | 2.5 | Resin 2 | 40.5 | — | — | 1591 | 3 | 3 |
| Example 41 | (CR-9) | PB16 | 18.7 | (D-3) | 2.5 | Resin 3 | 40.5 | — | — | 1591 | 3 | 4 |
| Example 42 | (MR-1) | PR122 | 34.7 | (D-3) | 4.7 | Resin 1 | 23.2 | — | — | 491 | 5 | 4 |
| Example 43 | (MR-2) | PR122 | 34.7 | (D-3) | 4.7 | Resin 2 | 23.2 | — | — | 491 | 4 | 3 |
| Example 44 | (MR-3) | PR122 | 34.7 | (D-3) | 4.7 | Resin 3 | 23.2 | — | — | 491 | 4 | 4 |
| Example 45 | (YR-1) | PY185 | 24.0 | (D-3) | 3.3 | Resin 1 | 37.3 | — | — | 1139 | 4 | 4 |
| Example 46 | (YR-2) | PY185 | 24.0 | (D-3) | 3.3 | Resin 2 | 37.3 | — | — | 1139 | 3 | 3 |
| Example 47 | (YR-3) | PY185 | 24.0 | (D-3) | 3.3 | Resin 3 | 37.3 | — | — | 1139 | 3 | 4 |
| Example 48 | (KR-1) | PR264/PB16/ | 36.2 | (D-3) | 4.9 | Resin 1 | 44.6 | — | — | 903 | 4 | 4 |
| | | PY215 | | | | | | | | | | |
| Example 49 | (KR-2) | PR264/PB16/ | 46.8 | (D-3) | 6.4 | Resin 1 | 35.5 | — | — | 555 | 4 | 5 |
| | | PY215 | | | | | | | | | | |
| Example 50 | (KR-3) | PR264/PB16/ | 51.2 | (D-3) | 7.0 | Resin 1 | 31.7 | — | — | 454 | 5 | 5 |
| | | PY215 | | | | | | | | | | |

TABLE 12

| | Coloring composition | | | | | | | | | | | |
|---|---|---|---|---|---|---|---|---|---|---|---|---|
| | | | | | | | | | | Proportion of | | |
| | | | | First | | Second | | Third | | second resin with | | |
| | | Colorant | | resin | | resin | | resin | | respect to 100 | | |
| | | | Content | | Content | | Content | | Content | parts by mass | Moisture | Heat |
| | | | (% by | | (% by | | (% by | | (% by | of first resin | resist- | resist- |
| | Type | Type | mass) | Type | mass) | Type | mass) | Type | mass) | (part by mass) | ance | ance |
| Example 51 | (KR-4) | PR264/PB16/ | 36.2 | (D-3) | 4.9 | Resin 2 | 44.6 | — | — | 903 | 3 | 4 |
| | | PY215 | | | | | | | | | | |
| Example 52 | (KR-5) | PR264/PB16/ | 36.2 | (D-3) | 4.9 | Resin 3 | 44.6 | — | — | 903 | 3 | 3 |
| | | PY215 | | | | | | | | | | |
| Example 53 | (KR-6) | PR264/PB16/ | 36.2 | (D-3) | 4.9 | Resin 4 | 44.6 | — | — | 903 | 3 | 4 |
| | | PY215 | | | | | | | | | | |
| Example 54 | (KR-7) | PR264/PB16/ | 36.2 | (D-3) | 4.9 | Resin 5 | 44.6 | — | — | 903 | 3 | 5 |
| | | PY215 | | | | | | | | | | |
| Example 55 | (KR-8) | PR264/PB16/ | 36.2 | (D-3) | 2.6 | Resin 1 | 46.9 | | | 1780 | 3 | 3 |
| | | PY215 | | | | | | | | | | |
| Example 56 | (KR-9) | PR264/PB16/ | 36.2 | (D-3) | 9.5 | Resin 1 | 8.9 | | | 93 | 2 | 3 |
| | | PY215 | | | | | | | | | | |
| Example 57 | (KR-10) | PR264/PB16/ | 36.2 | (D-3) | 4.9 | Resin 1 | 44.6 | — | — | 910 | 5 | 5 |
| | | PY215 | | | | | | | | | | |
| Example 58 | (KR-11) | PR264/PB16/ | 36.2 | (D-3) | 4.9 | Resin 1 | 44.6 | — | — | 910 | 5 | 5 |
| | | PY215 | | | | | | | | | | |
| Example 59 | (KR-12) | PR264/PB16/ | 36.2 | (D-3) | 4.9 | Resin 1 | 44.6 | — | — | 910 | 5 | 5 |
| | | PY215 | | | | | | | | | | |
| Example 60 | (KR-13) | CB | 51.4 | (D-3) | 7.0 | Resin 1 | 14.0 | — | — | 200 | 4 | 4 |
| Example 61 | (KR-14) | CB | 51.4 | (D-3) | 7.0 | Resin 2 | 14.0 | — | — | 200 | 3 | 3 |
| Example 62 | (KR-15) | CB | 51.4 | (D-3) | 7.0 | Resin 3 | 14.0 | — | — | 200 | 4 | 4 |
| Example 63 | (KR-16) | TiB | 51.4 | (D-3) | 7.0 | Resin 1 | 14.0 | — | — | 200 | 5 | 4 |
| Example 64 | (KR-17) | TiB | 51.4 | (D-3) | 7.0 | Resin 2 | 14.0 | — | — | 200 | 4 | 3 |
| Example 65 | (KR-18) | TiB | 51.4 | (D-3) | 7.0 | Resin 3 | 14.0 | — | — | 200 | 5 | 4 |
| Example 66 | (KR-19) | TiB/PV23/ | 51.4 | (D-3) | 7.0 | Resin 1 | 14.0 | — | — | 200 | 5 | 4 |
| | | PY150/PO71 | | | | | | | | | | |
| Example 67 | (KR-20) | TiB/PV23/ | 51.4 | (D-3) | 7.0 | Resin 2 | 14.0 | — | — | 200 | 4 | 3 |
| | | PY150/PO71 | | | | | | | | | | |
| Example 68 | (KR-21) | TiB/PV23/ | 51.4 | (D-3) | 7.0 | Resin 3 | 14.0 | — | — | 200 | 5 | 4 |
| | | PY150/PO71 | | | | | | | | | | |
| Comparative | (GR-c1) | PG36/PY150 | 59.3 | (D-1) | 8.1 | — | — | Resin c1 | 15.2 | 0 | 1 | 1 |
| Example 1 | | | | | | | | | | | | |
| Comparative | (GR-c2) | PG36/PY150 | 59.3 | — | 8.1 | Resin 1 | 15.2 | — | — | 188 | 1 | 2 |
| Example 2 | | | | | | | | | | | | |

As shown in the above tables, with the coloring compositions of Examples, a film having excellent moisture resistance could be formed. In addition, the film obtained by using the coloring compositions of Examples was also excellent in heat resistance.

### Example 1001

A silicon wafer was coated with a green coloring composition by a spin coating method so that a thickness of a film after film formation was 1.0 μm. Next, the silicon wafer was heated using a hot plate at 100° C. for 2 minutes. Next, using an i-ray stepper exposure device FPA-3000 i5+ (manufactured by Canon Inc.), exposure was performed with light having an exposure amount of 1000 mJ/cm² through a mask having a dot pattern of 2 μm square. Next, puddle development was performed at 23° C. for 60 seconds using a 0.3% by mass of tetramethylammonium hydroxide (TMAH) aqueous solution. Next, the coating film was rinsed by spin showering and was cleaned with pure water. Next, the green coloring composition was patterned by heating at 200° C. for 5 minutes using a hot plate to form a green pixel. In the same process, a red coloring composition and a blue coloring composition were patterned to sequentially form a red pixel and a blue pixel, thereby forming a color filter having the green pixel, red pixel, and blue pixel. In this color filter, the green pixel was formed in a Bayer pattern, and the red pixel and blue pixel were formed in an island pattern in an adjacent region thereof. The obtained color filter was incorporated into a solid-state imaging element according to a known method. The solid-state imaging element had a suitable image recognition ability. As the green coloring composition, the coloring composition (GR-1) was used. As the red coloring composition, a coloring composition (RR-1) was used. As the blue coloring composition, a coloring composition (BR-1) was used.

What is claimed is:

1. A coloring composition comprising:
a colorant;
a first resin including a repeating unit represented by Formula (b-10); and
a second resin different from the first resin,
wherein the second resin is at least one selected from the group consisting of a polyimide precursor, a polyimide resin, a polybenzoxazole precursor, a polybenzoxazole resin, and a polysiloxane resin, 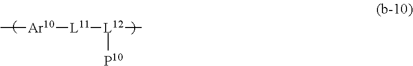
in Formula (b-10), Ar¹⁰ represents a group including an aromatic carboxyl group, L¹¹ represents —COO— or —CONH—, L¹² represents a trivalent linking group, and P¹⁰ represents a polymer chain.

2. The coloring composition according to claim 1,
wherein the second resin is at least one selected from the group consisting of a polyimide precursor, a polybenzoxazole precursor, and a polysiloxane resin.

3. The coloring composition according to claim 1,
wherein the second resin includes at least one selected from the group consisting of a polyimide precursor having a crosslinkable group, a polybenzoxazole precursor having a crosslinkable group, and a polysiloxane resin having a crosslinkable group.

4. The coloring composition according to claim 1,
wherein the second resin includes at least one selected from the group consisting of a polyimide precursor including a silicon atom and a polybenzoxazole precursor including a silicon atom.

5. The coloring composition according to claim 4,
wherein the polyimide precursor including a silicon atom is a polyimide precursor including a siloxane bond, and
the polybenzoxazole precursor including a silicon atom is a polybenzoxazole precursor including a siloxane bond.

6. The coloring composition according to claim 1,
wherein the second resin includes a polysiloxane resin having at least one group selected from the group consisting of an alkylsilyl group and an alkoxysilyl group.

7. The coloring composition according to claim 1,
wherein the first resin includes a crosslinkable group.

8. The coloring composition according to claim 1,
wherein the coloring composition includes 100 to 1600 parts by mass of the second resin with respect to 100 parts by mass of the first resin.

9. The coloring composition according to claim 1,
wherein a content of the first resin in a total solid content of the coloring composition is 0.5% to 10% by mass, and
a content of the second resin in the total solid content of the coloring composition is 10% to 50% by mass.

10. The coloring composition according to claim 1,
wherein a content of the colorant in a total solid content of the coloring composition is 30% to 70% by mass.

11. The coloring composition according to claim 1, further comprising:
a polymerizable monomer; and
a photopolymerization initiator.

12. The coloring composition according to claim 1,
wherein the coloring composition is used for forming a pixel of a color filter.

13. The coloring composition according to claim 1,
wherein the coloring composition is used for a solid-state imaging element.

14. A film obtained from the coloring composition according to claim 1.

15. An optical filter comprising:
the film according to claim 14.

16. A solid-state imaging element comprising:
the film according to claim 14.

17. An image display device comprising:
the film according to claim 14.
